(19) United States
(12) Patent Application Publication
(10) Pub. No.: US 2026/0009138 A1
(43) Pub. Date: Jan. 8, 2026

(54) Permeable Junction-Enhanced Roll-to-Roll Microfabrication for Electronic Devices

(71) Applicant: The University of Chicago, Chicago, IL (US)

(72) Inventors: Bozhi Tian, Chicago, IL (US); Chuanwang Yang, Chicago, IL (US); Aleksander Prominski, Chicago, IL (US); Pengju Li, Chicago, IL (US)

(21) Appl. No.: 19/259,856

(22) Filed: Jul. 3, 2025

Related U.S. Application Data
(60) Provisional application No. 63/667,434, filed on Jul. 3, 2024.

(51) Int. Cl. C23C 16/54; B82Y 40/00; C01B 32/186; C23C 16/26

(52) U.S. Cl. CPC C23C 16/54; B82Y 40/00; C01B 32/186; C23C 16/26

(57) ABSTRACT

The present disclosure relates to a roll-to-roll (R2R) apparatus for continuous production of carbon/graphene-based electronic devices and methods of using a R2R apparatus for continuous production of carbon/graphene-based electronic devices.

### CROSS-REFERENCE TO RELATED APPLICATIONS

This application claims priority to U.S. Provisional Application No. 63/667,434, filed Jul. 3, 2024, the disclosure of which is hereby incorporated by reference in its entirety.

### GOVERNMENT FUNDING STATEMENT

This invention was made with government support under FA9550-20-1-0387 awarded by the United States Department of Defense|U.S. Air Force, CBET-2128140 and MPS-2121044 awarded by the National Science Foundation, and W911NF-21-1-0090 awarded by the United States Department of Defense United States Army|U.S. Army Research, Development and Engineering Command|Army Research Office (ARO). The government has certain rights in the invention.

### BACKGROUND OF THE DISCLOSURE

Microfabrication—the process of fabricating small structure usually in micrometer scale—has wide practical applications but confronts sustainability challenges due to the substantial chemical and energy consumption during the patterning and transfer stages.

### SUMMARY OF THE DISCLOSURE

As shown and described herein, the present disclosure relates to a roll-to-roll (R2R) apparatus for continuous production of carbon/graphene-based electronic devices and methods of using the R2R apparatus for continuous production of carbon/graphene-based electronic devices.

In an embodiment of the present disclosure, a roll-to-roll (R2R) apparatus for continuous production of carbon/graphene-based electronic devices includes a substrate handling module, an infiltration module, a patterning module, a control system, and a post-processing module.

In various such embodiments, the substrate handling module includes a freely moving unwind unit, a tension control system, and a motor-driven rewind unit.

In various such embodiments, the freely moving unwind unit is configured to be continuously fed a flexible substrate from an unprocessed roll.

In various such embodiments, the tension control system further includes an alignment system, and the tension control system and the alignment system are configured to maintain tension of the flexible substrate as it moves from the freely moving unwind unit to the motor-driven rewind unit.

In various such embodiments, the motor-driven rewind unit is configured to collect the flexible substrate fed through the freely moving unwind unit onto a roll.

In various such embodiments, the infiltration module includes an infiltration bath and a heater assembly.

In various such embodiments, the infiltration bath is configured to process the flexible substrate in a predesigned sink using a deposition technique.

In various such embodiments, the infiltration bath comprises at least one of a functional salt, a conductive ink, a semiconducting polymer, a dielectric material, and an encapsulation layer.

In various such embodiments, the deposition technique includes a salt-impregnation process, and wherein the salt-impregnation process comprises applying a concentrated sodium borate solution to the flexible substrate.

In various such embodiments, the deposition technique comprises at least one of a slot-die coating and a spray coating.

In various such embodiments, the heater assembly includes a Joule heater assembled from resistive wire enclosed in high-temperature fiberglass sleeving.

In various such embodiments, the heater assembly is configured to dry the flexible substrate after the flexible substrate is bathed in the infiltration bath.

In various such embodiments, the patterning module includes an ablation machine and control software integrated with a stepper motor integrated into an Arduino board.

In various such embodiments, the ablation machine comprises a K40 CO₂ laser configured to create conductive carbon/graphene patterns on the flexible substrate such that the K40 CO₂ laser is configured to transform cellulose-based material into conductive carbon/graphene patterns on the flexible substrate.

In various such embodiments, the ablation machine includes at least one photolithography machine, a screen printing machine, and a blade coating machine to create patterns for electrodes, transistors, and other electronic components on the flexible substrate.

In various such embodiments, the ablation machine further includes an alignment system, and the control software allows for coordination of rolling, patterning, and pausing the flexible substrate with the ablation machine integrated with the alignment system.

In various such embodiments, the control system includes a central controller, an ablation controller, a raster, and a user interface for managing rolling and patterning processes of the R2R apparatus.

In various such embodiments, the control system coordinates operation of the substrate handling module, the impregnation module, the patterning module, and the post-processing module.

In various such embodiments, the control system is configured to precisely regulate substrate feeding speed at the substrate handling module, impregnation time at the impregnation module, patterning design at the patterning module, and post-processing conditions at the post-processing module to achieve uniform and high-quality flexible electronic devices.

In various such embodiments, the post-processing module includes a performance testing device and a water-phase transfer device.

In various such embodiments, the performance testing device is configured to test parameters of fabricated electronic devices created out of the flexible substrate through processing at the substrate handling module, the impregnation module, and the patterning module, the post-processing module is configured to separate fabricated electronic devices from the remainder of the flexible substrate after processing at the substrate handling module, the impregnation module, and the patterning module, or the water-phase transfer device is configured to transfer the fabricated electronic devices from the remainder of the flexible substrate after processing at the substrate handling module, the impregnation module, and the patterning module.

### BRIEF DESCRIPTION OF THE DRAWINGS

FIGS. 1A-1D depict a CAD design for a roll-to-roll (R2R) apparatus. FIG. 1A depicts a front view of the R2R apparatus. FIG. 1B depicts a top view of the material components in the design of the R2R apparatus. FIG. 1C depicts a design of the heating module featuring an aluminum plate for the R2R apparatus. FIG. 1D depicts a design of the filament holder equipped with aligned holes for resistive wire with high-temperature fiberglass sleeving for the R2R apparatus. Unit, inch.

FIG. 2 depicts 3D schematics of the R2R apparatus and its operational components. The R2R system is comprised of five key modules: substrate handling, infiltration, patterning, control system, and post-processing.

FIG. 3 depicts part of the code for a roller controller for the R2R apparatus. The interface is built upon the K40 Whisperer source code, which is accessible at www.scorchworks.com/K40whisperer/k40whisperer.html#download and is distributed under the GNU General Public License (GPL).

FIGS. 4A-4B depict Customized Arduino and Python codes for the controller of the R2R apparatus. FIG. 4A depicts the code and FIG. 4B depicts the graphical user interfaces (UIs) for the home-built R2R controller, which includes the roller, laser controller, electronics design, and laser raster components.

FIGS. 5A-5B depict a home built R2R apparatus. FIG. 5A depicts an image of the R2R apparatus highlighting its main components: product collector, control system, transfer system, roller system, patterning module, infiltration module, and substrate feed. FIG. 5B depicts close-up views of the individual modules, featuring the user interface, electronic controller, rolling system, laser patterning, and substrate feeding module (from left to right).

FIGS. 6A-6C demonstrate characterization of R2R-produced electronics under different working parameters. FIG. 6A demonstrates Raman spectra of electronic patterns fabricated under different laser powers in raster mode, with a constant raster speed of 100 mm/s. At least four replicates were analyzed. FIG. 6B demonstrates intensity ratio of D and G Raman peaks for the different samples. FIG. 6C demonstrates the effect of laser power on the sheet resistance of carbon membranes, with a minimum of six replicates examined. This demonstrates that by varying working parameters, the quality of electronics can be optimized in the R2R process.

FIGS. 7A-7B depict scalable production and transfer utilizing the R2R apparatus. FIG. 7A depicts an optical image showing fabricated RFID patterns on a 1.5-meter paper sheet. FIG. 7B depicts an optical image of transferred RFID patterns on a 1.5-meter transparent PET roll.

FIG. 8 demonstrates comparative analyses of environmental impact scores for producing a 1 m² device using different fabrication methods. This figure presents a detailed assessment of four different fabrication methods: the pyrolysis+lithography route (R1), CVD+lithography route (R2), lasering+casting route (R3), and the method described in this study (R4). The environmental impact is quantified across ten categories: (a) Global warming potential (measured in kg CO₂ equivalent), (b) Ozone depletion (measured in kg CFC-11 eq), (c) Smog (measured in kg O₃ eq), (d) Acidification (measured in kg SO₂ eq), (e) Eutrophication (measured in kg N eq), (f) Carcinogenic effects (measured in CTUh), (g) Noncarcinogenic effects (measured in CTUh), (h) Respiratory effects (measured in kg PM 2.5 eq), (i) Ecotoxicity (measured in CTUe), and (j) Fossil fuel depletion (measured in MJ surplus).

FIGS. 9A-9J depict a bioinspired permeable junction strategy for sustainable microfabrication of carbon-based devices. FIG. 9A depicts a delamination strategy inspired by various microscale junction interfaces in natural systems, including exoskeleton ecdysis in locusts (left), instantaneous attachment and release of a gecko's footpad on the wall (middle), and keratinocyte migration on a wound (right). FIG. 9B depicts a schematic diagram illustrating the responsive adhesion and delamination strategies of natural systems that employ biochemical mechanisms to drive sequential firm attachment (1) and on-demand release (2) at junction interface. Development of biomimetic synthetic materials, which leverage both chemical and mechanical responsiveness on junction structures, may present opportunities for enhancing adhesion strength while facilitating easy delamination for sustainable microfabrication. FIGS. 9C-9D depict simulations of interfacial delamination of a thin membrane from (FIG. 9C) a planar bulk substrate and (FIG. 9D) a porous substrate with junction structures. Contour plots show the strain distributions in the horizontal direction. FIG. 9E depicts delamination propagation dynamics that show that junction structure substantially expedites interfacial delamination by orders of magnitude in time under equivalent strain conditions. FIG. 9F depicts a cross-sectional image of a patterned carbon membrane atop a vertically oriented sodium carboxymethyl cellulose-based aerogel. FIG. 9G depicts a micro-computed tomography reconstruction of patterned carbon layer on fibrous cellulose network. Black, carbon; grey, cellulose microfibrils. FIG. 9H depicts an image of a fabricated neuron- and flower-like devices on a cellulose substrate. FIG. 9I depicts a photograph showing an electromyography (EMG) electrode array released from a porous cellulose substrate and attached to a human forearm through water-assisted tape transfer. FIG. 9J depicts schematic illustrations showing the multifunctional applications of devices through sustainable microfabrication.

FIGS. 10A-10I depict salt-assisted laser patterning and instantaneous delamination of carbon devices from permeable junctions. FIG. 10A depicts a schematic illustration of photochemical and chemomechanical processes of salt-catalyzed laser patterning and water-activated delamination on a junction interface. The chemomechanical force is generated using a chemical trio consisting of an activator (water), an inhibitor (salt), and a neutralizer (EDTA) with T shaped and dashed lines representing each function. FIG. 10B depicts a profile of temperature increase during photochemical patterning with the inset image illustrating the optical path for spectra collection. FIG. 10C depicts optical images that depict carbon synthesis on paper substrates without salt catalysts, with pseudo-colored scanning electron microscopic images on the right panel showing permeable junctions formed with the aid from Zn(NO₃)₂ or Na₂B₄O₇. FIG. 10D depicts in an upper panel: microscopic images of cellulose fiber before (left) and after (right) swelling in water with dashed lines showing the original fiber position. Lower panel: schematic illustration of borate- and Mⁿ⁺-based routes for molecular-bond control over swelling and strength behaviors of cellulose fiber. FIG. 10E depicts a swelling index (d′/d), and the energy release rate (G) of cellulose fibers, which was controlled through modulating the intermolecular H-bond using ethanol/water mixtures. Box plots represent the interquartile range (IQR) with the median line inside the box. Whiskers extend to ±1.5 times the IQR from the first and third quartiles. The mean value is shown by a white marker. All datapoints are plotted, with the number of independent samples being at least N=5. FIG. 10F depicts a change of Young's modulus (E), and d′/d of cellulose fibers in the presence of various inhibitors (Mⁿ⁺) and a neutralizer (EDTA). Box plots represent the IQR with the median line inside the box. Whiskers extend to ±1.5 times the IQR, with the mean value shown by a circle inside the box. All datapoints are plotted, with the number of independent samples being at least N=6. FIG. 10G depicts a measurement of the interfacial tension between water and the free-standing carbon film with comparisons of theoretical value of water-air interface and water-dense graphene interface. The inset image shows the cross section of the water meniscus formed between the delaminated carbon membrane and the cellulose substrate. FIG. 10H depicts penetration dynamics of water droplets represented by the change in relative droplet area over contact time. Data were analyzed from N=3 independent experiments, with results expressed as mean±s.d. (standard deviation). FIG. 10I depicts a schematic and image sequence of water-assisted separation of thin carbon layer from porous cellulose substrate.

FIGS. 11A-11D depict eco-friendly and versatile fabrication of multifunctional devices. FIG. 11A depicts scanning transmission electron microscopy images and illustrations of semi-crystalline carbon (left) and encapsulation of well-dispersed Pt atoms (middle) and Pt nanoparticles (right) within carbon shells. FIG. 11B depicts transmission electron microscopy images of metal (Mn/Fe/Co/Ni/Cu/Pd) and metal carbides (TiC/WₓC/Mo₂C)-incorporated within carbon device. The images are representative of more than 3 similarly prepared samples. FIG. 11C depicts water-assisted transfer of carbon devices onto various substrates, including water-phase separation on water surfaces (I-II), transfer to tape (III), and hydrogels (IV). FIG. 11D depicts a schematic illustration and optical images of repetitive pattern transfer from the same substrate through permeable junction design. The three printed layers depict images of a transferred house, industrial smokestacks and an electroencephalography experiment onto three transparent PET/acrylic plates.

FIGS. 12A-12I depict sustainable microfabrication for device patterning and transfer for flexible bioelectronics. FIG. 12A depicts a schematic illustration depicting transfer of porous carbon patterns onto flexible substrates for application in sciatic stimulation, low-voltage heart stimulation and high fidelity electrocardiogram (ECG) recording. The lower right panel shows the electrochemical interface between excitable tissues and patterned carbon interfaces. FIG. 12B depicts an image of fabricated soft carbon electrode on a thin PET film and the wrapped sciatic curve within the carbon electrode, showing a compliant interface. FIG. 12C demonstrates Electromyography (EMG) responses of skeletal muscle under different stimulation currents (from 75 to 1000 μA) using Au (left panel) or carbon electrode (right panel) at a frequency of 4 Hz. FIG. 12D depicts an optical image of a porous carbon membrane-grafted Au (Au—C) electrode for heart stimulation. The inset image shows an enlarged view of a serpentine-structured microcapacitor on the Au electrode. FIG. 12E demonstrates impedance and phase spectra of Au and Au—C electrodes with fitted curves according to the circuit displayed in FIG. 12A. FIG. 12F demonstrates an ECG response of isolated rat heart to biphasic, square current waveform stimulation at a frequency of 4 Hz. Under the same current density of 4.0 mA/cm², the heart showed different ECG responses under stimulation from Au or Au—C electrodes. FIG. 12G demonstrates duration-strength curves of Au and Au—C stimulation electrodes and their curve fitting are present at a stimulation frequency of 4 Hz. FIG. 12H demonstrates threshold voltage for stimulation at different durations for Au and Au—C electrodes with inset figure showing representative voltage change during a biphasic stimulation cycle. Threshold current and voltage were recorded from N=6 stimulation replications for N=4 independent devices. Results are presented as mean±s.d. FIG. 12I demonstrates representative ECG traces obtained from the 16-channel, carbon-coated recording electrode display the spatial propagation of rat heart activities.

FIGS. 13A-13J depict sustainable microfabrication of catalytic device for robotic sensing and environmental remediation. FIG. 13A depicts a schematic illustration of a water strider swimming on water surfaces (upper panel), and an optical image of a biomimetic nanozyme-powered soft robot transferred on PET film (lower panel). The schematic on top-right of the lower panel shows the layered structure of a catalytic membrane. FIG. 13B depicts high-speed images that demonstrate the burst dynamics of a single bubble at the edge of robots. After creating an air cavity in the margin of the robot, a water jet forms and creates a water wave, which propels the robot's movement (Δx) in 80 ms. FIG. 13C depicts a schematic illustration of the motion of biomimetic robots, which is fueled by O₂ bubbles generated via catalysis of H₂O₂ through the embedded Pt nanoparticles. FIG. 13D depicts a workflow diagram for extracting the trajectories of robots for automatic behavior analysis. FIG. 13E demonstrates a diameter change of O₂ bubbles on single, double, and multiple sites of Pt-embedded carbon particles. Inset panels display optical images of growing bubbles on an individual particle. Data were analyzed from N=3 independent experiments, and the results are expressed as mean±s.d. FIG. 13F depicts a schematic of the generated coalescence force (F_{growth}) and bubble burst force (F_{burst}) during O₂ generation. FIG. 13G demonstrates a trajectory analysis of a catalytic robot with nanozyme-powered motion in 1.0 M H₂O₂ solution and biomimetic robotic sensing of Hg(II) at different exposure concentrations. FIG. 13H demonstrates displacement of the robots after exposure to varying Hg(II) concentrations and the jumping analysis (inset figure). FIG. 13I depicts a schematic of active pollutant removal using swimming robots with external energy input. FIG. 13J demonstrates time-dependent removal efficiency of RhB pollutant under various treatment conditions with an inset photo showing the RhB color change in different groups.

FIGS. 14A-14G depict scalable microfabrication with minor environmental impact. FIGS. 14A-14B depict the home-built roll-to-roll (R2R) apparatus in a system design (FIG. 14A) and an image (FIG. 14B) of the home-built R2R apparatus, showcasing electrical components and fabrication systems, such as roller controller and laser writer with graphical user interface (GUI), paper feed, salt-impregnation system, laser scanner, roller system, electronic controller, and product collector. FIG. 14C depicts an optical image showing fabricated RFID patterns on a 1.5-meter paper sheet (top) and an optical image of transferred RFID patterns on a 1.5-meter transparent PET roll (bottom). FIG. 14D depicts the system boundaries of conventional microfabrication method based on pyrolysis+lithography techniques (upper panel) and the current approach (lower panel) for device fabrication. FIG. 14E demonstrates a comparative analysis of greenhouse gas (GHG) emissions for producing a 1 m² device (measured in kg CO₂ equivalent) using different fabrication methods: the pyrolysis+lithography route (R1), CVD+lithography route (R2), lasering+casting route (R3), and the route disclosed herein (R4). Data distribution, presented as mean±s.d., is derived from 1,000 trials of Monte Carlo simulation within 95% confidence interval. FIGS. 14F-14G demonstrate an analysis of GHG emission contributions by factors in R4 (FIG. 14F) and R1 (FIG. 14G). Each pie chart displays the distribution of different contributing factors, either materials, energy, or waste, to the total GHG for each fabrication route.

FIGS. 15A-15I demonstrate the efficiency of the permeable junction approach for fast delamination compared with other traditional methods and indicates that the permeable junction approach can also be applied to traditional photolithography methods on rigid substrates for rigid electronics fabrication. FIGS. 15A-15C depict high-speed imaging verified enhanced water droplet penetration in porous substrates, which substantially amplifies swelling dynamics. Subsequent delamination observations revealed rapid water induced swelling and membrane detachment within ˜152 ms, over three orders of magnitude faster than current etching/electrochemical/dry delamination methods used to delaminate graphene layer from Cu foil. FIGS. 15D-15I demonstrate that CNF enables rapid delamination of Au-based bioelectronics created via traditional photolithography or thermoplastic-based objects via additive manufacturing process.

FIG. 16 depicts an R2R apparatus for the automated production of carbon-based devices. The R2R apparatus incorporates an integrated system including a salt impregnation unit, an electronic roller module, a laser writer, and the water-assisted transfer system.

FIGS. 17A-17E demonstrate a comparative analysis that was conducted against conventional methods for fabricating carbon-based devices, including CVD+lithography methods, pyrolysis+lithography method, and lasering+casting method. FIG. 17E (panels a-i) demonstrate that the current method shows the least environmental impact in terms of resource consumption, effects on terrestrial ecosystems, acidification, and human health.

FIGS. 18A-18B demonstrate a Finite Element (FE) model of substrates immersed in water. FIG. 18A demonstrates FE models of a membrane on a porous substrate immersed in water, with the bottom images depicting the FE modeling before and after swelling. FIG. 18B demonstrates FE models of a membrane on a nonporous substrate immersed in water, with the bottom images depicting the FE modeling before and after swelling.

FIGS. 19A-19C demonstrate traction-separation response and shear stress distribution. FIG. 19A demonstrated a linear traction-separation response used for the cohesive elements. Distribution of the (FIG. 19B) water concentration and (FIG. 19C) shear stress of a half single fiber when graphene and cellulose fiber experience approximately 50% delamination while immersed in water. The contour plots, which depict the water concentration distributions.

FIG. 20 depicts a workflow of carbon membrane patterning and transfer. The process of carbon membrane fabrication, encompassing fiber processing via salt impregnation, microfabrication through laser synthesis, and water-assisted transfer onto various substrates. This includes transfer to 2D substrates/3D objects (I), hydrogels (II), and tape (III).

FIG. 21 depicts a transfer of carbon pattern onto water and various substrates. Water-assisted transfer onto various substrates, including water-phase separation on water surface (I-II), transfer to tape (III), and hydrogels (IV).

FIGS. 22A-22B depict thermoforming and responsive release for additive manufacturing. FIG. 22A depicts a representative serpentine design on a holding substrate for 3D printing of a thin layer. The printing steps involve 3D printing of a pre-designed structure on a Fused Deposition Modeling (FDM) printer (I-II), heating to induce the glass-transition of the thermoplastic resin (III), manually thermoforming into pre-designed shapes using flexible paper as the supporting substrate (IV), cooling under air and wetting with water for rapid and easy delamination of the fragile thin structure (V-VI), leading to the final product (VII). FIG. 22B depicts an image showcasing the 3D objects created using the thermoforming method.

FIGS. 23A-23B demonstrate a characterization of laser-synthesized carbon materials under various salt catalytic conditions. FIG. 23A demonstrates an optical characterization of cellulose paper substrate after laser treatment with different catalysts: control group (without any catalysts), sodium borate (0.15 M), MgCl₂ (0.5 M), MnCl₂ (0.5 M), Fe(NO₃)₃ (0.5 M), Co(NO₃)₃ (0.5 M), Ni(NO₃)₂ (0.5 M), Cu(NO₃)₂ (0.5 M), and Zn(NO₃)₂ (0.5 M). FIG. 23B demonstrates Raman spectra of laser-synthesized carbon materials under different catalytic conditions, highlighting effective graphitization achieved in the presence of sodium borate, MgCl₂, Fe(NO₃)₃, Co(NO₃)₃, Ni(NO₃)₂, and Zn(NO₃)₂.

FIGS. 24A-24D depict microscopic images of porous carbon layer on aerogel and fibrous cellulose network. FIGS. 24A-24B depict the formation of a carbon membrane (indicated within the red dashed line) on the surface of the aerogel (FIG. 24A), with an enlarged view of the porous carbon (FIG. 24B). FIGS. 24C-24D depict an optical image of the cross-section of a paper/carbon network (FIG. 24C) and a SEM image of the paper/carbon interface (FIG. 24D), both demonstrating the highly porous structure of the carbon layer.

FIGS. 25A-25C depict a high-resolution transmission electron microscopy (HRTEM) image of the laser synthesized carbon material. FIG. 25A depicts a HRTEM image of the edge of a carbon flake, revealing few-layer features and highly wrinkled structures with an average lattice spacing of ˜3.5 Å ((002) plane of graphite). FIGS. 25B-25C depict enlarged views of the atomic structure of carbon material. Scale bar, 2 Å. The results demonstrate that after salt-assisted lasering, thin carbon flakes with ripple-like wrinkled and turbostratic stacking structures were synthesized.

FIGS. 26A-26B demonstrate Raman characterization of the laser-synthesized carbon materials. FIG. 26A demonstrates Raman spectra of cellulose paper after lasering under different concentrations of sodium borate, ranging from 0 to 0.5 M. FIG. 26B demonstrates that the ratio of Raman intensity at 1350 cm⁻¹ (D peak) and 1580 cm⁻¹ (G peak) (I_{D}/I_{G}), as well as the intensity ratio of the 2D peak (2670 cm⁻¹) to the G peak (I_{2D}/I_{G}) for different samples. The inset figures display optical images of the lasered paper substrates at varying borate concentrations, with a scale bar of 2 mm. The results demonstrate that effective graphitization can be achieved when the borate concentration is above 0.05 M.

FIGS. 27A-27D demonstrate Raman spectra of laser-synthesized carbon materials under various lasering conditions. FIG. 27A demonstrates Raman spectra of carbon materials synthesized with varying laser scanning speeds while maintaining a constant intensity of 1.5 W. FIG. 27B demonstrates Raman spectra of carbon materials created at different laser powers while keeping a constant scanning speed of 15%. FIG. 27C demonstrates a contour map illustrating I_{2D}/I_{G} ratios at different laser intensities and speeds. A larger I_{2D}/I_{G} ratio is preferred for a higher degree of graphitization. FIG. 27D demonstrates the relationship between the threshold laser power and scanning rate for carbon material formation is nonlinear. Graphitization occurs when the conditions are within the shaded region, indicating a critical laser power point required for graphene formation.

FIGS. 28A-28E demonstrate wavelength-dependent carbonization of cellulose fiber under laser irradiation. FIGS. 28A-28B depict optical images of paper fibers before (FIG. 28A) and after (FIG. 28B) irradiation under 473 nm laser for 180 s. The laser power density was 3.5×10⁸ W/m². Extremity of line indicates the irradiation point. FIGS. 28C-28D depict optical images of paper fibers before and after irradiation under 532 nm laser for 180 s. The laser power density was 9.6×10⁹ W/m². FIG. 28E demonstrates the FTIR spectra of cellulose paper before and after impregnation with sodium borate. Cellulose showed strong IR absorbance at 1025 cm⁻¹, which can be attributed to vₛ(C—O) of C—OH/C—O—C. The absorbance peak locates around the center of CO₂ laser, 10.6 μm, which facilitated the fast temperature increase.

FIGS. 29A-29B demonstrate Raman characterization of pyrolyzed cellulose samples. FIG. 29A demonstrates Raman spectra of borate-impregnated cellulose paper after pyrolysis at 600° C. at a ramping speed of 20° C./min under a protective N₂ atmosphere. The concentration of sodium borate in the impregnation solution ranged from 0 to 0.5 M. FIG. 29B demonstrates a ratio (I_{D}/I_{G}) of Raman intensity of pyrolyzed cellulose paper samples. No characteristic peak appeared at 2650 cm⁻¹, indicating that no graphene material was produced in the pyrolysis condition even when borate was present.

FIGS. 30A-30C demonstrate thermal analysis of the carbonization process of cellulose paper with salt impregnation. FIG. 30A demonstrates TGA curves of cellulose paper impregnated with different borate solutions at a ramping speed of 20 K/min. FIG. 30B demonstrates differential thermogravimetric (DTG) curves of cellulose samples. FIG. 30C demonstrates change of the critical temperature of carbonization (T_{c}, dots) and the conversion ratio (rectangle) in different groups. The results demonstrate that borate significantly reduces T_{c} and enhances char yield, even at very low concentrations (0.005/0.01 M).

FIGS. 31A-31B demonstrate thermal analysis of cellulose paper carbonization at varying temperature ramping speeds. FIG. 31A demonstrates critical decomposition temperature at different borate concentrations. FIG. 31B demonstrates activation energy of cellulose paper at different conversion rates, calculated using the Coats Redfern method. Borate increases the activation energy of weight loss reaction, which corresponds to the increased char residue observed when borate is loaded (weight loss decreased). The energy barrier created by the borate layer on cellulose fibers may contribute to higher char production during rapid temperature increases, while ultrafast temperature increases may facilitate effective graphitization.

FIGS. 32A-32D demonstrate Nitrogen adsorption and desorption isotherms of various samples and pore size distribution. FIG. 32A demonstrates Nitrogen adsorption and desorption isotherms of cellulose paper samples with various treatments: untreated paper, borate-impregnated paper (Paper-B), paper treated with lasering (Paper/lasering), and borate-impregnated paper after lasering (Paper-B/lasering). FIG. 32B demonstrates Nitrogen adsorption and desorption isotherms of carbon membrane. FIG. 32C demonstrates pore size distribution curves of paper before and after borate impregnation. FIG. 32D demonstrates carbon membrane based on the adsorption process. The distribution shows the presence of micropores and mesopores within cellulose fibers with a primary pore diameter range of 1-16 nm. Borate impregnation does not affect the pore size distribution, indicating that it does not obstruct the pores inside the fibers.

FIGS. 33A-33B depict image sequences showing the delamination of carbon membrane in water. FIG. 33A depicts a release of a five-point star-shaped carbon pattern from an aerogel substrate in water. The aerogel's porosity facilitates the swift delamination of patterned carbon layers upon water submersion. FIG. 33B depicts image sequences illustrating the delamination of a carbon membrane from filter paper in water. The experiments showcase the rapid release behavior of the carbon membrane from permeable junctions.

FIG. 34 depicts a structural change of cellulose fibers before and after wetting. Fluorescence images of fibers in cellulose paper before (left) and after (right) wetting with water.

FIG. 35 depicts responsive delamination of carbon patterns through modulating the strain development. Upon water exposure, significant swelling of cellulose fibers within the paper matrix triggered an interfacial mechanical mismatch, leading to instant delamination in the borate or Mg-based approach. While metal ions (Zn/Co/Fe) acted as photocatalysts during patterning, they also formed strong chelation with the hydroxyl groups in the cellulose substrate, resulting in a tight binding between the carbon pattern and substrate. As a consequence, the carbon pattern remained bound to the supporting substrate even after overnight water exposure. However, through post-neutralization using EDTA, the activation of porous substrates and delamination via hygroscopic swelling in water can be induced, creating strain mismatch for fast, focal-enabled delamination in a matter of minutes.

FIG. 36 depicts critical delamination conditions through modulating the strain development. Separation of carbon membrane on paper substrate in different water/ethanol mixtures. The number shown above represents the w/v percentage of ethanol in the mixture. The images display the carbon layer successfully delaminating from the paper substrate in various solvent mixtures. Delamination is easily achieved in water but not possible when w(EtOH)≥75%. Decreasing the swelling ratio of the supporting substrate in the solvent reduces the generated energy, potentially allowing for the determination of a threshold energy for separating carbon and paper.

FIGS. 37A-37D demonstrate Molecular interaction between cellulose and solvents. FIGS. 37A-37C demonstrate FTIR spectra and their deconvolution results of cellulose paper (FIG. 37A), paper-EtOD (FIG. 37B) and paper-D₂O (FIG. 37C). Three characteristic H-bonds in 3000-3600 cm⁻¹ range were deconvoluted and highlighted. FIG. 37D demonstrates the normalized FTIR absorbance for the O-D stretch mode of D₂O in the absence or presence of cellulose. The shift of the D-O bond to a higher frequency indicates a weaker D-O bond in the presence of cellulose, suggesting an intermolecular interaction between D-O and the hydroxyl group of cellulose. molecular level control over swelling and strength properties in the amorphous region of cellulose II. A water/ethanol mixture is used to break the intermolecular H-bond of 3-O . . . HO-6′.

FIG. 38 depicts an XRD spectra change of cellulose in the presence of solvents. Spectra change of cellulose in the absence or presence of water. XRD peaks at 22.8° and ˜16° are assigned as the crystalline region (lattice plane, 002) of cellulose I and the amorphous region of cellulose II. Spectra were normalized according to the intensity at 22.8°. The presence of water greatly decreases the peak intensity at ˜16° and increases the intensity at about 28°. Relatively, the intensity of cellulose was only slightly changed in ethanol, implying the weak interaction between ethanol and cellulose chains.

FIGS. 39A-39B demonstrate stress-strain curves of wetted cellulose substrates. FIG. 39A demonstrates the stretch, X, is defined as the distance between the two clamps when the paper slice is deformed, divided by the distance when the paper slice is stretched. The inset figure shows the dog bone design of the paper slice according to the ASTM D638 Type I standard. FIG. 39B demonstrates Young's modulus calculated from the stress-strain curves. Control group stands for substrates at dry state.

FIGS. 40A-40E demonstrate stress-strain curves of wetted cellulose substrates with various metal ions and EDTA. FIGS. 40A-40D demonstrate stress-strain curves for cellulose paper impregnated with Fe(III), Co(II), Cu(II), and Zn(II), either in the absence or presence of EDTA. Compared to the control group (FIG. 40E), the addition of EDTA significantly reduces the mechanical enhancement induced by metal ions.

FIG. 41 demonstrates delamination energy generated in metal-based systems. The calculated delamination energy (G) based on the swelling ratio and modulus in metal-based systems. Initially, it was found that the delamination energy was quite low in the metal groups. However, following treatment with EDTA, the value of G exceeded the critical energy threshold (˜0.55 J/m²). This led to the successful release of the carbon membrane from the system.

FIG. 42 depicts scanning electron microscope (SEM) characterizations and height profiles of substrates. (a-d) SEM images (upper panels) and three-dimensional reconstructions of height profiles (lower panels) for a variety of substrates: CMC film (a), compressed cellulose paper (b), cellulose paper (c), and CMC-based aerogel (d). The color bars denote the height ranges.

FIGS. 43A-43D demonstrate surface roughness and interfacial fracture energy analysis. FIG. 43A depicts a schematic illustration of interfacial fracture energy measurements. Experiments were conducted in peel mode between tape (Scotch® Magic™ Greener Invisible Tape) and various substrates using a sandwich configuration to examine the influence of porosity on adhesion energy. FIG. 43B demonstrates curves that show peeling force/substrate width versus displacement for various substrate-tape bonds. The surface roughness (FIG. 43C) and interfacial fracture energy (FIG. 43D) were analyzed for four distinct substrates. The results qualitatively indicate a decrease in adhesion as porosity increases.

FIG. 44 depicts a wetting transition of sessile water droplets on various substrates. Wetting transition of sessile water droplets on aerogel (a), paper (b), compressed paper (c), and film (d). The left panel of each figure displays an optical image of the sample with a wetting droplet, while the right panel shows an image sequence of sessile droplets and their contact time with the surface. The results demonstrate that the presence of pores within the substrate significantly accelerates the penetration speed by orders of magnitudes.

FIG. 45 demonstrates an ‘Ashby-like’ plot comparing the activation time and actuation stress of the separation process with natural hygroscopic systems. Compared with naturally occurring hygroscopic actuators, including silk, seed, and mimosa, the porosity-enabled actuation system achieves much shorter delamination times (from ˜150 ms in water to ˜250 ms in 50% ethanol solution) at similar stress levels (107 Pa).

FIGS. 46A-46C depict scalable production and transfer with a home-built roll-to-roll (R2R) apparatus. FIG. 46A depicts a schematic illustration of the home-built R2R apparatus, showcasing components such as paper feed, laser scanner, roller system, salt-impregnation system, electronic controller, product, and transfer system. FIG. 46B depicts an optical image of fabricated RFID patterns on a 1.5-meter paper sheet, featuring an enlarged view of the pattern (right panel). FIG. 46C depicts an optical image of transferred RFID patterns on a 1.5-meter transparent tape with a green background, with a close-up view (right panel).

FIGS. 47A-47C demonstrate characterization of R2R-produced carbon membranes under different working parameters. FIG. 47A demonstrates Raman spectra of carbon membranes fabricated under different laser powers in raster mode, with a constant raster speed of 100 mm/s. At least four replicates were analyzed. FIG. 47B demonstrates an intensity ratio of D and G Raman peaks for the different samples. FIG. 47C demonstrates an effect of laser power on the sheet resistance of carbon membranes, with a minimum of six replicates examined. This demonstrates that by varying working parameters, the quality of carbon membranes can be optimized in the R2R process.

FIG. 48 depicts patterning resolution under varying laser parameters. Measurement was conducted by analyzing the line width of laser-scribed patterns on cellulose paper at different lasering speeds. The right panel presents microscopic images of laser-scribed lines at scribe speeds of 4.8, 8.0, 11.2, 14.4, 19.2, 24.0, 32.0, and 48.0 mm/s (from top to bottom). According to the definition of DPI (dots per inch), the laser writing method employed in this study could achieve a printing resolution as high as 282 DPI. The scale bar is set at 500 m.

FIGS. 49A-49B demonstrate tests on Pt-loaded carbon membranes and matrixes. FIG. 49A demonstrates TEM analysis of Pt-loaded carbon membrane and particle size distribution. (Panels a-d) TEM images of Pt-loaded carbon membrane with different K₂PtCl₄ concentrations during impregnation: 0.025 (a), 1.0 (b), 2.5 (c), and 5.0 (d) wt % in 0.15 M sodium borate solution. (Panels e, f) Pt NP size distribution across groups; smaller and more uniform NPs observed at lower initial Pt concentrations. No Pt NPs were detected in 0.025% group via HRTEM. Statistics based on >100 particles. FIG. 49B demonstrates STEM and SAED analysis of Pt-loaded carbon matrix. (Panel a) STEM micrograph of the Pt-loaded carbon matrix with an initial K₂PtCl₄ loading of 0.025% alongside the corresponding SAED pattern (Panel b). (Panel c) STEM micrograph of the Pt-loaded carbon matrix with an initial K₂PtCl₄ loading of 5% and its respective SAED pattern (Panel d). For low Pt loading group, no discernible diffraction patterns of lattice structures are observed in the SAED image. Distinctly dispersed Pt atoms and clusters can be clearly differentiated from the faint carbon matrix in the STEM micrographs. Regarding carbon matrices with high K₂PtCl₄ loading (5%), various features such as Pt nanoparticles (10-40 nm in size with a lattice spacing of 2.6 Å), Pt clusters (consisting of tens of platinum atoms), and individual Pt atoms can be readily distinguished in the STEM micrographs. The disparity between high and low Pt loading groups may be attributed to the varying atomic distances between neighboring Pt atoms within the two groups. The shorter atomic distances in the higher loading group increases the likelihood of Pt atom aggregation to minimize surface energy during lasering.

FIGS. 50A-50D demonstrate XRD spectra of metal-incorporated carbon membrane. XRD spectra of carbon membrane with different metal species, including Co (FIG. 50A), Mn (FIG. 50B), Ni (FIG. 50C), and Cu (FIG. 50D). The XRD peaks demonstrate that these metal nitrates can be reduced to metals during the lasering process. These metal salts can be dissolved in sodium borate solutions (0.15 M) at a concentration of 1 wt % at a pH of 5.0. Further laser processing can be performed after impregnating paper substrate in the mixture solutions.

FIGS. 51A-51C demonstrate XRD spectra of metal carbide-incorporated carbon membrane. (a-c) XRD analysis of titanium carbide (FIG. 51A), tungsten carbide (FIG. 51B), and molybdenum carbide (FIG. 51C) synthesized in carbon matrix using salt impregnation and lasering method. The precursors used were titanyl sulfate, phosphotungstic acid, and sodium molybdate (0.5 M).

FIG. 52 depicts HRTEM images of various metal-incorporated carbon membranes. Based on the laser additive manufacturing process with various metal salts, functional metal nanoparticles (Mn, Fe, Co, Ni, Cu, Pd) or carbides (TiC, WC/W₂C, and Mo₂C) can be incorporated into the carbon matrix.

FIGS. 53A-53C depicts templated synthesis of amorphous Si material. FIG. 53A depicts a laser microscopy image of a patterned carbon matrix with deposited crystallized Si through chemical vapor deposition (CVD) method after water-phase transfer onto a quartz slide. FIG. 53B demonstrates Xray diffraction (XRD) spectroscopy of the material, confirming the presence of crystalline Si on the carbon matrix. FIG. 53C depicts SEM images of the amorphous carbon matrix after Si deposition.

FIG. 54 depicts optical characterization of transferred pattern. (Panel a) Laser fabricated serpentine carbon pattern on paper substrate. Scale bar, 4 mm. (Panel b) Floating carbon pattern on water after releasing the paper substrate. Scale bar, 4 mm. (Panel c) Transferred carbon pattern on a glass slide. Scale bar, 4 mm. (Panel d) Laser microscopy image of the transferred serpentine carbon pattern on glass slide, which shows an intimate interface between carbon membrane and the substrate. Scale bar, 1 mm.

FIGS. 55A-55B depict morphology of lasered cellulose substrate before and after membrane delamination. FIG. 55A depicts SEM images demonstrating the morphology of impregnated cellulose paper post-lasering. The impregnation solution had a sodium borate concentration of 0.1 mol/L. The lasering parameters comprised a power of 1.8 W, a speed of 1.6 cm/s, 1000 points per inch, and raster mode. Scale bar: 200 μm. Post-lasering, cellulose fibers were transformed into aligned amorphous microstructures. FIG. 55B depicts optical microscopic image of the cellulose substrate following membrane delamination. The cellulose substrate's highly porous and junction structure remained intact post-delamination, facilitating the repeated formation and isolation of junctions.

FIGS. 56A-56D demonstrate electrochemical characterization of Au and Au—C electrodes. FIGS. 56A-56B demonstrate cyclic voltammetry curves (FIG. 56A) for Au and Au—C electrodes, and their corresponding capacitance (FIG. 56B). FIG. 56C demonstrates electrochemical stability across 3,000 CV cycles within a range of −0.2 to 0.4 V in a phosphate buffer solution (PBS). FIG. 56D demonstrates negligible change in capacitance over 3,000 cycles. These results underscore the high electrochemical stability of the carbon coating on the Au membrane.

FIGS. 57A-57B depict electrode configuration for stimulation and rat leg movement during stimulation. FIG. 57A depicts an optical image showing the integration of five-channel working and counter electrodes on a PET film. FIG. 57B depicts recorded leg movement during stimulation using either Au or carbon electrodes. The stimulation current was applied with a pattern of 1 ms of cathodic current, a 50 μs interpulse silence, 1 ms of anodic current, and a 258 ms pause.

FIGS. 58A-58B demonstrate electromyography (EMG) response of skeletal muscle under stimulation. Recorded EMG signals under different stimulation currents (75, 100, 200, 300, 400, 500, 750, and 1000 μA) using either an Au (FIG. 58A) or a carbon (FIG. 58B) electrode, operating at a frequency of 4 Hz.

FIG. 59 demonstrates EMG signal responses at various stimulation currents. Depiction of EMG peak amplitudes from skeletal muscle under different stimulation currents using either an Au or carbon electrode. Experiments were conducted in 6 replicates.

FIGS. 60A-60D depict design and transfer of carbon-coated Au electrode. FIG. 60A depicts AutoCAD schematics illustrating the serpentine pattern applied for heart stimulation. FIGS. 60B-60D depict fabrication steps, including creation of the serpentine pattern on a filter paper substrate (FIG. 60B), pattern flotation on water (FIG. 60C), and final transfer of the pattern onto an Au film coated on a PET substrate (FIG. 60D).

FIG. 61 depicts changes in ECG signal during heart stimulation. This figure displays representative ECG profiles of an isolated heart either in its normal beating state (Ctrl group) or under stimulation at a frequency of 4 Hz. Stimulation is applied using either an Au or Au—C electrode, with a current density of 4.0 mA/cm².

FIG. 62 demonstrates a threshold of charge injection for Au and Au—C electrodes at different durations. The required charge for successful heart stimulation using different electrodes (Au and Au—C) at different durations. The experiments were conducted in 6 replicates for each condition.

FIG. 63 depicts carbon coating for enhancing multichannel Au electrode performance. The fabrication process involves: (a) fabrication of a multichannel Au electrode (AutoCAD design on the right panel) on a PI substrate with lithography method, (b) transferring two layers of carbon membrane onto a PET substrate, followed by laser cutting to achieve a compatible design, and (c) aligning the EVA-coated carbon pattern with the multichannel electrode, performing hot lamination, and removing any residual material.

FIGS. 64A-64D demonstrate integrated Au-carbon membrane electrode (Au—C) for high-fidelity recording. FIG. 64A depicts optical and microscopic images comparing the Au electrode and the Au—C electrode used for ECG recording. FIG. 64B demonstrates ECG traces recorded from a single heartbeat using two different recording devices. FIG. 64C demonstrates baseline curves of ECG signals recorded with both devices. FIG. 64D demonstrates the signal-to-noise (S/N) ratio calculated from the recorded ECG curves. The Au electrode's S/N ratio increased by 8.0 folds (from 234.7 to 2112.5) after being coated with a carbon membrane. This enhancement in S/N ratio indicates the improved high-fidelity recording capability of the Au—C electrode.

FIGS. 65A-65B demonstrate decomposition of H₂O₂ with different Pt-incorporated carbon membranes. FIG. 65A demonstrates UV-vis absorbance spectra of H₂O₂ solution before and after reaction for 60 min in PBS buffer (1×, pH 7.4). H₂O₂ concentration, 20 mM. Area of membrane: 2 cm². The number in the legends refers to the weight ratio of potassium platinum (II) chloride in sodium borate solution (150 mM, pH=5.0). Cellulose papers were impregnated with the mixture and were transformed into carbon membrane after lasering. The concentration of each material was set at 24 mg/L. No decomposition of H₂O₂ was found when Pt was not present in carbon membrane, indicating that the active components were Pt. FIG. 65B demonstrates an amount of H₂O₂ reacted with membrane after 30 min or 60 min. The concentration of H₂O₂ was quantified according to the absorbance at 240 nm. Experiments were conducted at 37° C. As the precursor concentration increases, the reactivity of the carbon membrane also increases. The carbon membrane's reactivity becomes comparable to that of commercially available Pt/C (10%) particles when the precursor concentration is at 5 wt %.

FIGS. 66A-66B depict pH-dependent catalytic performance of nanozyme membranes for H₂O₂ decomposition. FIG. 66A depicts an image of potassium tetrachloroplatinate and sodium borate mixture solutions at various pH conditions, used for paper impregnation and laser manufacturing. After water-phase separation, catalytic nanozyme membranes were obtained. FIG. 66B demonstrates catalytic performance of each nanozyme membrane toward H₂O₂ decomposition. Reaction parameters: initial H₂O₂ concentration, 20 mM; Membrane size, 1 cm²; Reaction volume, 10 mL. The reaction rate was obtained after averaging the H₂O₂ decomposition in 90 min. These results demonstrate that a pH of 5 is optimal for obtaining a stable mixture solution and achieving reasonable reactivity in the catalytic performance of nanozyme membranes.

FIGS. 67A-67B depict microscopic bubble generation dynamics. FIG. 67A depicts a schematic illustration of the microscopic experiment setup for bubble generation dynamics. Laser-induced Pt/C membrane was broken into particles and deposited on PET. Microscopic observation of the bubble growth process was conducted after the addition of H₂O₂. FIG. 67B depicts microscopic images of growing processes of bubbles generated on different particles. Bubble growth dynamics were classified into three different processes, i.e., single site (I), double sites (II), and multiply sites (III), according to the number of nucleation sites. The bubble radius was plotted as a function of time as R∝t^{1/2}. According to the fitted a value, the least growth constant in the Pt/C membrane is 17.2 m. The growth rate of multiply sites is multiply times of single site.

FIG. 68 depicts size-dependent robotic motion activity. (a) Optical image of circular robots with diameters of 2, 4, 6, 8, and 10 mm. Scale bar, 2 mm. (b) Optical images of the moving robots in 1.0 M H₂O₂ solutions at room temperature, with overlaid trajectories in approximately 500 s. Scale bar, 2 cm. (c) Enlarged trajectory map of each robot over 300 s. Scale bar, 2 cm. The results indicate that as the diameter of the circular robots increases, the displacement also increases.

FIGS. 69A-69F demonstrate quantitative analysis of the motion dynamics of robots. FIGS. 69A-69E demonstrate jumping and coalescence behavior of circular robots with diameters of 2, 4, 6, 8, and 10 mm. FIG. 69F demonstrates the time-dependent displacement of each robot in 300 s.

FIGS. 70A-70C demonstrate shape-dependent motion of robots. FIG. 70A demonstrates motion trajectories of circular, triangle, square, rectangle, pentagon, and hexagon robots in 1.0 M H₂O₂ solution over 1200 s. All robots are regular shapes, except the rectangle with a 2:1 length-to-width ratio. The planar area of each robot is set at 0.5 cm². FIG. 70B demonstrates accumulated displacement of various shaped robots with linearly fitted curves. FIG. 70C demonstrates average velocity (v, cm s⁻¹) of each robot over 800 s, based on triplicate experiments. No clear relationship was observed between motion dynamics and shape.

FIGS. 71A-71F demonstrate H₂O₂ concentration-dependent motion of robots. FIGS. 71A-71E demonstrate jumping and coalescence behavior of circular robots with an 8 mm diameter in different H₂O₂ solutions. FIG. 71F demonstrates time-dependent displacement of each robot. As the concentration of H₂O₂ increases, both the jumping frequency and displacement increase.

FIGS. 72A-72H demonstrate motion behavior of biomimetic robots before and after Hg(II) exposure. FIGS. 72A-72G demonstrate changes in motion dynamics of robots after exposure to different Hg(II) solutions. FIG. 72H demonstrates robot displacement in 1.0 M H₂O₂ solution over time, following exposure to Hg(II) solutions. After exposure, the robot's motion is significantly suppressed, exhibiting decreased jumping frequency and velocity. Lower jumping frequency and velocity are observed with even higher Hg(II) concentrations.

FIGS. 73A-73B demonstrate accelerated degradation of pollutant by robots. FIG. 73A demonstrates absorbance spectra of RhB pollutant under different treatments. The highest removal efficiency was achieved with integrated active motion and pollutant degradation components. FIG. 73B demonstrates time-dependent absorbance of RhB solution under various treatment conditions.

### DETAILED DESCRIPTION

All publications, including but not limited to patents and patent applications, cited in this specification are herein incorporated by reference as though set forth in their entirety in the present application.

As utilized in accordance with the present disclosure, unless otherwise indicated, all technical and scientific terms shall be understood to have the meaning commonly understood by one of ordinary skill in the art. Unless otherwise required by context, singular terms shall include the plural and plural terms shall include the singular.

Throughout this specification, unless the context specifically indicates otherwise, the terms “comprise” and “include” and variations thereof (e.g., “comprises,” “comprising,” “includes,” and “including”) will be understood to indicate the inclusion of a stated component, feature, element, or step or group of components, features, elements or steps but not the exclusion of any other component, feature, element, or step or group of components, features, elements, or steps. Any of the terms “comprising,” “consisting essentially of,” and “consisting of” may be replaced with either of the other two terms, while retaining their ordinary meanings.

As used herein, the singular forms “a,” “an,” and “the” include plural referents unless the context clearly indicates otherwise.

In some embodiments, percentages disclosed herein can vary in amount by ±10, 20, or 30% from values disclosed and remain within the scope of the contemplated disclosure.

Unless otherwise indicated or otherwise evident from the context and understanding of one of ordinary skill in the art, values herein that are expressed as ranges can assume any specific value or sub-range within the stated ranges in different embodiments of the disclosure, to the tenth of the unit of the lower limit of the range, unless the context clearly dictates otherwise.

As used herein, ranges and amounts can be expressed as “about” a particular value or range. About also includes the exact amount. For example, “about 5%” means “about 5%” and also “5%.” The term “about” can also refer to ±10% of a given value or range of values. Therefore, about 5% also means 4.5%-5.5%, for example.

As used herein, the terms “or” and “and/of” are utilized to describe multiple components in combination or exclusive of one another. For example, “x, y, and/or z” can refer to “x” alone, “y” alone, “z” alone, “x, y, and z,” “(x and y) or z,” “x or (y and z),” or “x or y or z.”

### I. OVERVIEW

In general, the present disclosure relates to a roll-to-roll (R2R) apparatus designed for scalable fabrication processes. This apparatus combines precision mechanical components with advanced control software to achieve efficient material processing and electronics fabrication. This document provides a comprehensive description of the apparatus, including its design, assembly, and operational capabilities.

Flexible and sustainable electronics have potential for use in health equipment, wearable devices, the Internet of Things, smart packaging, and other applications. Conventional lithography methods are not conducive to large-scale flexible electronics production, as they are costly, time-consuming, environmentally hazardous, and incompatible with flexible substrates. The R2R fabrication disclosed herein addresses these limitations by enabling continuous, cost-effective manufacturing of electronics on flexible substrates.

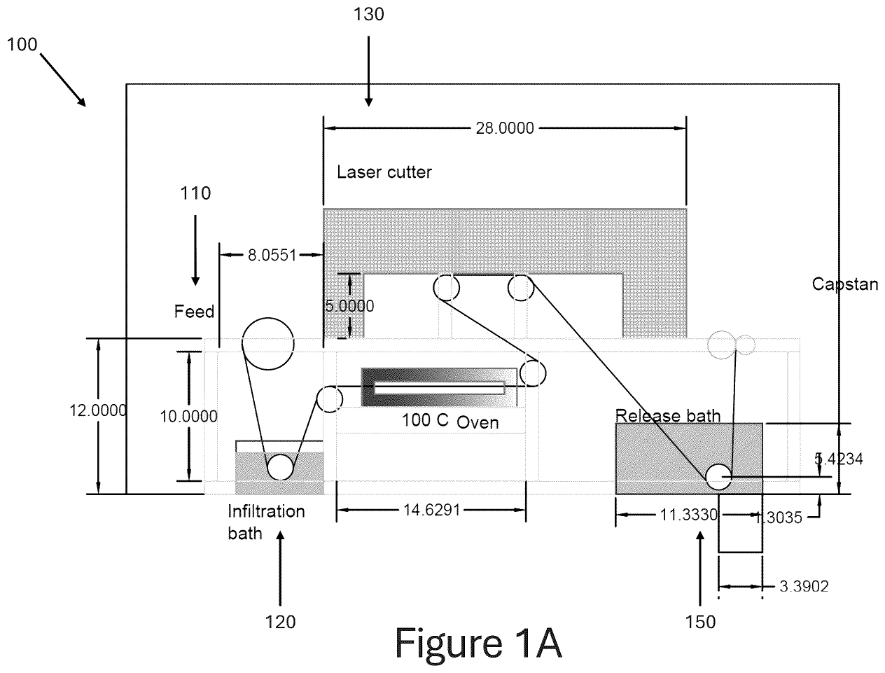

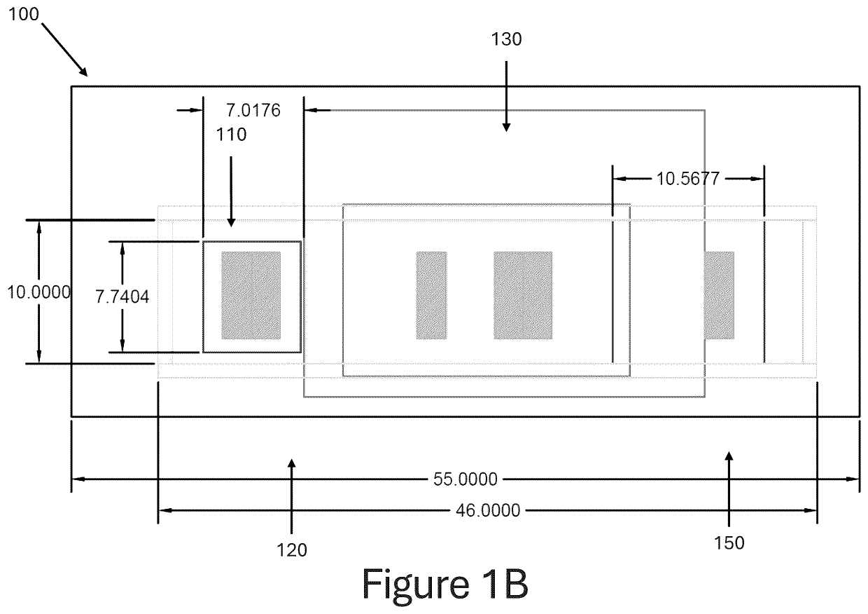

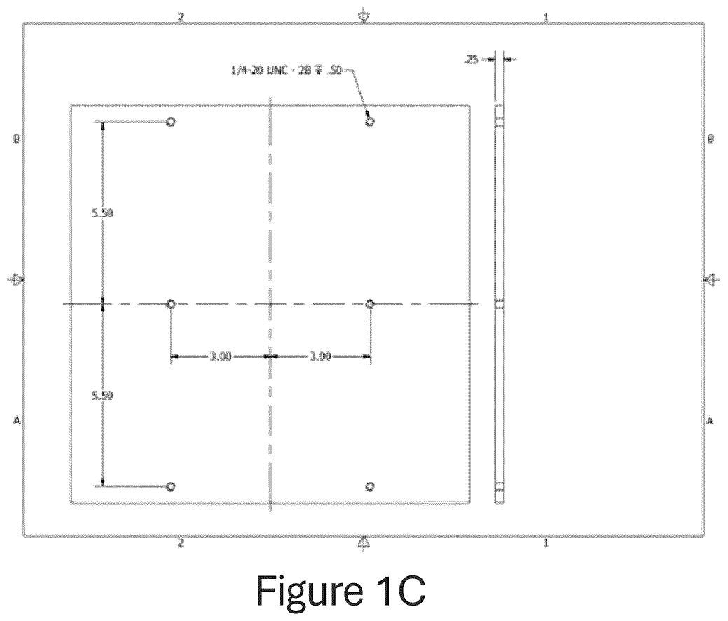

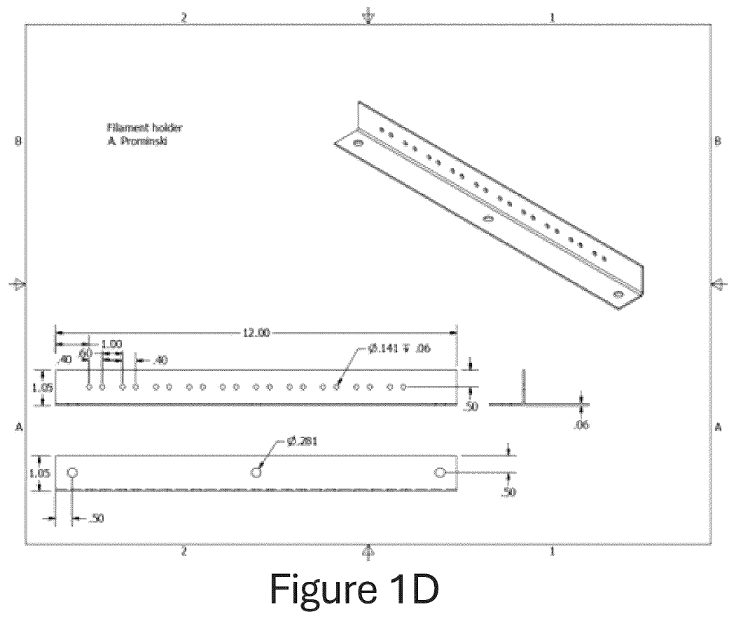

Integrated with a permeable junction-based microfabrication strategy as disclosed here, this disclosure provides a novel R2R apparatus and method for the scalable fabrication of economical, flexible, and sustainable electronics. The apparatus comprises multiple interconnected modules, including a substrate handling module, an infiltration module, a patterning module, and a post-processing module, strategically arranged to enable continuous photochemical patterning and transfer of electronic devices on flexible substrates. The apparatus's design is detailed in FIGS. 1A-1B. Among the many components, additional design files for the heating plate and filament holder are listed in FIGS. 1C-1D to facilitating a comprehensive understanding of its construction and operation.

### II. THE ROLL-TO-ROLL (R2R) APPARATUS AND ASSOCIATED METHODS

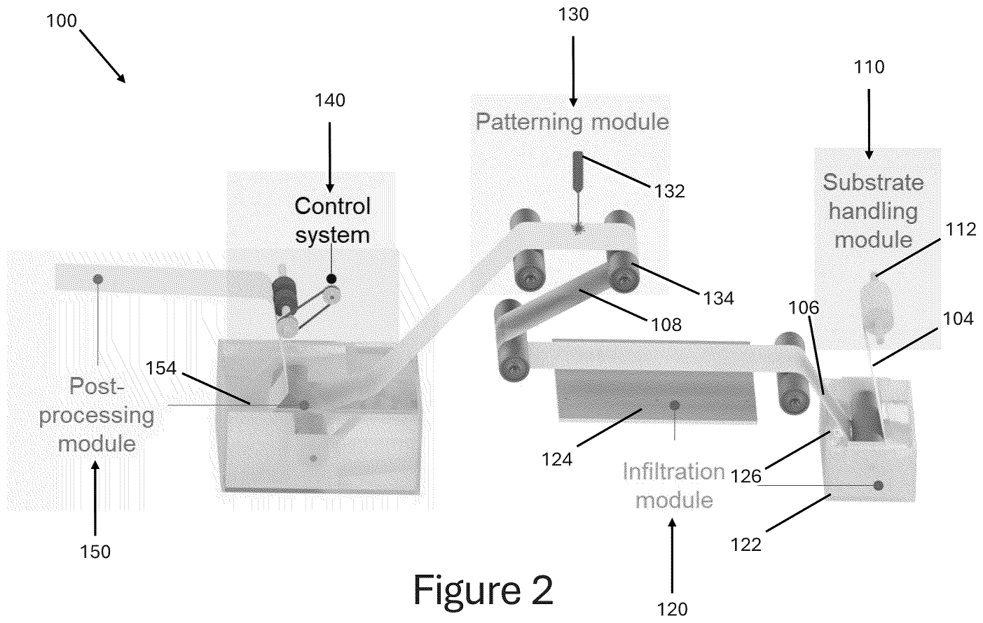

In some embodiments, a R2R apparatus is disclosed, such as the R2R apparatus 100 shown in FIGS. 1A-1B and FIG. 2. The R2R apparatus comprises a substrate handling module 110, an infiltration module 120, a patterning module 130, a control system 140, and a post-processing module 150.

In the R2R apparatus 100, the substrate handling module 110 consists of a freely moving unwind unit 112, a tension control system 114, and a motor-driven rewind unit 116. The unwind unit 112 accommodates a roll of flexible substrate 102, which is continuously fed into the apparatus 100. The functional rollers are composed of 3 PVC-based conveyor rollers. The rewind unit 116 collects the processed substrate 104 onto a roll. This work employs printing paper, which is environmentally friendly, sustainable, cost-effective, and flexible. The apparatus 100 includes a paper supply roll with a width of about 3 cm to about 100 cm. In some embodiments, the paper supply roll has a width of about 3 cm to about 10 cm. In an embodiment, the paper supply roll has a width of about 6 cm. The paper is fed through a set of idler rollers and pulled using a capstan roll driven by a stepper motor, ensuring precise and controlled material movement. During the continuous running, a tension control mechanism 114 and alignment system 118 are used to maintain optimal substrate tension throughout the process, preventing wrinkles, stretching, or misalignment.

In the R2R apparatus 100, the infiltration module 120 includes an infiltration bath 122 and a heater assembly 124. The infiltration module 120 is responsible for depositing various functional salts onto the substrates. As disclosed herein, to ensure complete salt impregnation, a concentrated sodium borate (Na₂B₄O₇, 0.15 M) solution was used in a predesigned sink 126 of the infiltration bath 122 following the substrate feeding module 110 to create the impregnated substrate 106. This module can accommodate a wide range of functional materials, including but not limited to functional salts, conductive inks, semiconducting polymers, dielectric materials, and encapsulation layers, for example. Although the current disclosure provides a salt-impregnation process, the methods disclosed herein can be compatible with a different deposition technique, such as for example, slot-die coating or spray coating. Following the infiltration bath 122, the apparatus 100 incorporates a heater assembly 124 comprising a Joule heater assembled from resistive wire and enclosed in high-temperature fiberglass sleeving. This heater assembly 124 provides electrical insulation and is powered by a benchtop AC-AC converter connected to a standard North American 110 VAC electrical grid. Based on the rolling speed, the operation voltage was optimized to facilitate complete substrate drying. The processed substrate 104 is fed into the infiltration module 120, and a coated substrate 108 is produced by the infiltration module 120.

In the R2R apparatus 100, the patterning module 130 includes an ablation machine 132 and control software integrated with a stepper motor integrated into an Arduino board to control the ablation machine 132. The patterning module 130 enables the precise definition of electronic features on the coated substrate 108. The patterning module 130 includes the ablation machine 132, such as a laser machine (K40 CO₂ laser) for creating conductive carbon/graphene patterns on the pretreated paper substrates. With a continuous nitrogen (N₂) flow serving as the protective atmosphere, a high-power CO₂ laser is employed to selectively transform cellulose-based materials into conductive carbon/graphene patterns. The apparatus 100 is controlled by Python scripts and coordinated with a stepper motor integrated into an Arduino board. The control software, based on the K40 Whisperer source code, was modified to allow control of the roller stepper motor and execute sequential pre-programmed ablation at the ablation machine 132. An alignment system 134, integrated with the ablation machine 132, allows for the coordination of rolling, patterning, and pausing. In an embodiment, this disclosure provides a laser patterning technique, but the method can also be extended to various other techniques, such as for example, photolithography, screen printing, and blade coating, to create patterns for electrodes, transistors, and other electronic components.

In the R2R apparatus 100, the control system 140 includes a central controller 142, an ablation controller 144, a raster 146, and a user interface 148 for managing rolling and patterning processes of the R2R apparatus The control system 140 coordinates the operation of different modules, such as operation of the substrate handling module 110, the impregnation module 120, the patterning module 130, and the post-processing module 150. The control system allows for precise regulation of substrate feeding speed, impregnation time, patterning design, and post-processing conditions to achieve uniform and high-quality flexible electronic devices.

In the R2R apparatus 100, the post-processing module 150 includes a performance testing device 152 and a water-phase transfer device 154. The post-processing module 150 consists of multiple steps for performance testing, encapsulation, and water-phase transfer of the fabricated electronic devices. Product tests include key parameters, such as resistance and Raman spectral characteristics, to ensure the quality of the fabricated electronics. The performance testing device 152 is configured to test parameters of fabricated electronic devices created out of the flexible substrate 102 through processing at the substrate handling module 110, the impregnation module 120, and the patterning module 130. The post-processing module 150 is configured to separate fabricated electronic devices from the remainder of the coated substrate 108 after processing at the substrate handling module 110, the impregnation module 120, and the patterning module 130. The water-phase transfer device 154 is configured to transfer the fabricated electronic devices from the remainder of the coated substrate 108 after processing at the substrate handling module 110, the impregnation module 120, and the patterning module 130.

In some embodiments, the post-processing module 150 further includes an encapsulation device, or a hot pressing device, that can be used for encapsulating the conductive patterns within the polymer matrix.

An example method of using the R2R apparatus 100 for continuous production of carbon/graphene-based electronic devices includes impregnating a paper roll substrate with a sodium borate salt solution or mixed sodium borate/metal salt solutions to create an impregnated substrate 106 at the infiltration module 120 of the R2R apparatus 100, drying the impregnated substrate to form the coated substrate 108 at the infiltration module 120 of the R2R apparatus 100, laser fabricating electronic patterns on the dry impregnated, coated substrate 108 at the patterning module 130 of the R2R apparatus 100, delaminating the electronic patterns from the impregnated, coated substrate 108 with a triggering agent at the post-processing module 150 of the R2R apparatus 100, and transferring the delaminated electronic patterns from the impregnated, coated substrate 108 onto a transparent PET substrate or other polymer film at the post-processing module 150 of the R2R apparatus 100. In some embodiments, the R2R apparatus 100 is configured to operate at variable rolling speeds, rastering speeds, heating voltages, and/or sequencing timings. In various such embodiments, delaminating the electronic patterns from the impregnated, coated substrate 108 with the triggering agent at the post-processing module 150 of the R2R apparatus 100 further includes utilizing water as the triggering agent to accelerate delamination efficiency during the separation of the electronic patterns from the impregnated, coated substrate 108. Further, in various such embodiments, transferring the delaminated electronic patterns from the impregnated substrate onto the transparent PET substrate or other polymer film at the post-processing module 150 of the R2R apparatus 100 includes a permeable junction strategy that improves transfer efficiency from the impregnated, coated substrate 108 onto the transparent PET substrate or other polymer film. In some embodiments, the polymer film includes polyethylene, polypropylene, nylon, polyester, cellulose acetate, cellophane, polytetrafluoroethylene (PTFE), polyethylene terephthalate (PET), and the like. In some embodiments, the transparent PET substrate or other polymer film is a 2D substance. In other embodiments, the transparent PET substrate or other polymer film is a 3D substance.

The permeable junction strategy incorporated into the R2R apparatus improves transfer efficiency by utilizing structure modulation to employ the microscale or nanoscale junctions on the interface for fast solvent penetration, thereby facilitating the creating of conductive pattern and accelerating the delamination/transfer speed.

### III. DEVELOPMENT OF THE R2R APPARATUS AND ASSOCIATED METHODS

### Construction of the Hardware and the Software Components

The machining and assembly of the hardware of the R2R apparatus were conducted at the University of Chicago MRSEC Student Machine Shop. Table 1 lists part of the materials for constructing the R2R hardware. The machining process includes cutting the aluminum frame, refurbishing the laser cutter, and polishing the edges to ensure the precision and quality of the apparatus. It is important to note that the machining process involves working with heavy-duty machinery for tasks such as cutting, and polishing, which necessitate considerable experience. Given the nature of the heavy-duty equipment involved, safety is a paramount concern, and operators must adhere strictly to the Standard Operating Procedures (SOP).

TABLE 1
Lists of materials for constructing the R2R hardware.

| | | | Unit of |
|---|---|---|---|
| Line | Description | Quantity | Measure |
| 1 | 1.9″ Diameter Abrasion-Resistant | 7 | Each |
| | Conveyor Roller PVC Plastic, for 9″ | | |
| | Between Frame Width | | |
| 2 | Fiberglass High-Temperature Sleeving | 2 | Each |
| | 1/16″ ID, 100 Feet Long | | |
| 3 | Neoprene Roller Drive, Aluminum Hub, | 1 | Each |
| | 1-½″ Roller Diameter, 1″ Roller Width | | |
| 4 | Linear Motion Shaft 1566 Carbon Steel, | 2 | Each |
| | ½″ Diameter, 10″ Long | | |
| 5 | Timing Belt Pulley L Series, Press-Fit, | 1 | Each |
| | ½″ Maximum Belt Width, 2.156″ oD | | |
| 6 | Timing Belt Pulley XL Series, 1.12″ oD | 1 | Each |
| 7 | Linear Motion Shaft 1566 Carbon Steel, | 1 | Each |
| | ¼″ Diameter, 10″ Long | | |
| 8 | XL Series Timing Belt Trade No. | 1 | Each |
| | 120xL037 | | |
| 9 | Alloy Steel Cup-Point Set Screw Black | 1 | Pack of |
| | oxide, 8-32 Thread, ⅛″ Long | | 100 each |
| 10 | Alloy Steel Cup-Point Set Screw Black | 1 | Pack of |
| | oxide, 10-32 Thread, ¼″ Long | | 100 each |
| 11 | Alloy Steel Cup-Point Set Screw Black | 1 | Pack of |
| | oxide, ¼″-20 Thread, ¼″ Long | | 50 each |
| 12 | White Delrin ® Acetal Resin Sheet ⅛″ | 1 | Each |
| | Thick, 12″ × 24″ | | |
| 13 | Clear Scratch- and UV-Resistant Cast | 2 | Each |
| | Acrylic Sheet 24″ × 36″ × ¼″ | | |
| 14 | Structural Sealant 3M Hybrid Polymer 760 | 1 | Each |
| | UV, 9.8 oz. Cartridge, White | | |
| 15 | Caulk Gun for 10-13 oz. Cartridge, 10:1 | 1 | Each |
| | Thrust, Skeleton Frame | | |
| 16 | Multipurpose 6061 Aluminum ¼″ | 1 | Each |
| | Thick × 12″ Wide, 1 Foot Long | | |
| 17 | Multipurpose 6061 Aluminum Sheet | 1 | Each |
| | 0.063″ Thick, 12″ × 12″ | | |
| 18 | 18-8 Stainless Steel Button Head Hex | 1 | Pack of |
| | Drive Screw ¼″-20 Thread Size, | | 50 each |
| | ¼″ Long | | |
| 19 | T-Slotted Framing Single 4-Slot Rail, | 4 | Each |
| | Silver, 1″ High × 1″ Wide, Solid, | | |
| | 10′ Long | | |
| 20 | K40 CO₂ laser | 1 | Each |
| 21 | Silver Corner Bracket 1″ Long for 1″ | 60 | Each |
| | High Rail T-Slotted Framing | | |
| 22 | T-Slotted Framing End-Feed Single Nut | 15 | Packs of |
| | with Button Head ¼″-20 Thread Size | | 4 each |

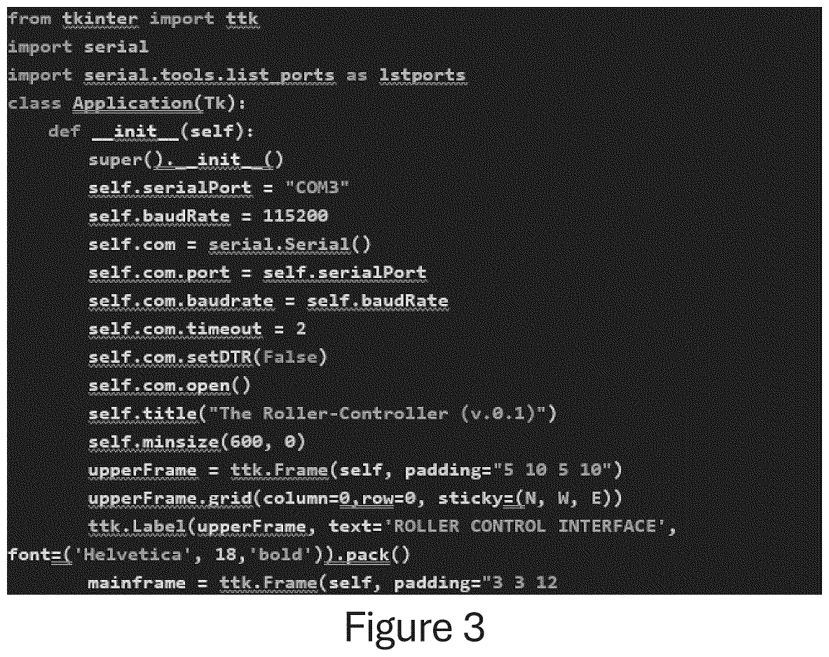

To enhance communication and streamline the fabrication process, a software interface on the Windows 10 operating system was developed. This interface was crafted using Python and has been optimized to manage the laser controller interface, regulate engraving speed, oversee roller operations, and facilitate the design of electronic device patterns. (shown in FIG. 3).

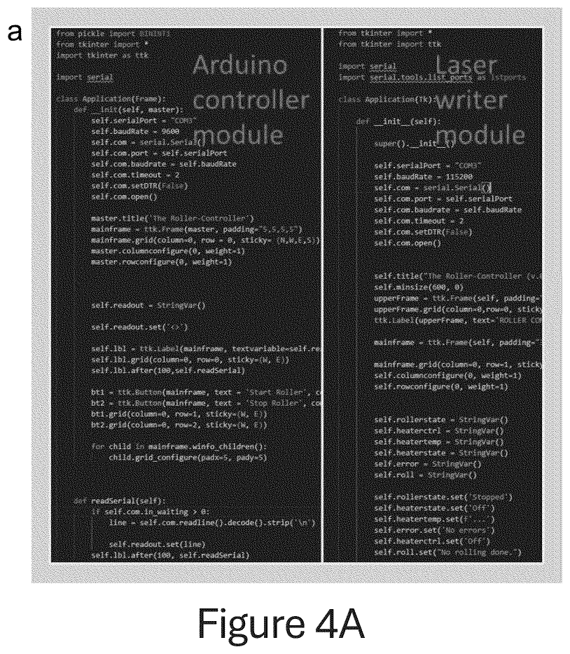

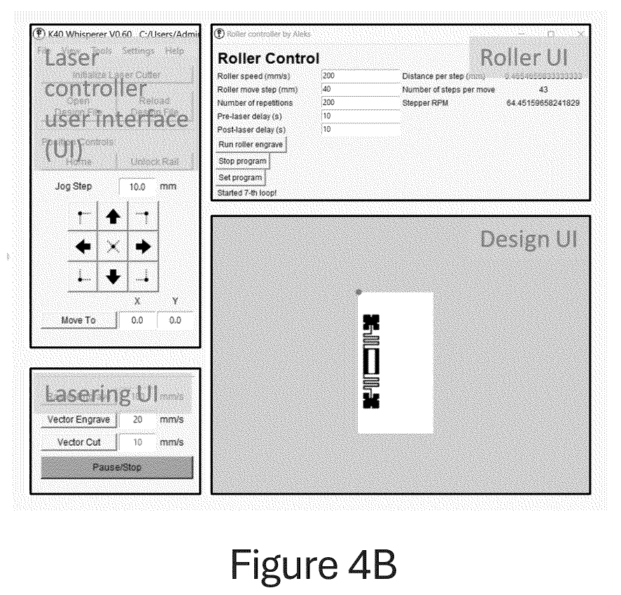

The user interface integrates seamlessly with an Arduino board and control module, enabling precision control of the roller stepper motor and the execution of pre-programmed patterning sequences (See FIGS. 4A-4B). This innovation synchronizes the patterning machinery with the roller control system, offering a versatile platform that can be adapted for use with other techniques such as photolithography, screen printing, and artificial intelligence-driven automated laboratory systems, thereby expanding its commercial applicability, scalability, and intelligent capabilities.

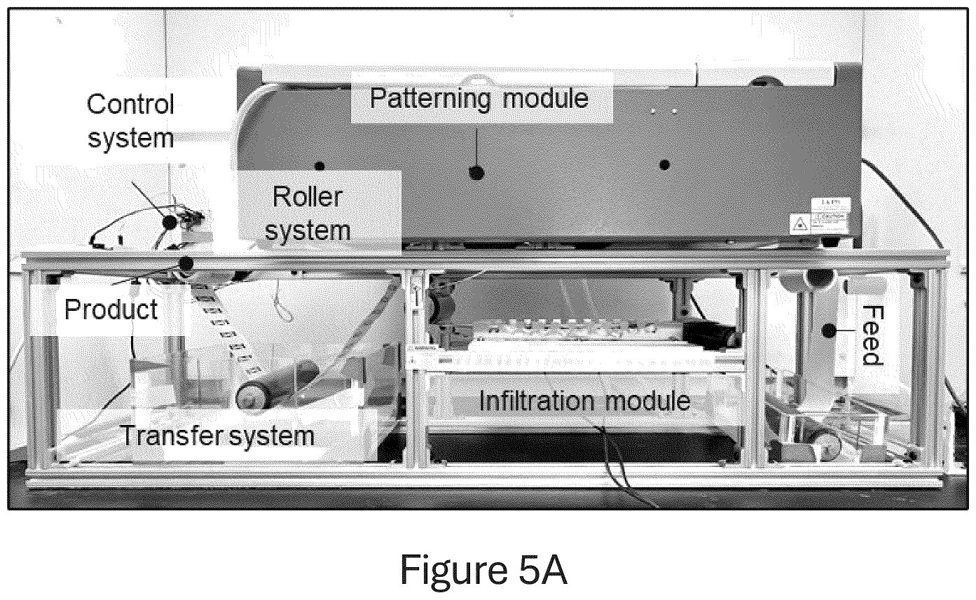

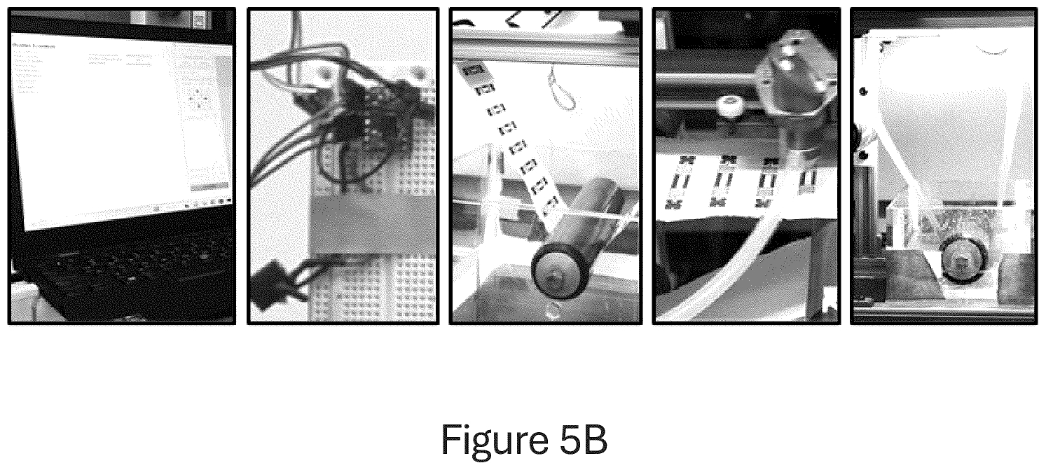

Following CAD design, each component was assembled in a systematic sequence, with the final assembly depicted in FIG. 5A. The modular setup, as viewed from left to right, comprises the product collector, electronic controller, transfer system, roller system, laser scanner, salt-impregnation system, substrate feeding roller, and the computer user interface. Following the assembly, the entire apparatus was subjected to testing under varying conditions such as rolling speed, engraving speed, heating voltage, and sequencing timing. After fine-tuning these parameters, the control system was meticulously adjusted for continuous roll-to-roll production, maintaining consistent device quality. Laser parameters were then further scrutinized based on the conductivity performance and graphene content. FIG. 5B shows Close-up views of the individual modules, featuring the user interface, electronic controller, rolling system, laser patterning, and substrate feeding module (from left to right).

Characterization of the Materials Fabricated using R2R Apparatus

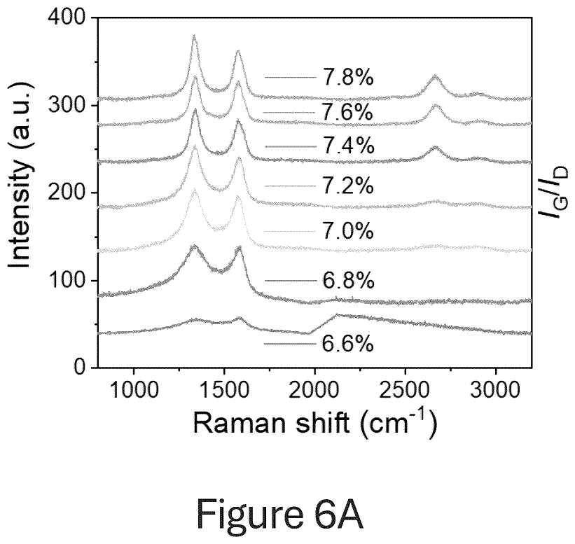

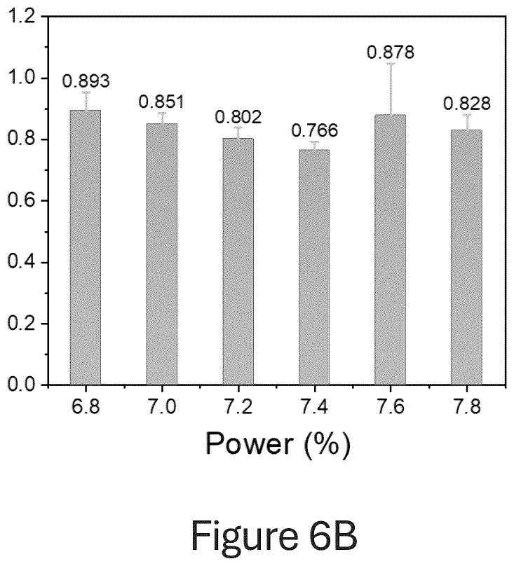

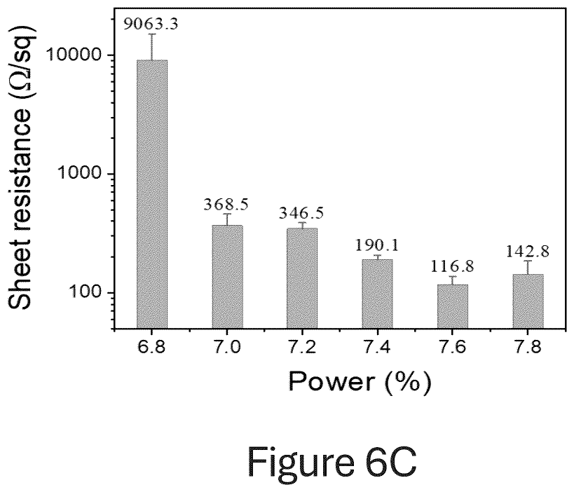

During the roll-to-roll (R2R) fabrication, various parameters were assessed to determine their impact on the quality of patterns, as is shown in FIGS. 6A-6C. The raster speed was maintained at 100 mm/s while the effect of laser power on the patterns was investigated. A minimum of four samples were analyzed using Raman spectroscopy and resistance measurement techniques. Raman characterization revealed that with an increase in laser power, the intensity of the D (˜1335 cm⁻¹), G (˜1580 cm⁻¹), and 2D (˜2665 cm⁻¹) peaks on the carbon surface also increased. The highest I_{G}/I_{D} value of 0.88 was achieved at a power setting of 7.6%. The presence of 2D peaks at power levels above 7.2% suggested graphene formation. The scanning speed remained constant as the power intensity was increased. According to conductivity measurements, the lowest sheet resistance of 116.8 Ω/sq was obtained at a laser power of 7.6%. For subsequent R2R fabrication, the instrumental settings of 100 mm/s speed and 7.2% power were employed.

### INDUSTRIAL APPLICABILITY

The R2R apparatus as disclosed herein successfully achieved continuous production of carbon/graphene-based electronic devices. This capability was demonstrated by fabricating flexible RFID electronic patterns on a paper roll with dimensions of 150 cm×6 cm. This demonstration was conducted on a laboratory scale using short conveyer rollers (9 inches between frame width). However, the method and device can be adjusted for industrial rollers. In some embodiments, the scalability can be extended to accommodate size in the scale of up to about 1 m in width and up to about 100 m long.

The permeable junction strategy, as described herein, has also enabled the transfer RFID electronics onto transparent PET substrates, which can be used for creating adhesive RFID tapes. By employing water as the triggering agent, the permeable junctions significantly accelerate delamination efficiency (˜152 ms) when separating membrane devices from porous interfaces, eliminating the need for environmentally harmful chemicals. The permeable junction strategy provided herein also extends its applicability to 2D film substrates and 3D shapes, enabling the realization of functionalities that previous planar electronics could not achieve. In addition to RFID patterns, the current control and coordination capabilities make it suitable for producing high-quality flexible materials such as sensors, solar cells, superior bioelectronic devices, catalytic robotics, and more.

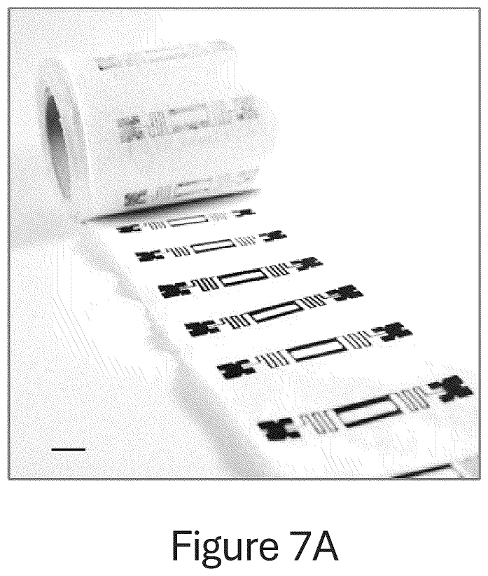

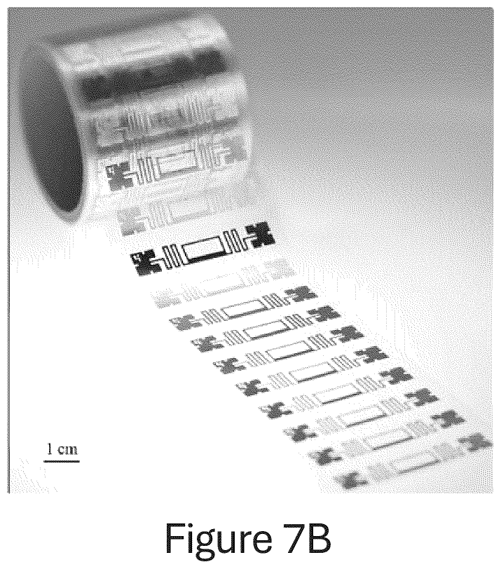

For example, FIGS. 7A-7B depict scalable production and transfer utilizing the R2R apparatus. FIG. 7A depicts an optical image showing fabricated RFID patterns on a 1.5-meter paper sheet. FIG. 7B depicts an optical image of transferred RFID patterns on a 1.5-meter transparent PET roll.

In assessing the commercial viability and scalability of the approach disclosed herein, a cost analysis was conducted based on the materials used and operational expenses associated with the R2R apparatus. The total cost of electronics fabrication was divided into two main categories: material costs and manufacturing costs. For material costs, the method primarily utilizes paper roll (with pricing referenced from www.alibaba.com) and sodium borate salt (≥99.5% purity, sourced from Sigma), priced at $0.5/m² and $0.38/m², respectively, with the latter being based on the actual salt absorbed by the substrate. In this context, the cost of water is considered negligible. The manufacturing process leverages cost-effective techniques such as impregnation, drying, laser fabrication, and transfer within our R2R setup. Based on the R2R trials, the production rate for the RFID pattern is approximately 80 cm² per hour with an operational power consumption of 40 W. With an electricity rate of 16.04 ¢/kWh, the average electrical cost works out to $0.08/m². Consequently, the overall cost to manufacture freestanding carbon membranes is roughly $1/m². This total cost could be further diminished by increasing the engraving speed judiciously.

This streamlined microfabrication process significantly enhances both the production rate (400 cm²/h) and cost-effectiveness (approximately $1/m²) of electronic devices in the roll-to-roll setup, offering superior efficiency and reduced environmental impact compared to conventional methods.

### EMBODIMENTS

This disclosure provides the R2R apparatus and its associated techniques for the efficient and cost-effective production of carbon/graphene-based electronic devices, while seeking protection for the following aspects of the disclosed technology.

In an example embodiment, a roll-to-roll (R2R) apparatus for the continuous production of carbon/graphene-based electronic devices includes a product collector, an electronic controller, a transfer system, a roller system, a laser scanner, a salt-impregnation system, a substrate feeding roller, and a computer user interface. In such embodiments, said apparatus may be configured to operate at variable rolling speeds, rastering speeds, heating voltages, and sequencing timings; alignment for continuous R2R fabrication with consistent device quality. Also, in such embodiments, the method may employ a permeable junction strategy for the facile transfer of electronic patterns onto adhesive plastic films. Further, in such embodiments, the method may utilize water as a triggering agent to accelerate delamination efficiency during the separation of membrane devices from porous interfaces, thereby eliminating the need for environmentally detrimental chemicals. Further still, in such embodiments, the method may extend suitability to 3D shapes, achieving functionalities previously unattainable by conventional planar electronics. In such embodiments, the method may allow in-device nanocatalyst design from single-atom dispersion to nanoparticles, and renewable adhesion and delamination on a single substrate.

In another example embodiment, a method for the continuous production of carbon/graphene-based electronic devices using the R2R apparatus as disclosed herein, comprising the steps of impregnating a paper roll substrate with a sodium borate salt solution or mixed sodium borate/metal salt solutions, drying the impregnated substrate, laser fabricating electronics patterns on the substrate, transferring the electronic patterns onto a transparent PET substrate or other polymer films, and/or utilizing water as a triggering agent for delamination.

### Safety Notes for Construction and Operation

Due to the incorporation of high-powered CO₂ laser and electrical heating plate, specialty for the usage should be taken into consideration. Provided here are a few notes for the construction and operation: Do not operate the equipment in this room without reading the SOP for class 3b and 4 Lasers. Familiarize yourself with the location of the safety goggles and infrared viewer. Do not wear high-reflective (metal) objects such as watches, jewelry, etc. Always wear shoes, preferably with rubber soles. Do not leave laser on and unattended without curtain fully closed and warning sign on. Know the light path and the potential position of the reflections from its mirrors. Do not place flammable materials (plastics, wood, electrical tape, plastic bags etc.) into the laser beam path. Familiarize yourself with the beam power at different points along the light path. Keep the optical table simple, clean, and organized. Do not leave unnecessary optics on the table. Check the position of the laser blocking optics. Whenever possible block undesired beam reflections by using “beam blocks” or beam dumps. Never lower your head to the tabletop level, use chair of appropriate height.

A roll-to-roll microfabrication technology is provided that employs salt-assisted photochemical patterning of carbon-based devices on biopolymer matrices (e.g., cellulose paper, and aerogel) and realize water-phase transfer onto arbitrary substrates. Through rational design of impregnation method, an in-device nanocatalyst design was achieved from single-atom dispersion to nanoparticles, and renewable adhesion and delamination on a single substrate. This microfabrication paradigm offers many promising applications, and the superior performance of our bioelectronic devices relative to traditional bioelectronic leads and sensors was demonstrated. A roll-to-roll apparatus was developed to streamline the microfabrication process, which boosts the production speed (400 cm²/h) and cost efficiency of electronic device (˜$1/m²), surpassing conventional techniques over the efficiency, cost and environmental impacts.

A bioinspired strategy is provided that significantly enhances the stability and transfer potential for scalable fabrication. The method disclosed herein involves the use of various metal ions (Fe(III), Co(II), Cu(II), Zn(II), Mg(II), and borate ions) and an innovative ‘actuator-inhibitor-neutralizer’ system with controllable hygroscopic interactions at permeable junctions. By employing transition metal ions as inhibitors, this effectively suppresses cellulose fiber swelling and increases mechanical strength, thereby improving the stability of patterns in water. During controllable transfer, the approach described herein enables water-phase transfer onto arbitrary substrates, while the permeable junction strategy substantially accelerates the delamination process (152 ms) when separating membrane devices from porous interfaces. The use of water as the solvent eliminates the need for environmentally detrimental chemicals that are commonly employed in conventional microfabrication processes. This work shows promising scalability that our home-built roll-to-roll apparatus is capable of producing electronic products at a speed of 400 cm²/h, all at a very low cost (˜$1/m²). When compared to conventional techniques, this work not only provides an economic microfabrication method, but also enhances fabrication efficiency and significantly reduces environmental impacts. The method disclosed herein can significantly accelerate scalable and environmentally friendly bioelectronic device fabrication.

A method is provided that not only ensures efficient transfer, but also embraces a general approach towards on-demand delamination with minimal environmental impact. This development is particularly noteworthy as it tackles both efficiency and sustainability challenges in the transfer process of devices. To provide a thorough understanding of the peeling-transfer method in device fabrication, a variety of applications were compiled that employ a similar method (based on laser induced graphene (LIG)) for transferring carbon/graphene-based devices from their original substrates (mainly polyimide, PI) to functional substrates for biological and sensing applications (see Table 2).

TABLE 2
Laser-enabled transfer printing method for functional electronics.

| Original | Transfer | Substrate | Fabrication | | | | |
|---|---|---|---|---|---|---|---|
| substrate | substrate | dimension | techniques | Function | Conductivity | | Reference |
| PI | PDMS | Film | Vacuum | Compact sensor | 570 | Ω/sq | Adv. Mat. 34, |
| | | (thickness, | transfer | | | | 2201663 (2022). |
| | | 300 um) | | | | | |
| PI | PDMS | Film | Transfer by | Electrophysiological | 11.0 | Ω/sq | Adv. Mat. 30, |
| | | (thickness, | capillary | sensor | | | 1804327 (2018). |
| | | 500 um) | force | | | | |
| PI | SEBS | Film (143 | Casting and | ECG sensor | N.A. | | npj Flex. Electron. |
| | | um) | peel-off | | | | 6, 11 (2022). |
| PI | SEBS | Film (50 um) | Vacuum | Neurotransmitter | ~2000 | Ω | Nature 606, |
| | | | transfer | sensor | | | 94-101 (2022). |
| PI | PU | Film (50 um) | Casting and | Tactile sensor | N.A. | | ACS Nano 16, |
| | | | peel-off | | | | 6687-6699 (2022). |
| PI | PU | Film | Casting and | EMG sensor | 800 | Ω/sq | ACS Appl. Mater. |
| | | (thickness, ~50 | peel-off | | | | Interfaces 12, |
| | | um) | | | | | 19855-19865 |
| | | | | | | | (2020). |
| PI | Hydrogel | Film | Cryogenic | Multifunctional | 62.3 | Ω/sq | Nat. Electron., |
| | | (thickness, ~11 | transfer | sensor | | | (2023). |
| | | um) | | | | | |
| Paper | Various | From 2D to | Water- | Multiple | 43.6 | Ω/sq | This work |
| | substrates | 3D | enabled | functions | | | |
| | | | transfer | | | | |

Abbreviations: PI, polyimide; PDMS, polydimethylsiloxane; SEBS, styrene-ethylene-butylene-styrene; PU, polyurethane; ECG, electrocardiogragh; EOG, electrooculography; EMG, electromyogram.

The conventional LIG transfer method typically involves a three-step process: elastomer casting, curing, and peeling off. This method generally requires a thick elastomer coating (over 50 μm) for effective infiltration and transfer. In contrast, the approach described herein enables facile delamination aided by water, allowing for transfer onto a wide range of substrates with varying thicknesses in both 2D and 3D forms. Additionally, the method disclosed herein mitigates the mechanical transformation issues observed in LIG pattern transfer, where peeling off the PI substrate can compromise the conductivity of the LIG pattern. This strategy of water-enabled swelling of cellulose fibers offers a gentler delamination process, thereby preserving the performance of the electrodes. The use of water, a green solvent, not only enhances the sustainability of the process but also, through our permeable junction strategy, significantly improves transfer efficiency. Compared with the recent work that cryogenically transfers carbon pattern to a hydrogel film, the method disclosed herein provides a much easier fabrication process without any cooling or casting procedures. The feasibility of creating adhesive hydrogels also suggests potential uses in long-term wearable sensors for on-skin monitoring and cardiac patches for in vivo detection.

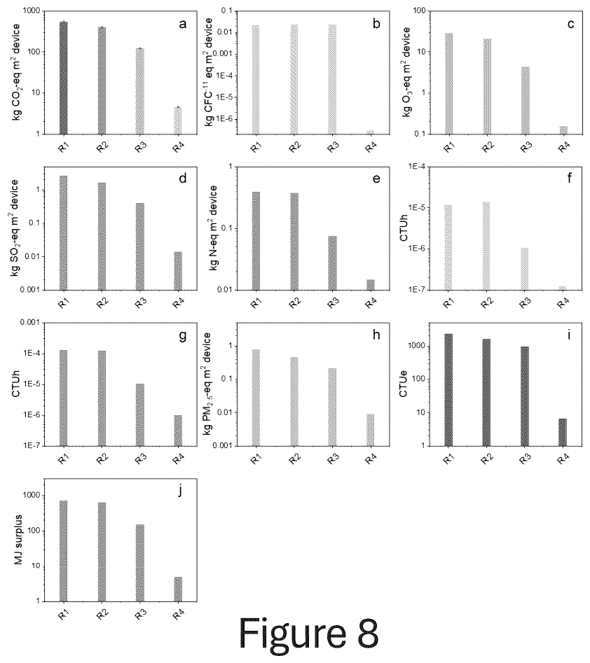

The global urgency to transition toward sustainable industries with reduced carbon emissions or carbon neutrality is growing. While significant efforts have been made to enhance microfabrication techniques, the environmental impacts of these advancements remain largely unexamined. Therefore, a comparative life cycle analysis (LCA) was conducted of the technique described herein against conventional microfabrication methods for carbon-based devices, including CVD+lithography methods, pyrolysis+lithography method, and lasering+casting method based on their system boundaries. LCA results indicate (see FIG. 8) that the greenhouse gas (GHG) emissions for device fabrication by our proposed method are significantly lower (4.56 kg CO₂ eq) compared to pyrolysis (537.04 kg CO₂ eq), CVD (397.47 kg CO₂ eq), and lasering (124.55 kg CO₂ eq) methods, within a 95% confidence interval. In our method, the primary sources of GHG emissions are energy consumption, contributing to 3.67 kg CO₂ eq, and gas usage, adding 0.36 kg CO₂ eq. The utilization of sustainable paper substrates and the simplified fabrication and delamination processes significantly reduce the carbon footprint. Conversely, traditional methods involving materials and chemicals like Si wafers, epoxy, photoresist, etchants, organic solvents, and substantial energy consumption, lead to much higher environmental burdens. Furthermore, our method also demonstrates the lowest environmental impact in areas such as resource consumption, effects on terrestrial ecosystems, acidification, and human health.

The methods and devices as disclosed herein exceed existing technologies in terms of transfer speed, functionality, adaptability, and sustainability, and show significant innovations and advantages for bioelectronics fabrication.

### IV. BACKGROUND TO THE DEVELOPMENT OF THE R2R APPARATUS AND ASSOCIATED METHODS

### Overview

As discussed above, microfabrication—the process of fabricating small structure usually in micrometer scale—has wide practical applications but confronts sustainability challenges due to the substantial chemical and energy consumption during the patterning and transfer stages. Here, a bioinspired permeable junction approach is introduced, involving patterning on biopolymer matrices with a salt-assisted photochemical synthesis, to advance sustainable microfabrication. This approach leverages an ‘actuator-inhibitor-neutralizer’ process for on-demand adhesion and delamination. Utilizing water as a green actuation agent, our method realizes instantaneous delamination (<1 s) for patterned device transfer, far exceeding the efficacy of traditional technologies. This advancement boosts the roll-to-roll production speed, and minimizes the consumption of energy and hazardous chemicals. The combination of sustainable substrates and hazards-free processing has substantially lower greenhouse gas emissions and reduced environmental impacts for device fabrication, compared with traditional microfabrication methods. This approach is widely applicable to various device fabrication processes, ranging from bioelectronic devices to catalytic robotics. Overall, this work addresses the sustainability challenges of microfabrication, paving the way to environmentally friendly device fabrication.

Microfabrication holds great promises for transforming sectors from healthcare to electronics; however, it faces substantial environmental challenges, including high chemical usage, energy consumption, and related greenhouse gas (GHG) emissions. Microfabrication necessitates complex steps such as photolithography, deposition, and transfer, which involve extensive use of hazardous chemicals like etchants, organic solvent, and fluorinated gases. The industry's reliance on such chemicals results in nearly 1 billion cubic meters of etchants being consumed annually, with a projected global annual growth rate of 6.2%. Additionally, the dependence of microfabrication on nonrenewable resource-based materials, from silicon or metal-based substrates to petroleum-derived polymers, magnifies its persistent environmental impact. Energy use is also a critical issue, with semiconductor microfabrication industry alone accounting for approximately 1.5% of the industrial electricity usage in the United States. Overall, the life cycle of microfabrication not only poses environmental burden in terms of hazardous chemical use but also intensifies global carbon footprints through the energy intensive procedures.

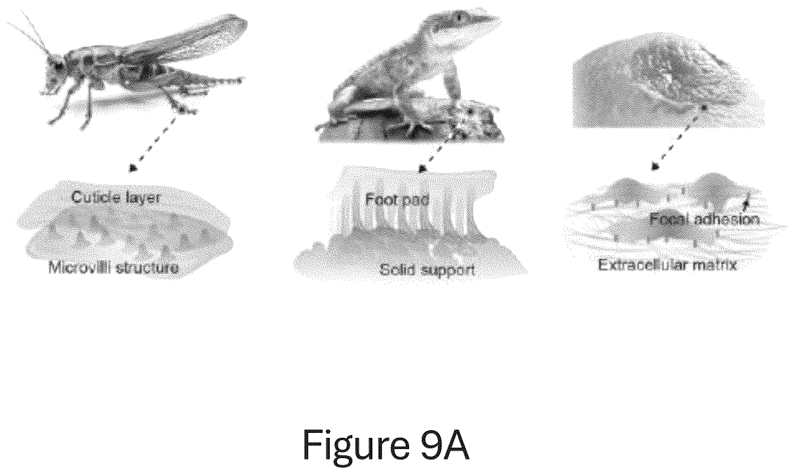

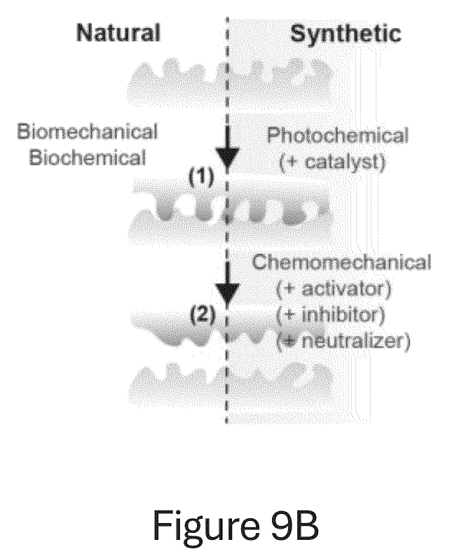

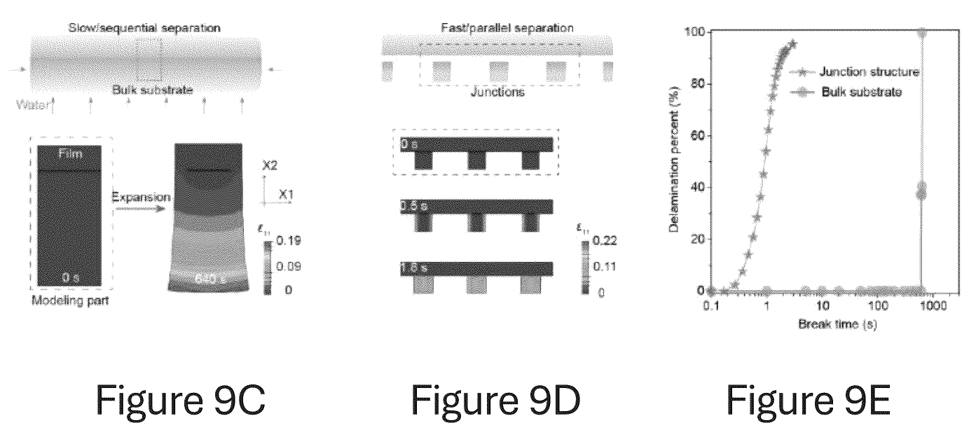

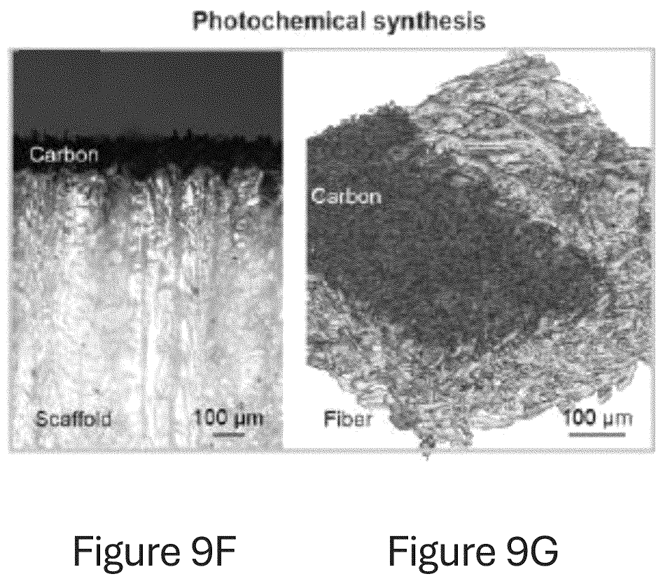

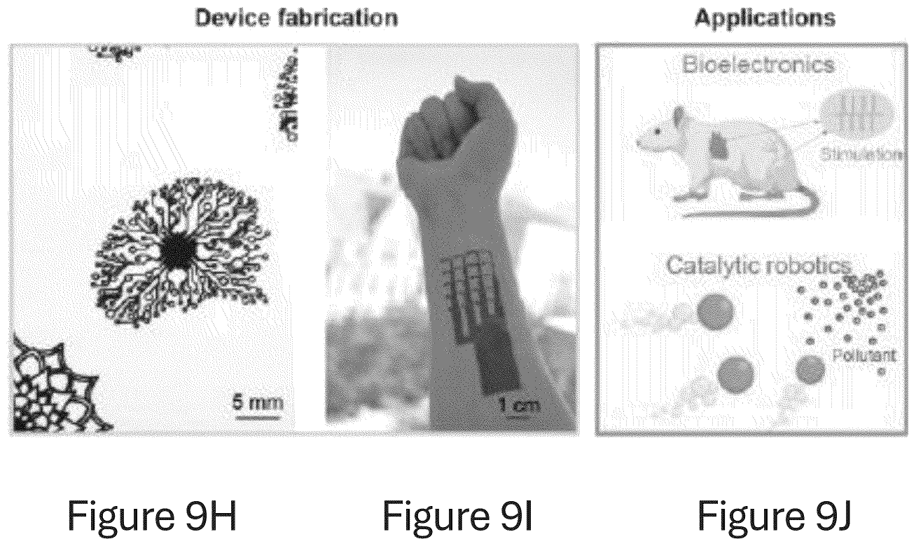

Application of green engineering principles to maximize mass, energy, space, and time efficiency could potentially lead to significant environmental benefits for microfabrication. Conventional photolithography relies on photochemical reactions to pattern photoresist, which is resource-intensive both in terms of chemicals and energy. Reviving the subtractive processes through additive patterning could streamline fabrication procedures. Conventional patterning also requires a robust interfacial bond for adhesion, and hence involves the use of harsh chemical or complex procedures during lift-off and transfer phases. Striking a balance between strong adhesion for patterning and ease of delamination for transfer is crucial for developing sustainable and efficient microfabrication techniques. Achieving this would eliminate the need for external etchants and allows for the reuse of preparation substrates, thereby minimizing waste. Interestingly, natural organisms exhibit on-demand adhesion and detachment behaviors through intricate junction structure. For example, locusts grow and shed protective exoskeletons during ecdysis through microvilli architecture (FIG. 9A, left), geckos swiftly move on vertical walls through microscale junctions (FIG. 9A, middle), and keratinocyte cells migrate across wounds through focal adhesion (FIG. 9A, right). These natural mechanisms utilize specialized tiny junction structures, categorized as either permeable or ‘focal’, for on-demand adhesion and detachment (FIG. 9B). Harnessing permeable junction strategy from natural systems may offer efficient pathways for material patterning and delaminating, thereby enhancing the sustainability of microfabrication methodologies. A bioinspired permeable junction approach for sustainable microfabrication was targeted to be developed. A salt-assisted photochemical process was first proposed (FIG. 9B, right) for direct patterning of device on biopolymer substrates. Microscale junction structures were then constructed with aerogel and cellulose paper, and utilized water to generate chemo-mechanical force for sustainable and efficient delamination. The elimination of the use of hazardous chemicals and reduction in energy consumption makes this method as a universal platform for sustainable microfabrication. Given the eco-friendly and scalable advantages, this work holds promise for diverse device applications, including bioelectronics and robotics.

### Results—On-Demand Pattern and Delamination of Device

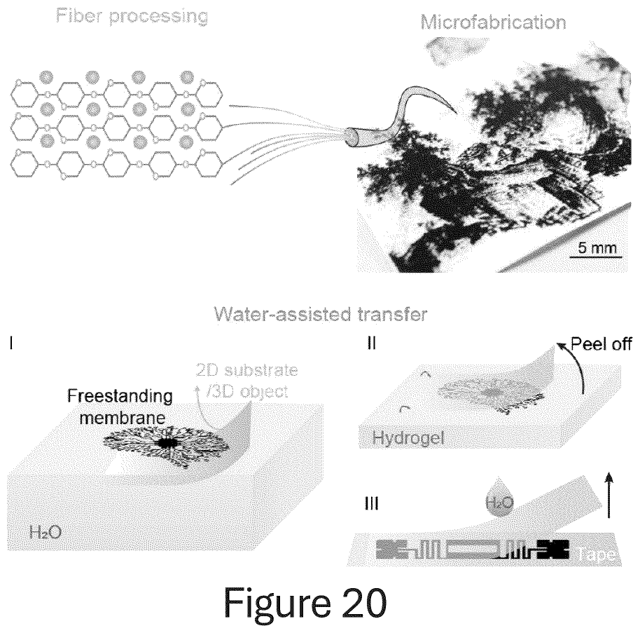

In some embodiments, it was demonstrated theoretically that when mechanical force prompts strain mismatches, permeable junctions resulted in fast delamination on the interface (FIGS. 9C-9E & Example 1), Simulations using the cohesive zone model reveal permeable junctions significantly decrease delamination time from ˜640 s (nonporous substrates) to ˜2 s (FIG. 9E). This technique enables streamlined patterning (FIGS. 9F-9H) and transfer of device onto various surfaces, like 3D objects, tapes, and hydrogels for diverse applications (FIGS. 9I-9J & FIG. 20).

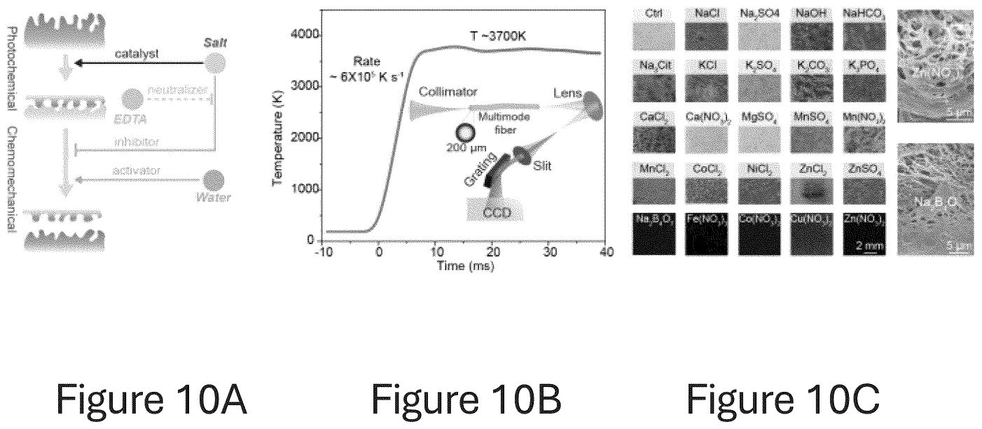

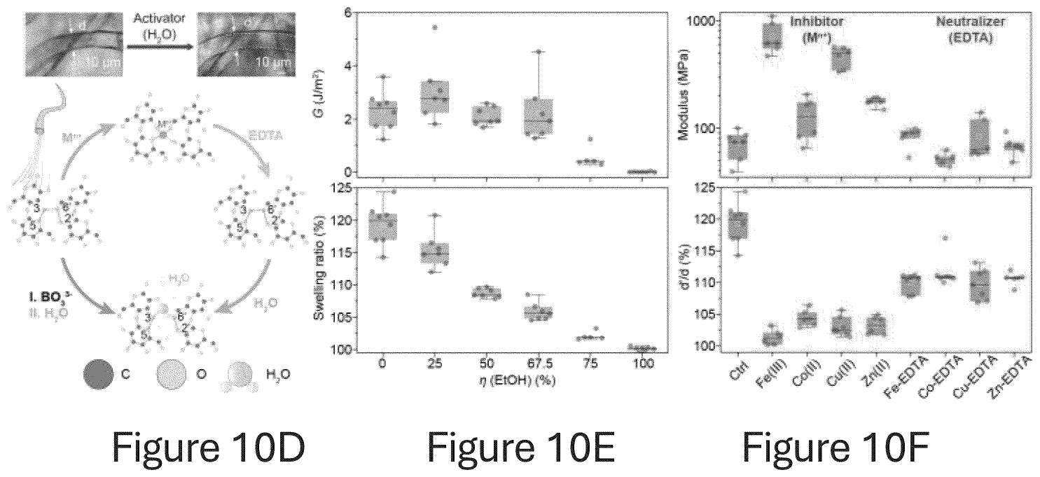

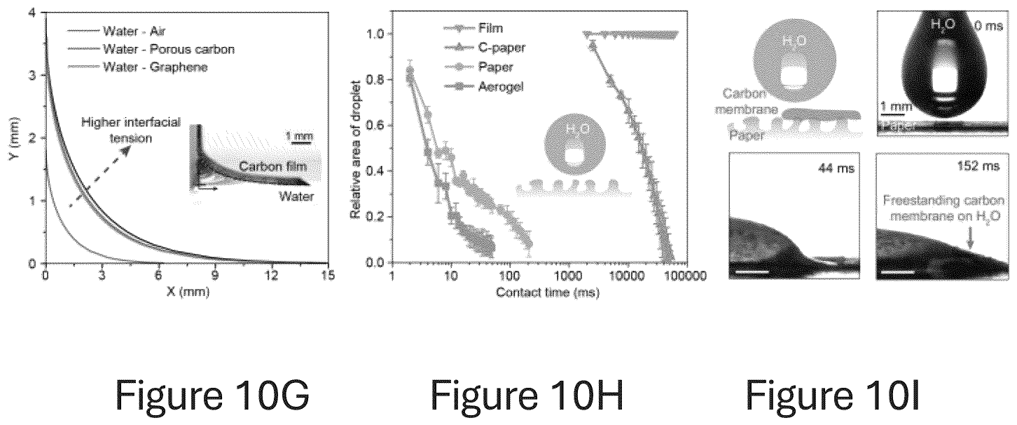

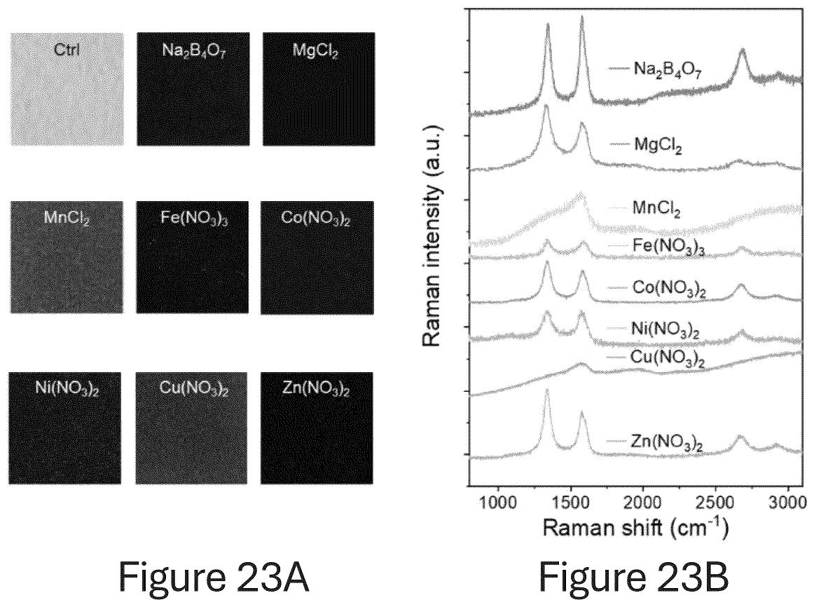

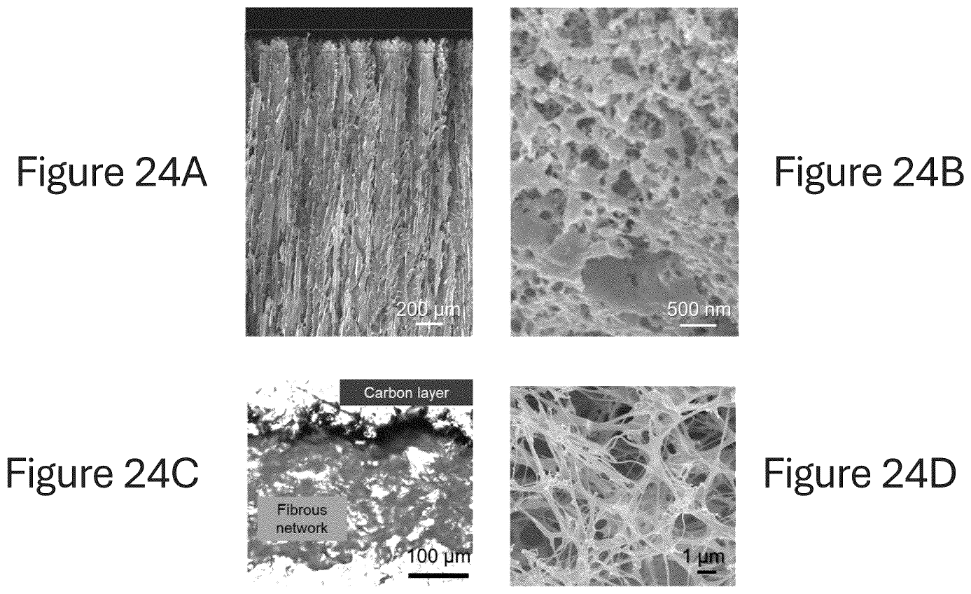

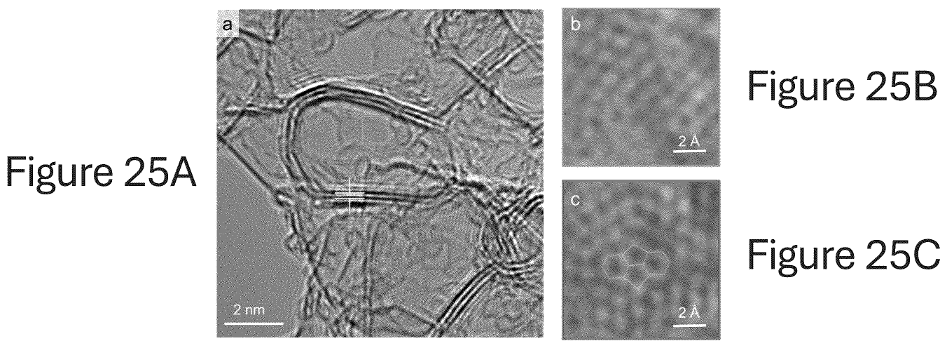

Polymer-based substrates from renewable biomaterials can emulate the strain propagation of biological tissues for biomimetic patterning and delamination. The potential of direct patterning and delamination of devices on natural polymer substrates was explored, as illustrated in FIG. 10A. A well-established, CO₂ laser-based photochemical process was deployed for device patterning (FIGS. 10A-10C & Example 2). However, the low char production of biopolymer at high temperatures hinders graphitization. To overcome this, various salts were employed for catalyzing the photochemical synthesis, including Na₂B₄O₇, MgCl₂, Fe(NO₃)₃, 80 Co(NO₃)₂, and Zn(NO₃)₂ (FIG. 23). Sodium borate was utilized as the catalyst to evaluate the synthesis conditions. The transient laser irradiation induces a localized temperature shock of 3700 K at the focal point (FIG. 10B). The temperature acceleration averaged around 6.2×10⁵ K/s under a critical laser energy of 11.2 mJ. The presence of sodium borate significantly enhanced the graphene yield under the ultra-high temperature condition. Raman spectroscopy confirmed the formation of graphene, indicated by distinctive peaks: the G peak (˜1,580 cm⁻¹) and the 2D peak (˜2,700 cm⁻¹) (FIG. 23). Transmission electron microscopy (TEM) revealed an average lattice spacing of approximately 3.5 Å, indicating turbostratic graphene structures (FIG. 25). This approach allowed the in-situ formation of semi-crystalline carbon membranes on various hydrophilic scaffolds, such as sodium carboxymethyl cellulose (CMC), cellulose, sodium alginate, and agar.

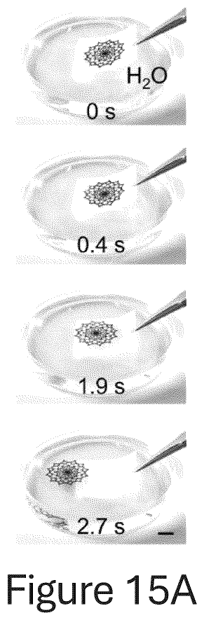

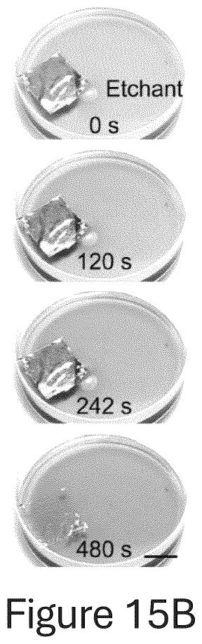

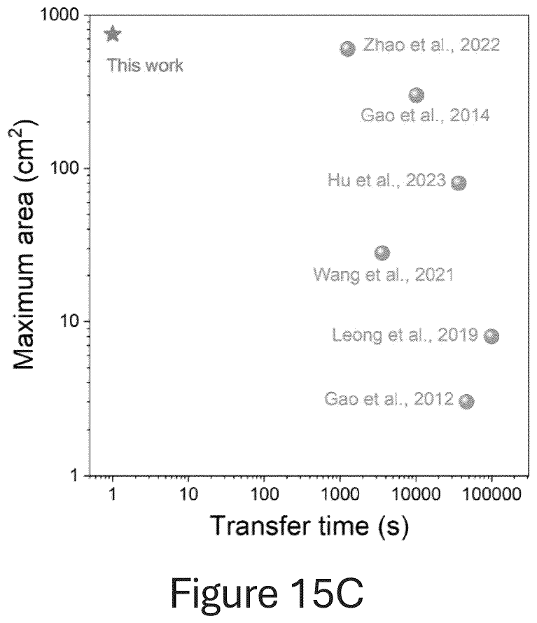

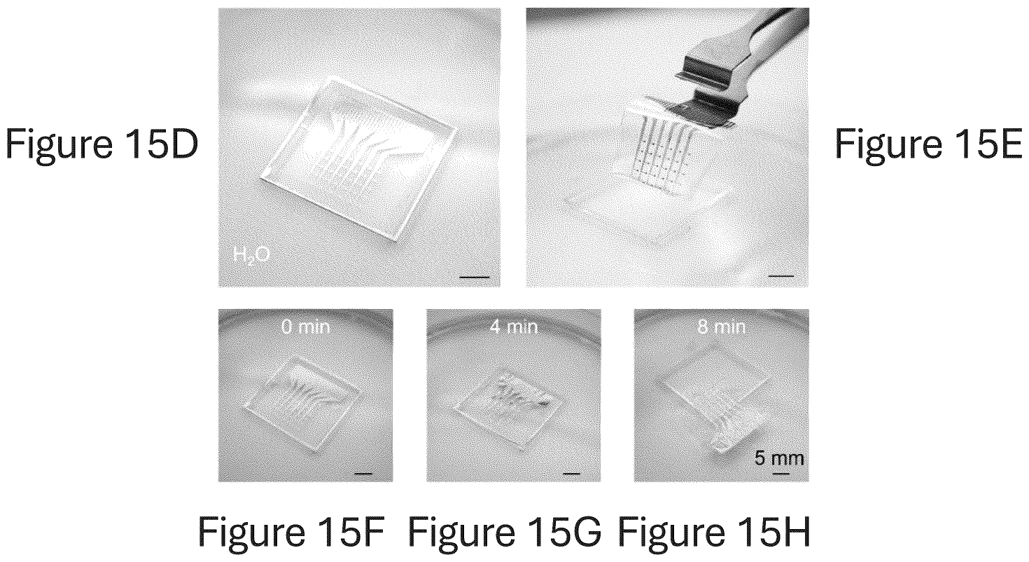

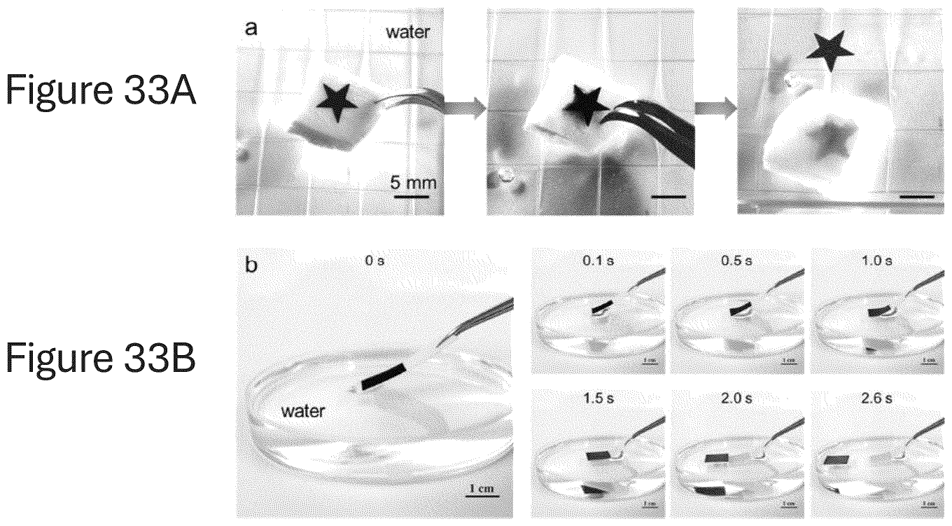

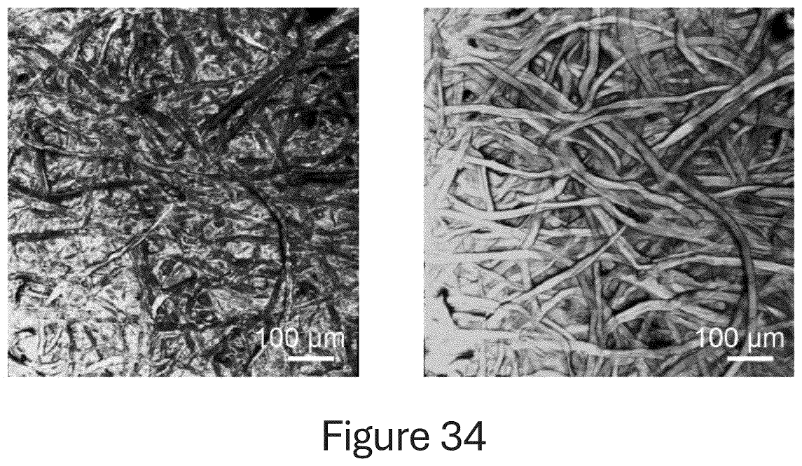

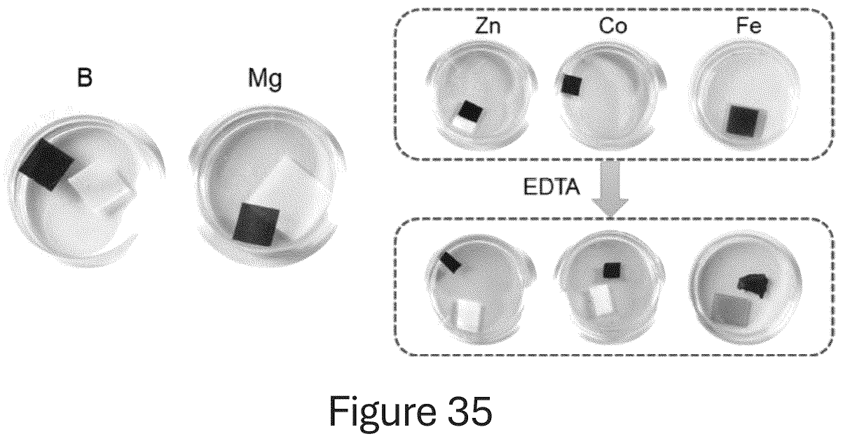

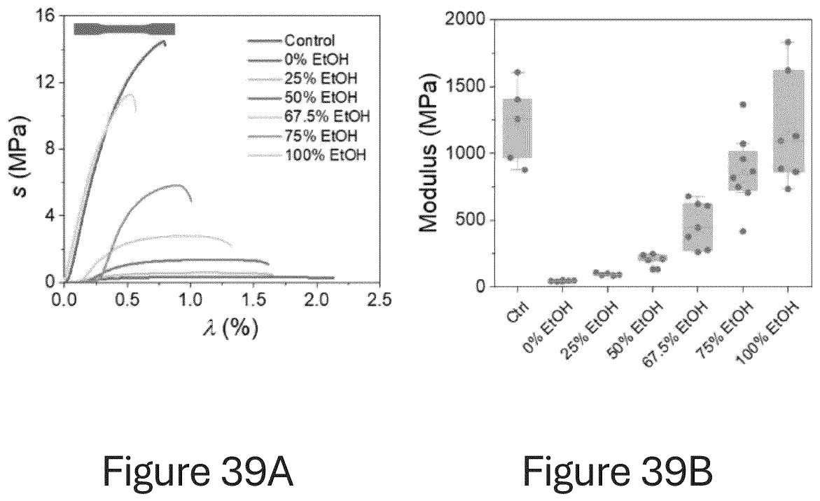

Drawing inspiration from natural systems, the application of chemo-mechanical forces is crucial for achieving efficient delamination on junction structures. The hydration and swelling dynamics of cellulose paper (FIG. 10D) were assessed by altering intermolecular interactions among the anhydroglucose units within cellulose. Two pathways were demonstrated to regulate cellulose fiber's swelling and mechanical properties, utilizing inhibitors (borate/Mⁿ⁺ ions), a neutralizer (ethylenediaminetetraacetic acid (EDTA)), and an activator (water). In the approach involving borate or MgCl₂, salt does not inhibit the swelling and water interferes with the 3-O . . . HO-6′ H-bond in cellulose II's amorphous zone, triggering rapid delamination without the need for energy/chemical-intensive etching process (FIG. 15). Conversely, the Mⁿ⁺-pathway utilizes metal ions to chelate with hydroxyl groups, yielding a stable interfacial bonding. However, application of EDTA re-initiates hygroscopic swelling of cellulose and delamination in water (FIGS. 33-41). While the borate-based method is straightforward, the inhibitors offer chemical responsiveness for on demand adhesion and delamination in microfabrication processes.

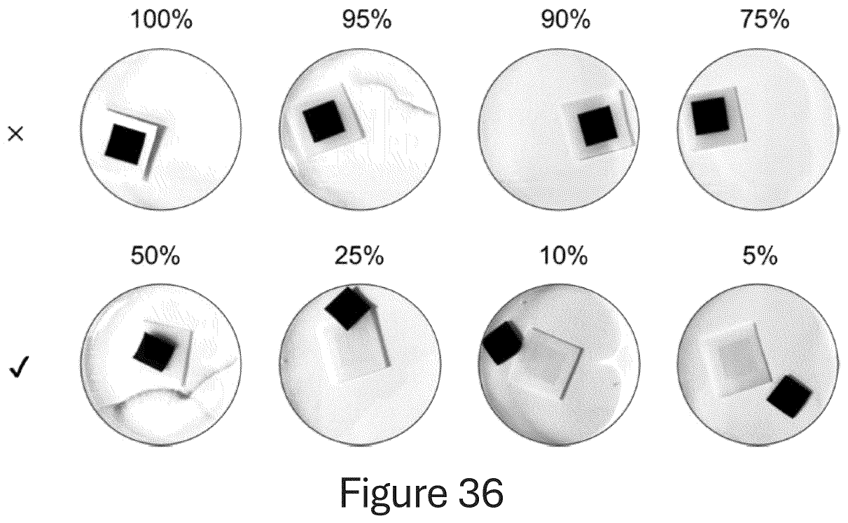

To identify the critical energy release rate, a set of separation experiments were performed in the borate-pathway. Using different water/ethanol ratios to modulate the intermolecular H-bond (FIG. 10E & FIGS. 36-39), the control of the delamination process was realized. Results show that swelling ratio decreased proportionately with ethanol concentration, whereas delamination was inhibited at 75% ethanol ratio (FIG. 36). The delamination threshold is met when the energy release rate (G) due to swelling surpasses the interfacial fracture energy between a membrane and a substrate (Γ_{c}), according to the equation:

$$G = \frac{1 - v}{2 ( 1 + v )} LE {ε}^{2} > Γ c$$

where L is the effective fiber thickness, ν is the Poisson's ratio of the fibers, E is the Young's modulus, and ε is the swelling strain of cellulose fibers. At 75% ethanol concentration, where ν=0.3, L=5 μm, E=466 MPa and ε=3.0%, the energy release rate is G=0.55 J/m². At 0% ethanol concentration, where E=45 MPa and ε=19.3%, the energy release rate is G=2.2 J/m², which is ˜3 times higher. Considering error bars, the calculated interfacial fracture energy is consistent with the values reported for thin film/substrate interface (˜0.4 J/m²) in the literature. We also verified that water-induced instant separation is applicable to aerogel substrate with microscale junction interfaces (FIG. 33).

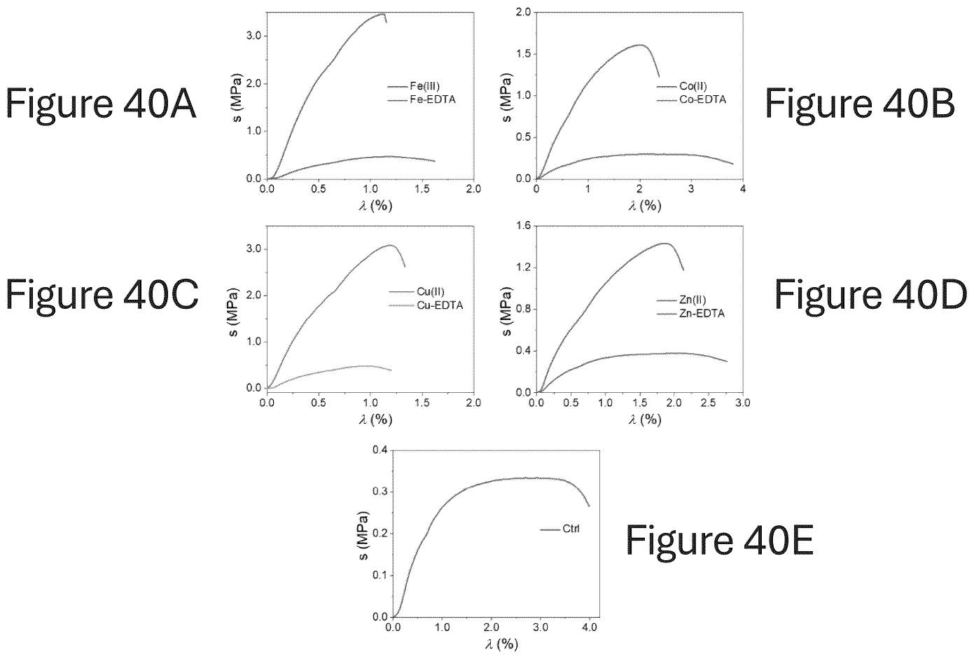

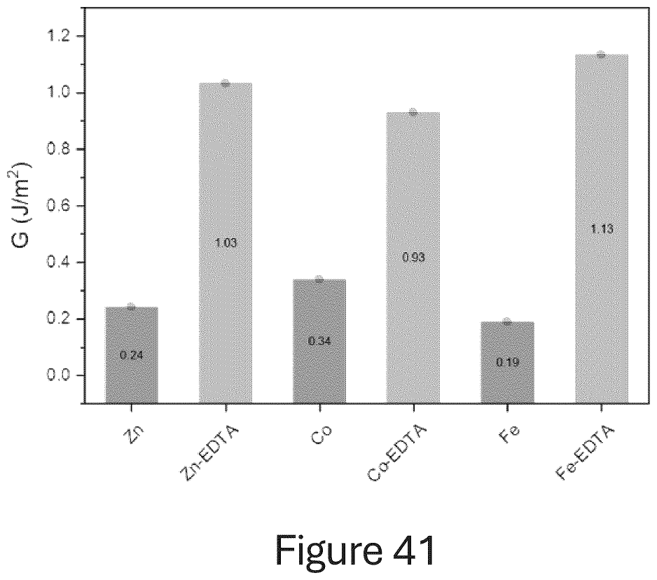

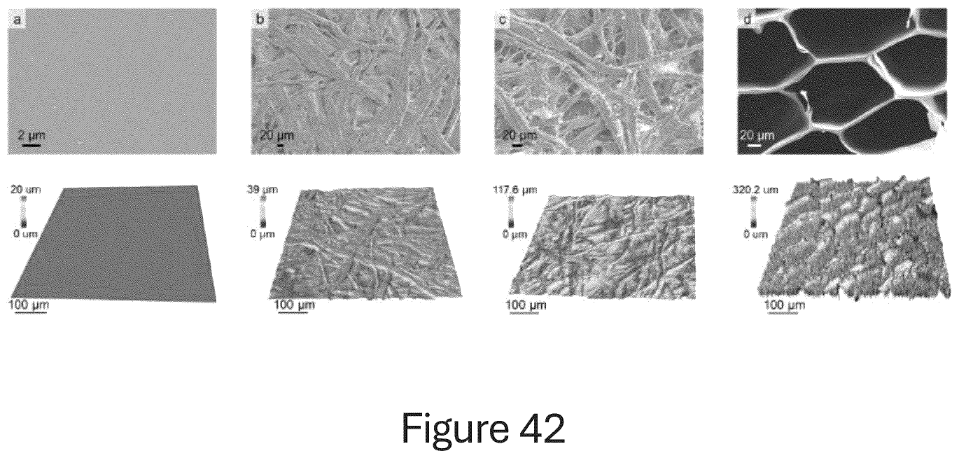

Utilizing transition metal ions as inhibitors, cellulose fiber experienced effective swelling suppression and the increase of mechanical strength and stability (FIG. 10F). EDTA was used as a neutralizer to modulate the responsive behavior of the junction. Upon immersion in a 0.1M EDTA solution, the swelling ratio of metal-laden cellulose fibers increased markedly from under 5% to over 10%, boosting the swelling energy (˜1.0 J/m²) and triggering delamination (FIGS. 40-41). Past research indicates that capillary peeling arises from capillary forces when film-substrate adhesion is below the film-water tension. Our measurements showed the film-water interfacial tension (64±3 mJ/m²) is between the air water (73 mJ/m²) and graphene-water (17 mJ/m²) tensions (FIG. 10G). The energy from cellulose swelling considerably exceeds surface tension energy, underscoring the pivotal role of junction swelling in delamination.

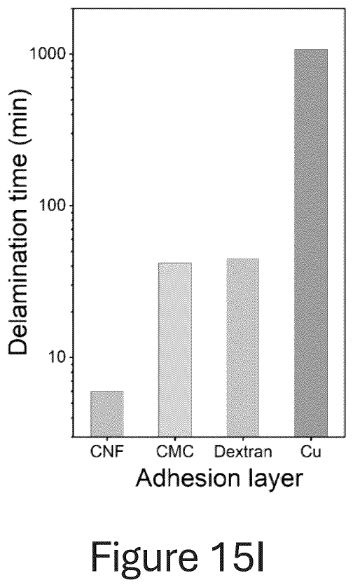

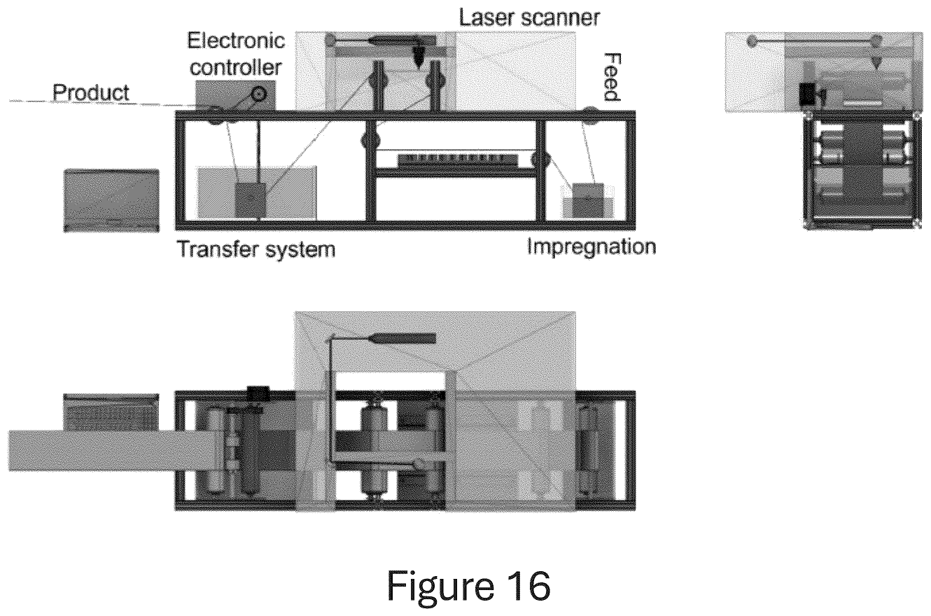

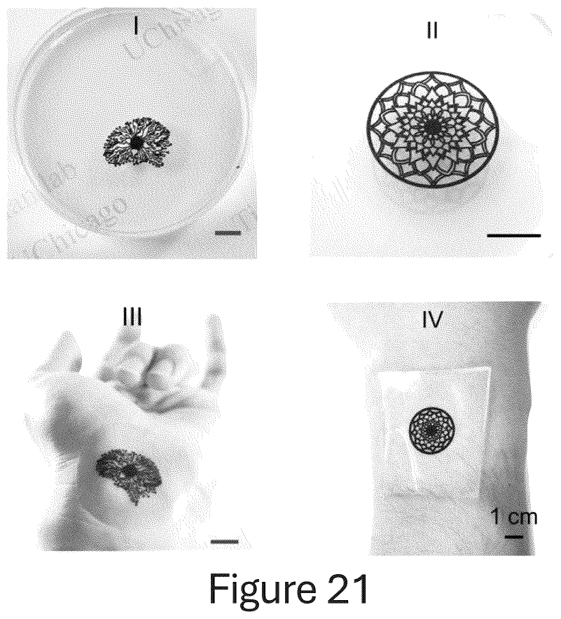

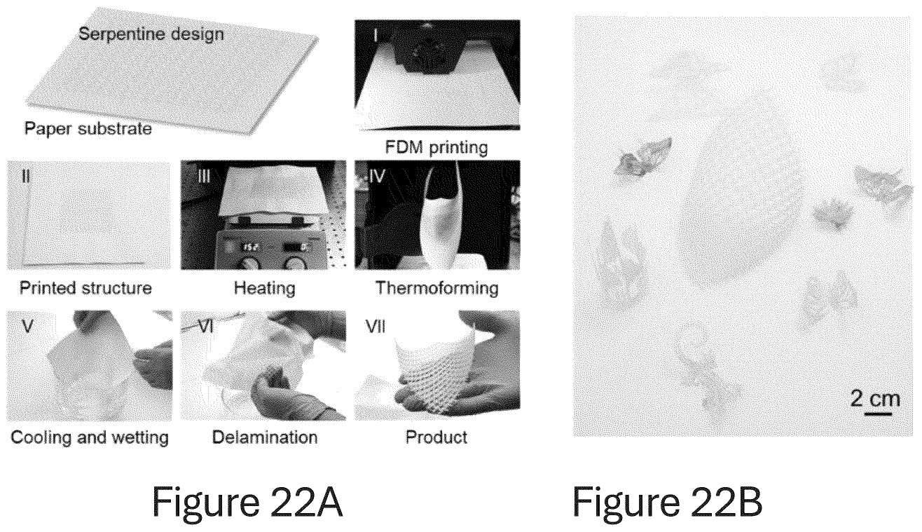

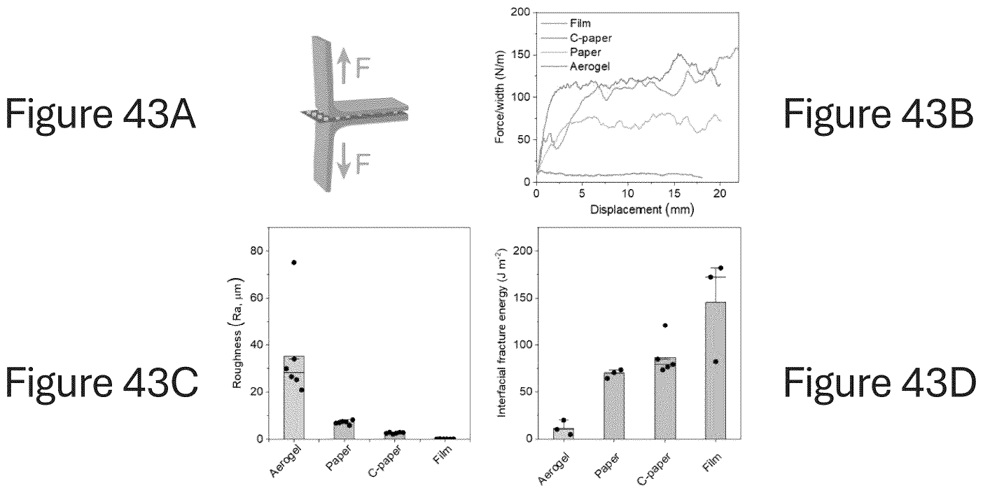

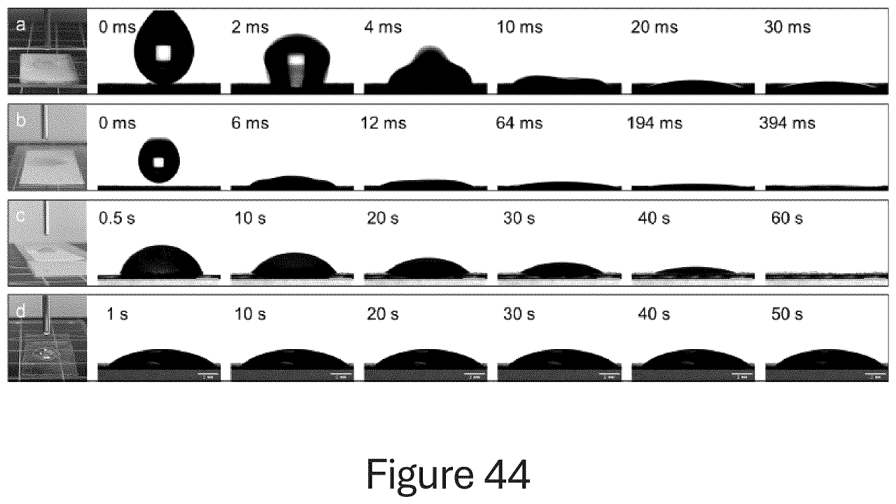

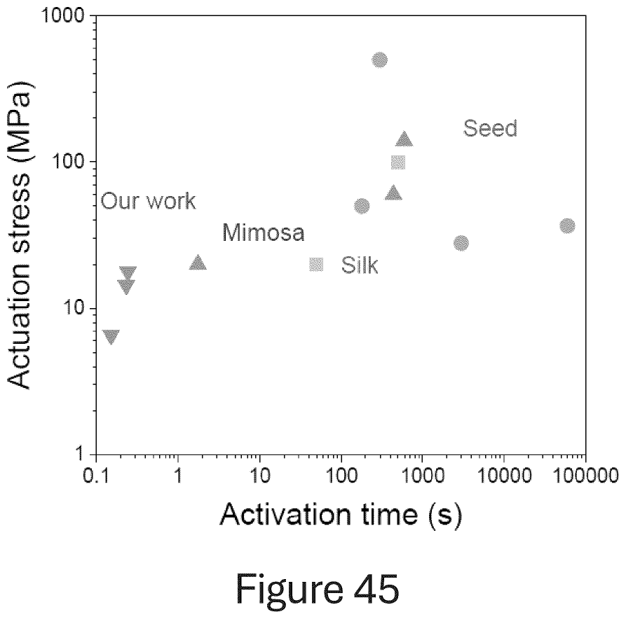

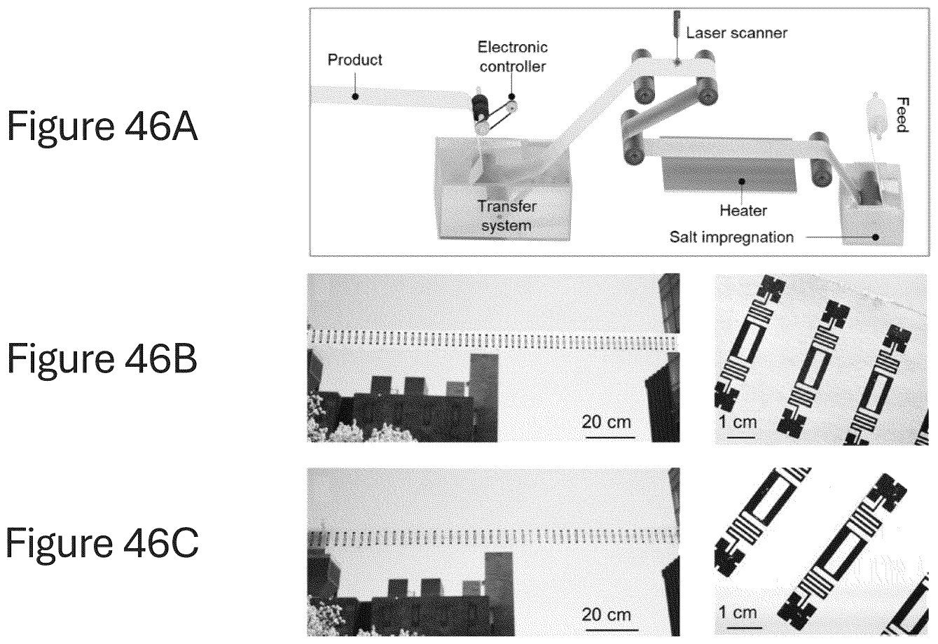

To elucidate the mechanism of instantaneous delamination, we crafted four substrates from sustainable materials with different porosities: (1) CMC film, (2) CMC aerogel, (3) cellulose paper, and (4) compressed cellulose paper (FIG. 43). Using a sandwich test, the interfacial fracture energy between substrates and adhesive tape was assessed, revealing higher porosity diminished peel adhesion strength. The fracture energy descended from 145.6 J/m² (CMC film) to 15.6 J/m² (CMC aerogel) and 86.9 J/m² (compressed paper) to 69.4 J/m² (cellulose paper) (FIG. 44). High-speed imaging (FIG. 10H & FIG. 44) verified enhanced water droplet penetration in porous substrates, which substantially amplifies swelling dynamics. Subsequent delamination observations revealed rapid water induced swelling and membrane detachment within ˜152 ms (FIG. 10I), over three orders of magnitude faster than current etching/electrochemical/dry delamination methods used to delaminate graphene layer from Cu foil (FIG. 15). In comparison to natural hygroscopic actuators like silk, seeds, and mimosa, the junction-driven actuation achieves reduced delamination periods (˜150 ms in water to ˜250 ms in 50% ethanol) at comparable stress levels (˜10⁷ Pa) (FIG. 45). Additionally, paper substrate also offers support for thermoforming in additive manufacturing, enabling the fabrication of thin-layered 3D patterns upon wet release (FIGS. 21-22). The “permeable junction” strategy also proves to be a universal approach for microfabrication on rigid substrates (e.g., silicon wafers, glass), with cellulose nanofiber (CNF) significantly enhancing delamination efficiency. The findings show that CNF enables rapid delamination of Au-based bioelectronics created via traditional photolithography or thermoplastic-based objects via additive manufacturing process (FIG. 16 & FIGS. 46-48). This nanojunction strategy presents unparalleled efficiency for fabricating multifunctional devices with enhanced precision over traditional methods.

### Results—A Versatile Platform for Device Microfabrication

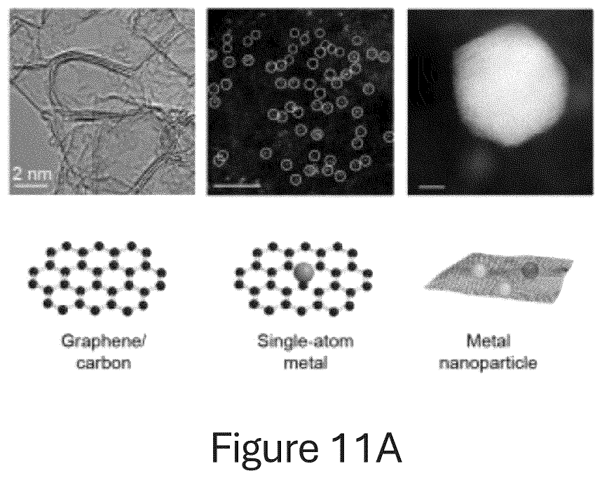

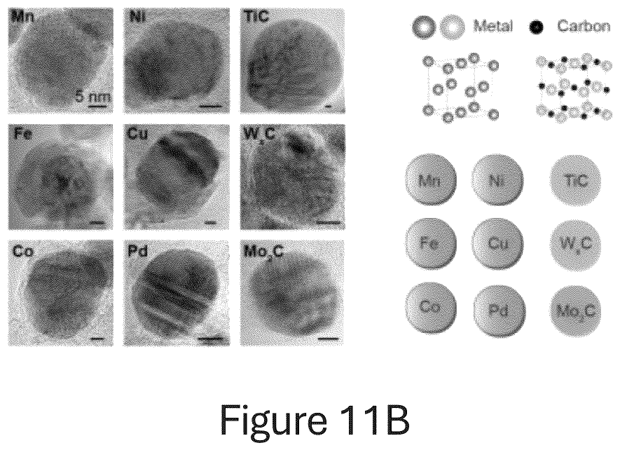

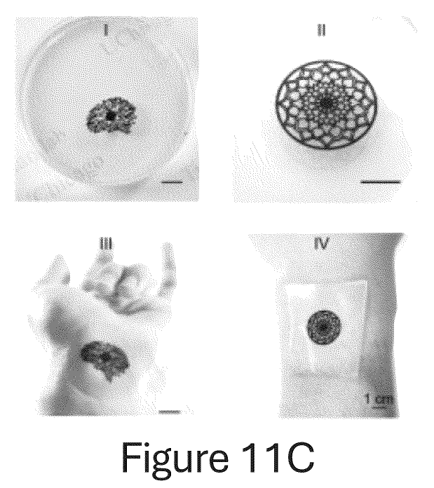

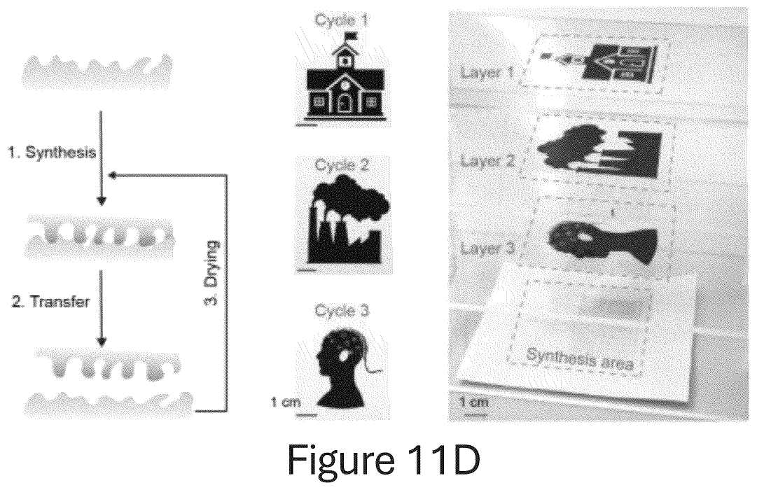

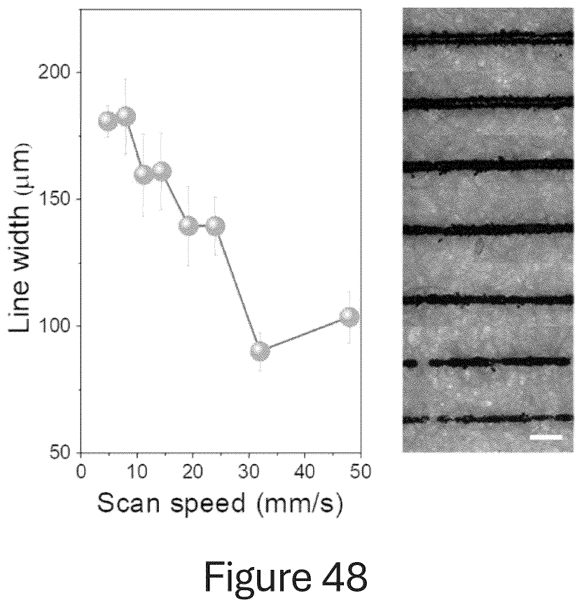

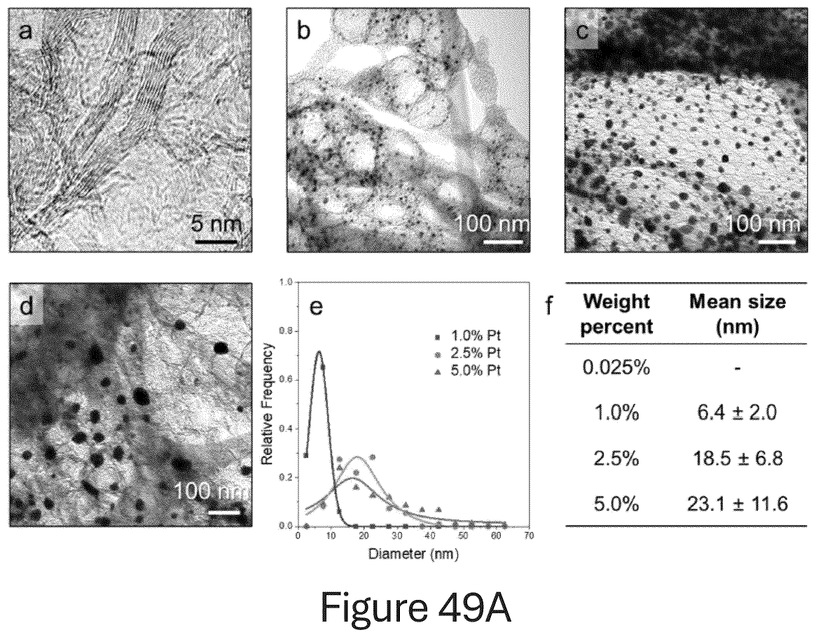

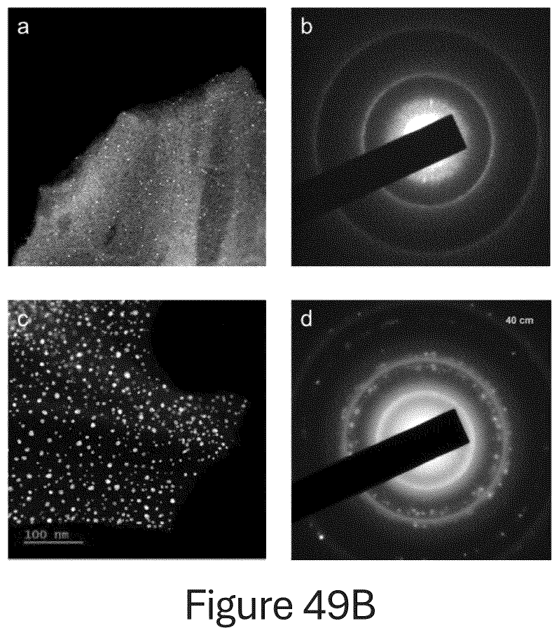

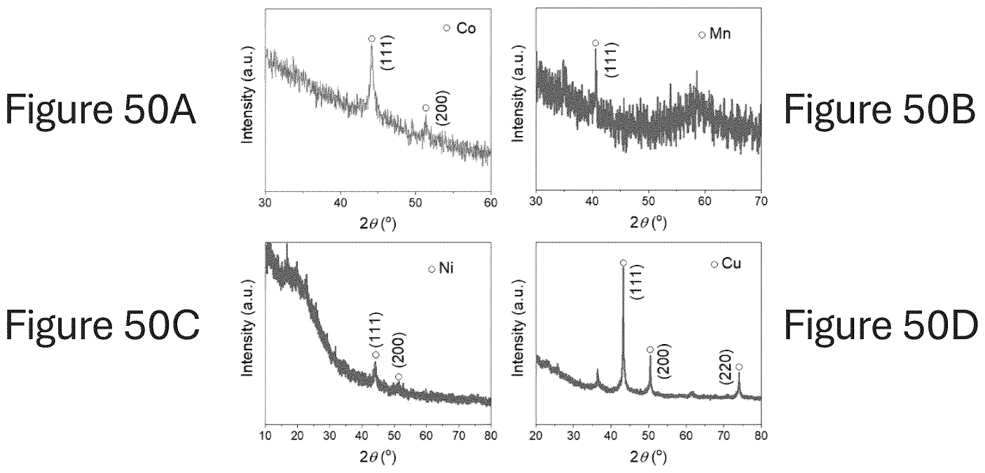

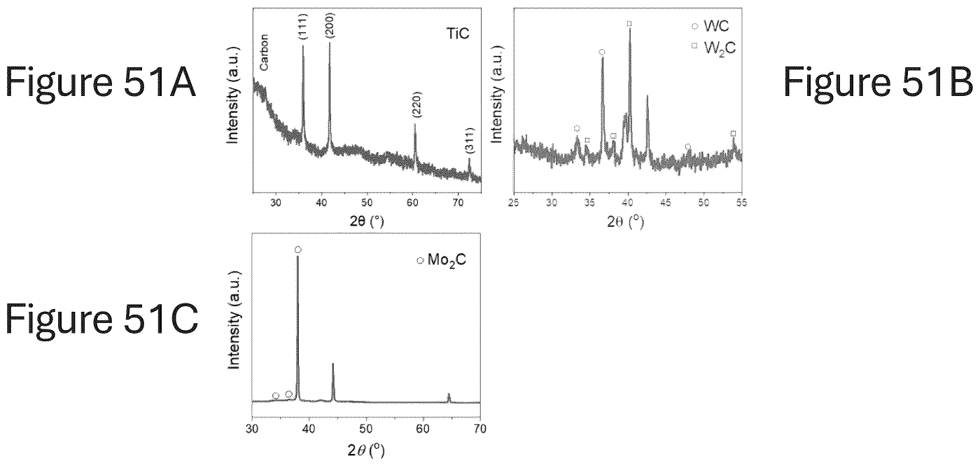

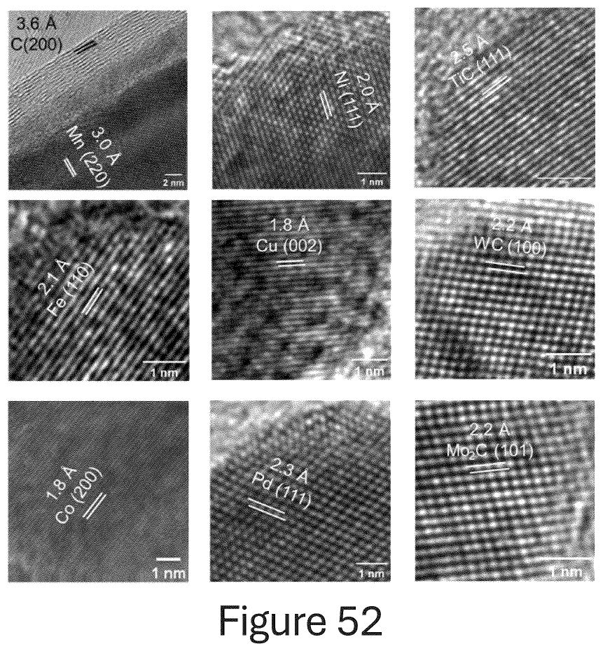

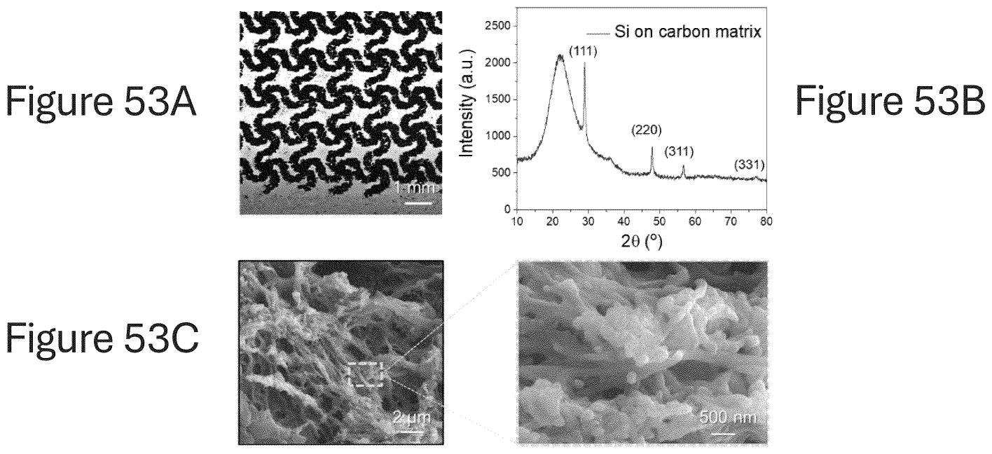

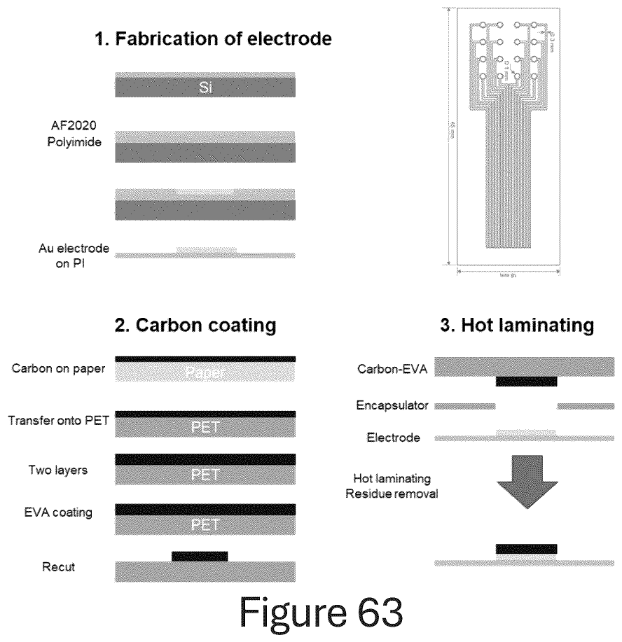

This method enables the versatile tuning of patterning and material property (FIGS. 11A-11B). A line width of 90.1 μm on cellulose paper (FIG. 48) was achieved, with the potential to reach resolutions finer than 50 m. This method proved to be compatible with a variety of metal salts across different concentrations. Taking platinum (Pt) as an example, single-atom dispersion of Pt to nanoparticle encapsulation in semicrystalline carbon matrix (FIG. 11A & FIG. 49) was achieved. At a low precursor concentration (K₂PtCl₄, 0.025 wt % in 0.15 M sodium borate solution), single Pt atoms are dispersed. In contrast, a higher concentration (5%) leads to the encapsulation of Pt nanoparticles with an average size of 23.1 nm. This reduction behavior of carbon at high temperatures is consistent with the Ellingham diagram. Using laser additive manufacturing, various metals, or carbide nanoparticles (Mn, Fe, Co, Ni, Cu, Pd, TiC, WC/W₂C, and Mo₂C, FIG. 11B) can be integrated into carbon matrices (FIGS. 50-52). The carbon membrane can also serve as a template for silicon growth, enabling porous semiconductor production (FIG. 63). This versatility underscores the potential of this method for generating materials with tailored properties for specific applications.

Three eco-friendly water-assisted transfer techniques were employed, circumventing pollution from traditional etching process. Water-phase transfer capitalized on capillary forces (FIG. 11C & FIG. 20), while hydrogel-based transfer used the water content in hydrogels (>90 wt %) for delamination and transfer. Additionally, water-assisted tape transfer achieved direct pattern transfers onto adhesive substrates. Compared to other laser-based fabrication methods, this permeable junction strategy enables efficient device transfers from the original substrate to a variety of others, spanning from non-adhesive 2D surfaces to complex 3D structures.

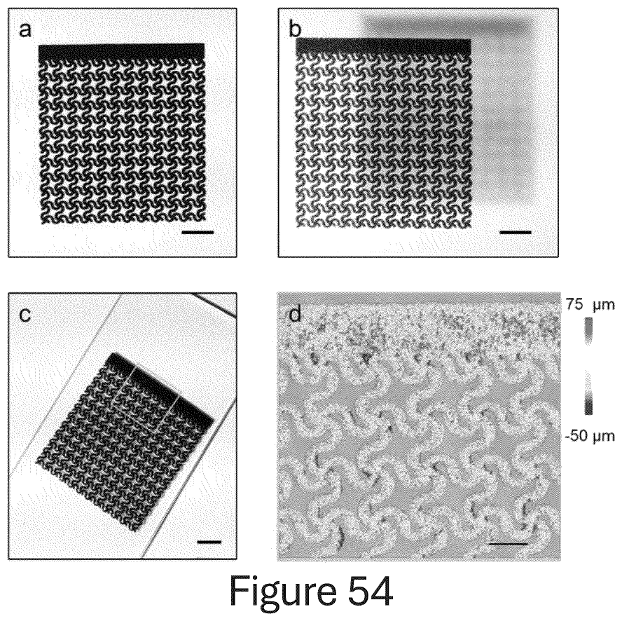

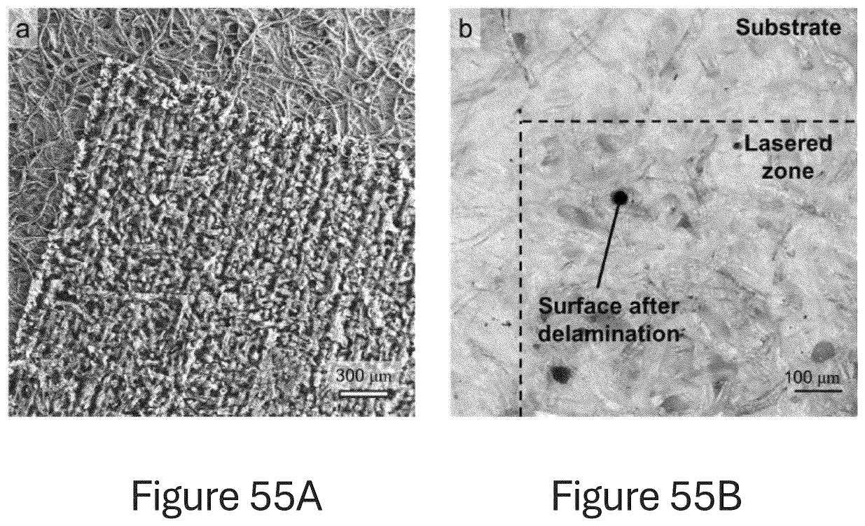

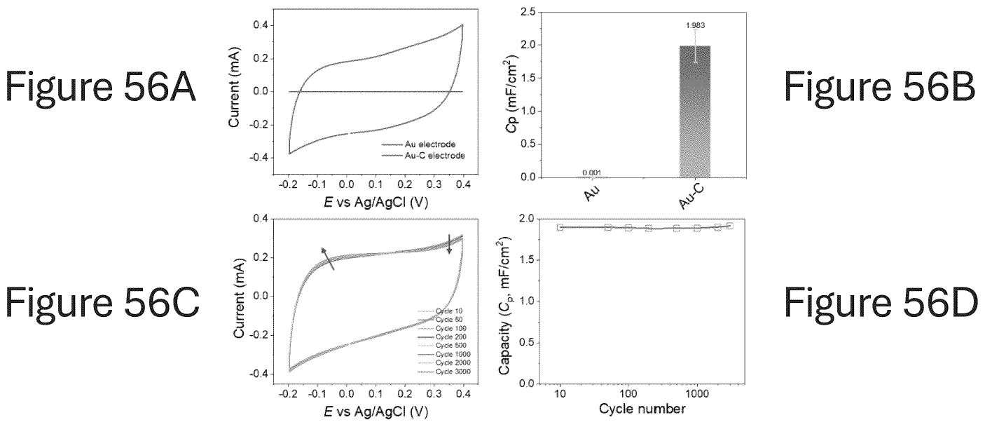

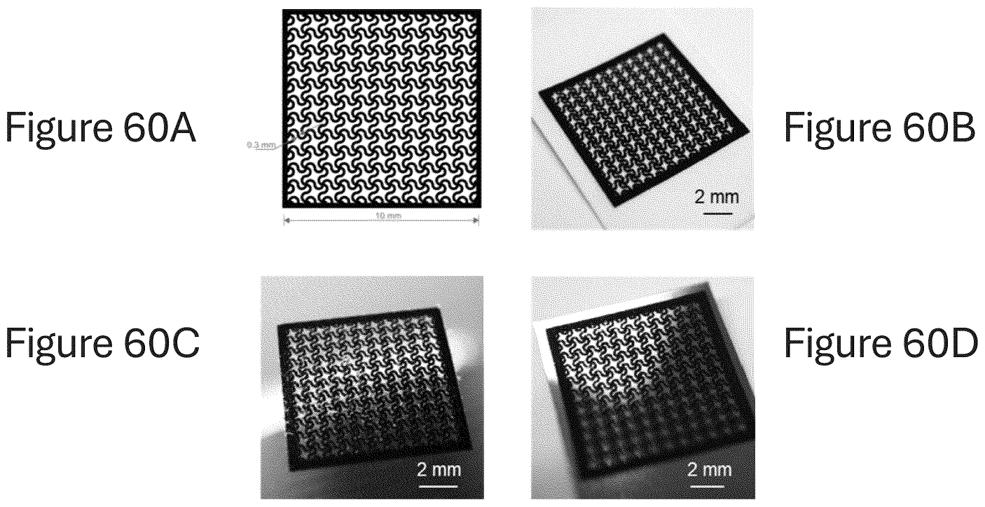

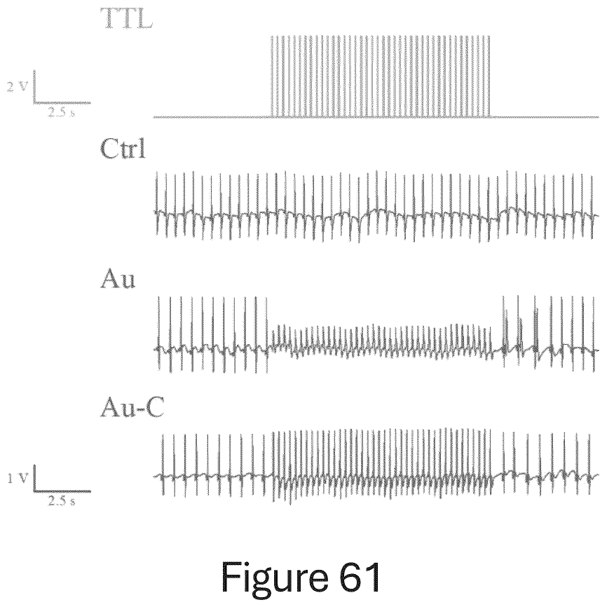

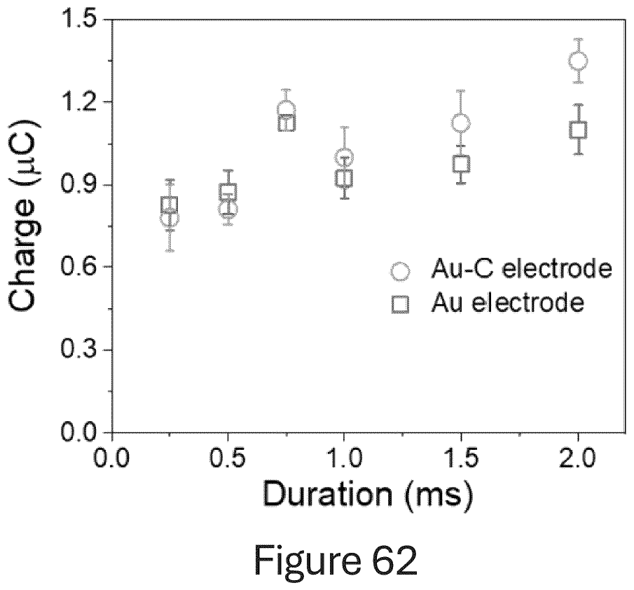

This natural inspired approach of permeable junction formation supports sustainable on-demand, renewable attachment and delamination. As a demonstration, a serpentine image was patterned, transferred to transparent tape, and regenerated porous substrate post-transfer (FIGS. 54-55). This allowed stepwise patterning, such as a house followed by the diagrams of industrial smokestacks and an electroencephalography experiment, on the same substrate, demonstrating the repeatability of the process from the same initial substrate (FIG. 11D). The distinctive properties of porous carbon materials, including high surface area, electrical conductivity, and flexibility, provide a versatile platform for diverse applications in fields like supercapacitors, sensors, and flexible electronics (FIGS. 56-60).

### Results—Fabrication of Flexible Bioelectronics

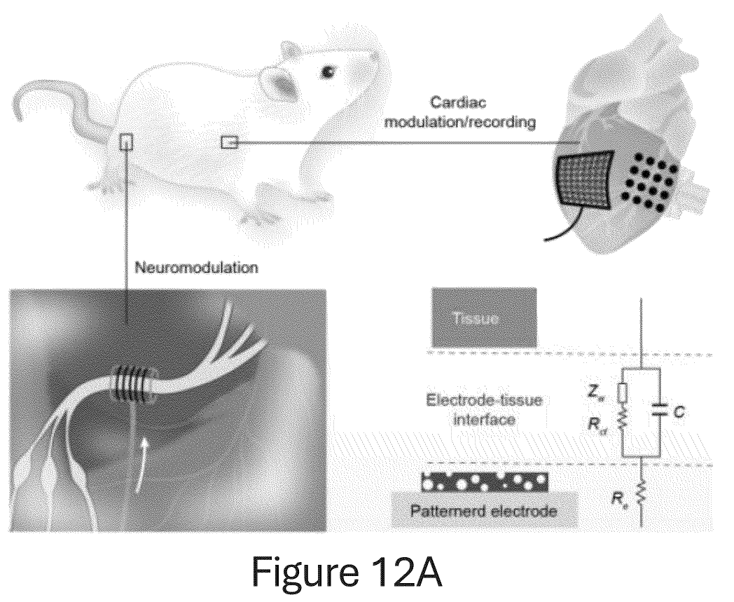

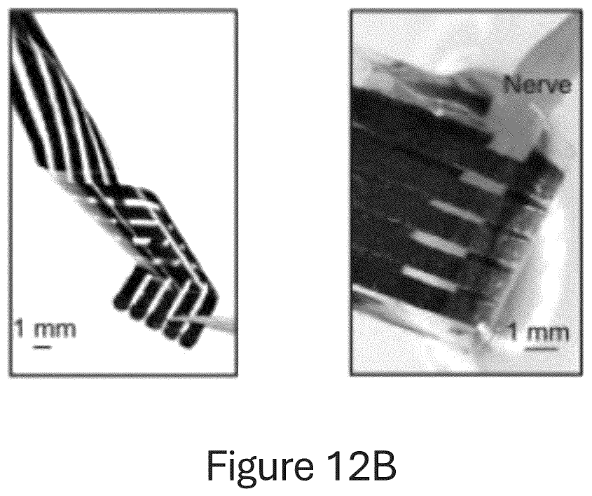

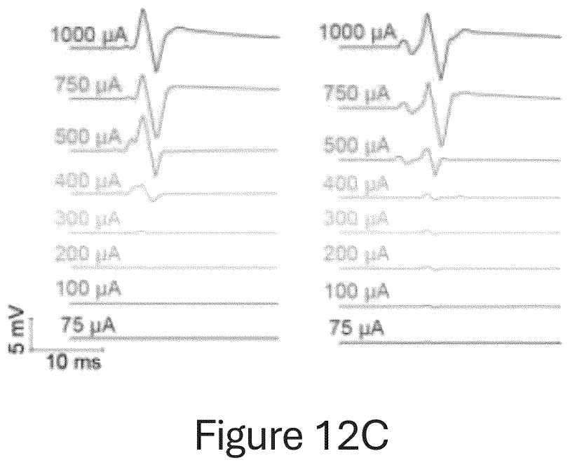

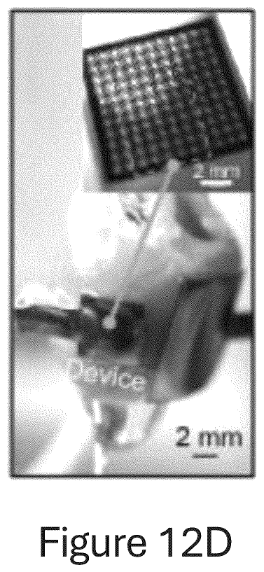

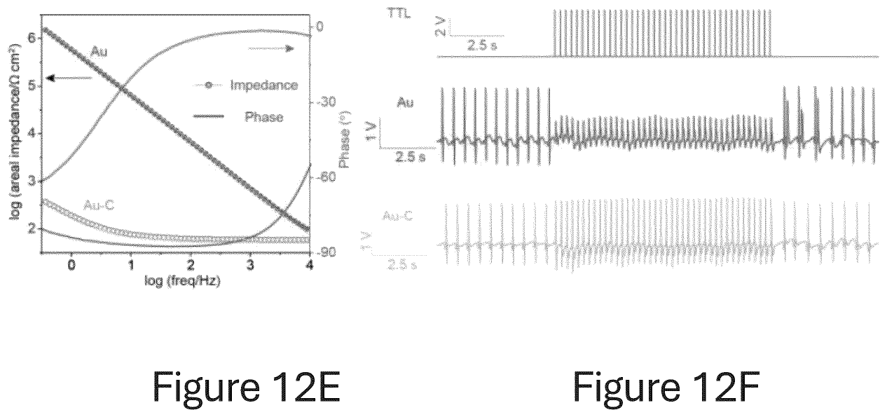

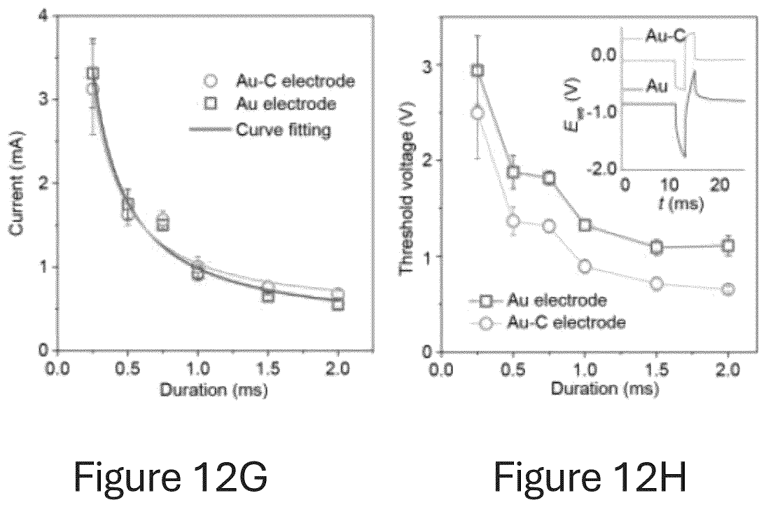

To showcase the potential applications, a platform for bioelectronics fabrication was established. This involves the development of microcapacitors and the construction of effective biointerfaces for electrical modulation or sensing of neural and cardiac systems (FIG. 12A).

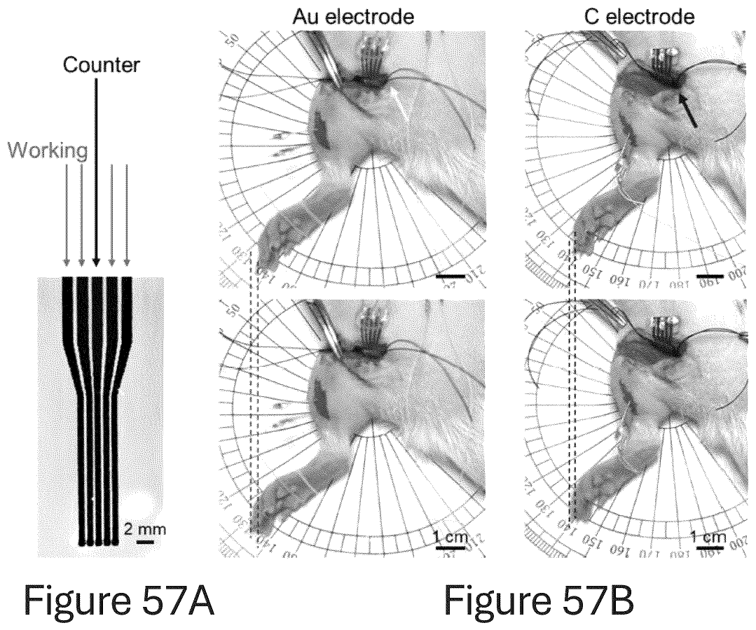

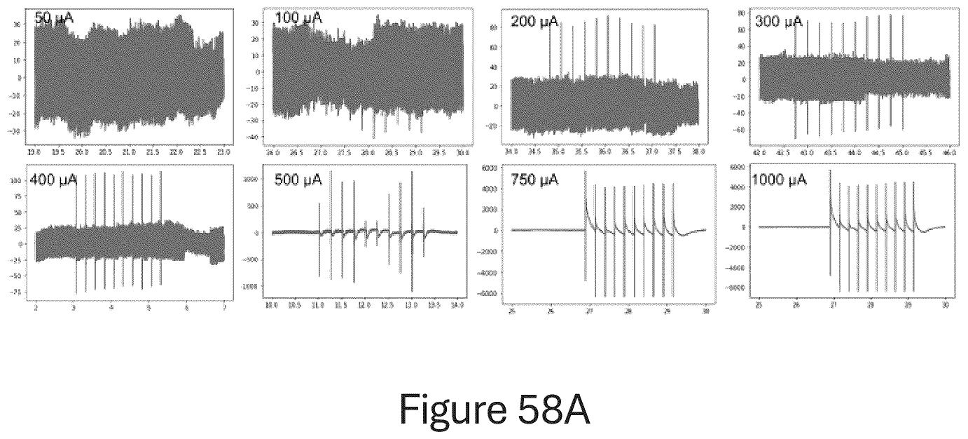

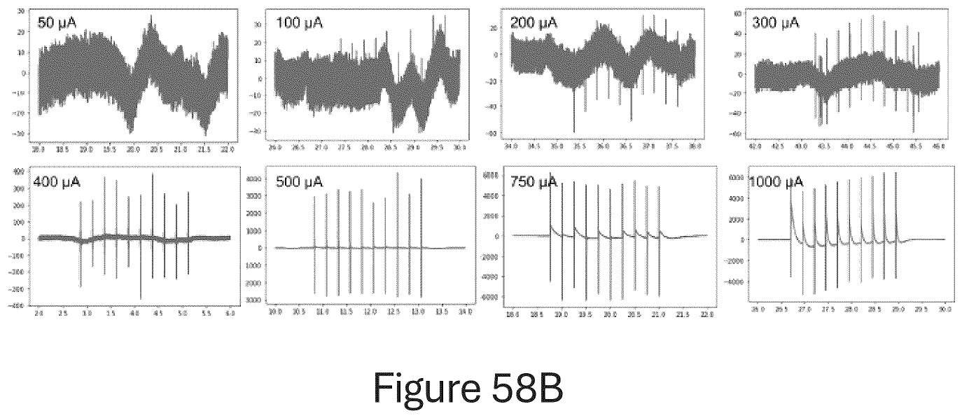

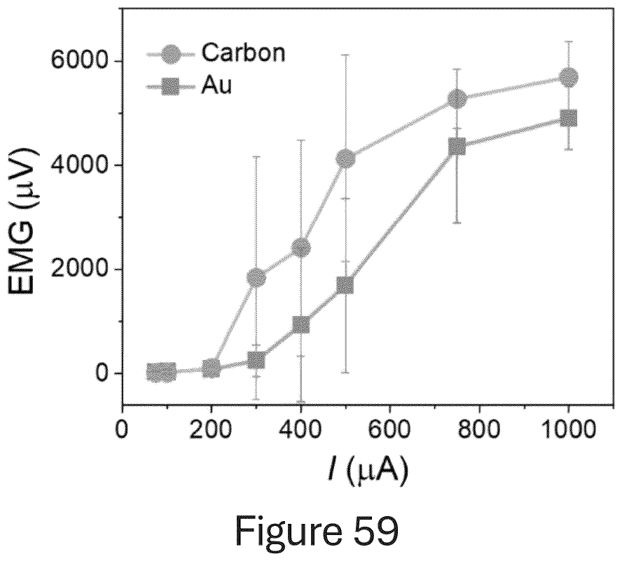

For neural modulation, we developed cuff-type neural electrodes through water transfer of carbon-based electrodes onto thin PET films (thickness, 12.5 μm) (FIG. 12B & FIG. 57). The compliant carbon electrodes formed a seamless interface with soft sciatic nerve of rat, facilitating electrical coupling. We electrically stimulated the sciatic nerve using a traditional Au electrode and the carbon electrode, and recorded action potentials from the muscles clear limb movement was observed that synchronized with each current injection, which was corroborated by electromyography (EMG) recordings from the rat limb. EMG results displayed large potential spikes in synchrony with the cathodic phase (FIG. 12C & FIGS. 58-59). The carbon electrodes exhibited neuromodulation capabilities analogous to those of the traditional Au electrode, demonstrating their potential as soft and flexible neural stimulators.

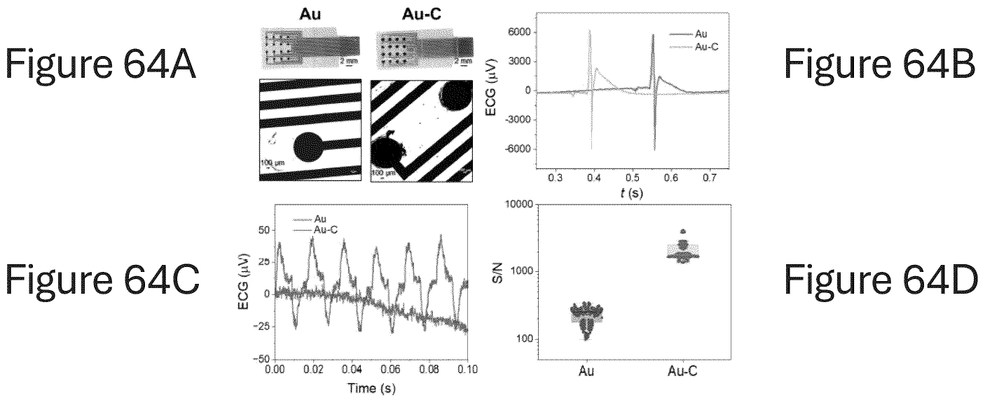

Nanostructured carbon material presents an effective solution to enhance bioelectronic device performance owing to their high charge storage capacity. Traditional methods for creating carbon-based electrodes include electrodeposition, spin coating, and screen printing, which are limited by the patterning capabilities or complex precursor preparation procedures. Relatively, this method enables facile patterning and instant transfer of carbon devices onto traditional Au electrodes for enhancing performance (FIG. 12D). The Helmholtz capacitance of the Au electrode increased significantly after carbon coating, from 0.025 to 1.98 mF/cm2 (FIG. 56). The increasing of capacitance using this microcapacitor coating strategy can effectively lower the polarization voltage. Impedance characterization further confirmed that the carbon coating substantially reduced the impedance of the Au electrode by approximately 2 orders of magnitude, from 7244.4 to 63.1Ω at 100 Hz frequency pertinent to electrocardiogram (ECG) signals (FIG. 12E). We then evaluated the efficiency for cardiac stimulation. Using a Langendorff perfusion system, the Au or Au—C electrode was placed on the left ventricular (LV) wall for charge injection at biphasic square current waveforms (FIGS. 12F-12H). Upon 4 Hz stimulation (1 mA), both Au and Au—C electrodes achieved effective overdrive pacing. However, a notably higher ECG amplitude, indicative of contraction strength, was observed in the Au—C group. Both electrodes demonstrated an exponential decrease in the threshold current for stimulation with pulse duration. The strength-duration curve was modelled using the equation: I(t)=I_{rheobase}/(1−exp(−t/τ)), wherein I(t) refers to the stimulus current at the pulse duration (t), I_{rheobase} is the threshold current at an infinitely long pulse duration (rheobase), and τ is the membrane time constant. The minimum charge necessary was calculated for successful stimulation at chronaxie as Q=I_{rheobase}×τ. Qₘᵢₙ values were determined as 0.79 and 0.71 μC for Au and Au—C electrodes, respectively (FIG. 12G). Stimulation thresholds, which indicate the lowest voltages for effective frequency modulation, were also measured across various pulse widths (FIG. 12H). At a stimulation current of 4 mA/cm², threshold voltages for effective stimulation were observed at 1.32 V and 0.90 V for 236 Au and Au—C electrodes, respectively. The 30.3% reduction in threshold voltage suggests a potential decrease in oxidative stress during prolonged stimulation, thus facilitating safer bioelectronics application with minimal tissue damage. Additionally, we developed a carbon-grafted 16-channel Au electrode for enhanced epicardial ECG signal detection (FIG. 12I & FIGS. 63-64). The nanostructured carbon transfer notably improved the signal-to-noise ratio by 8.0 folds compared to traditional Au electrodes, demonstrating the effectiveness of our approach for high-fidelity bioelectronics.

### Results—Fabrication of Catalytic Robotic Devices

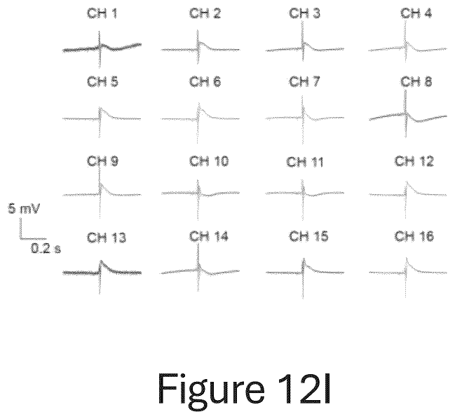

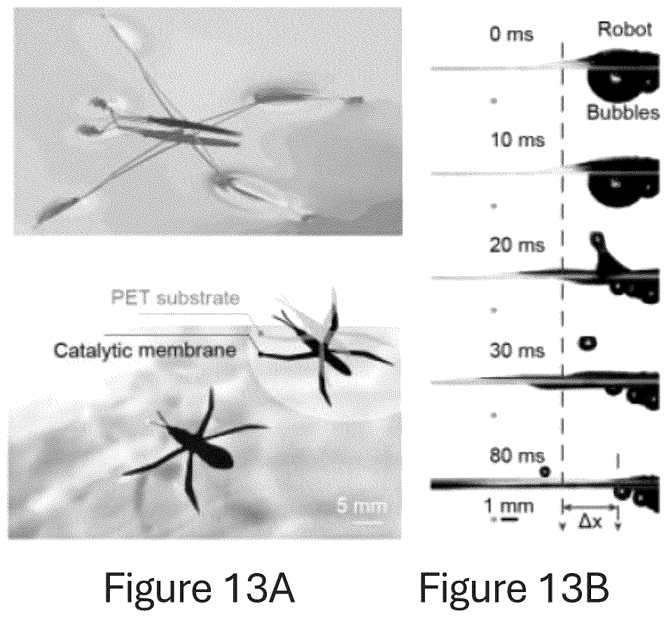

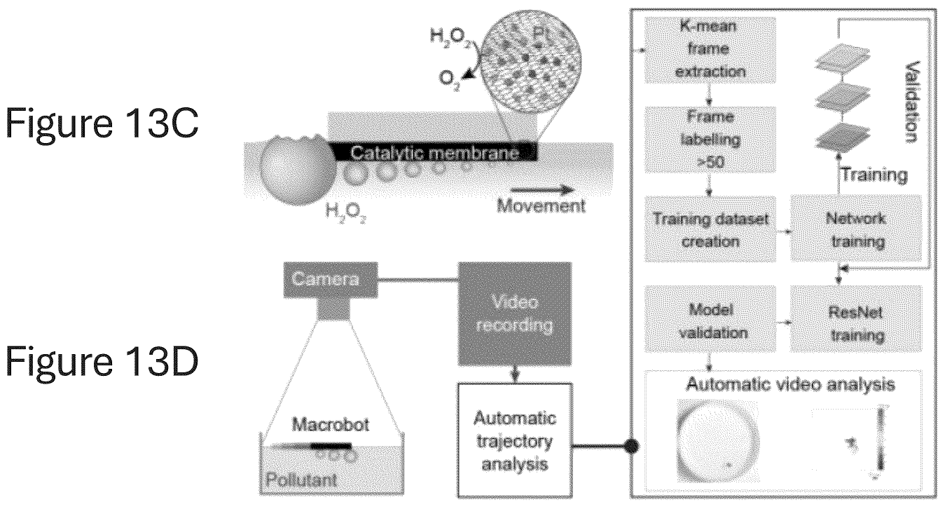

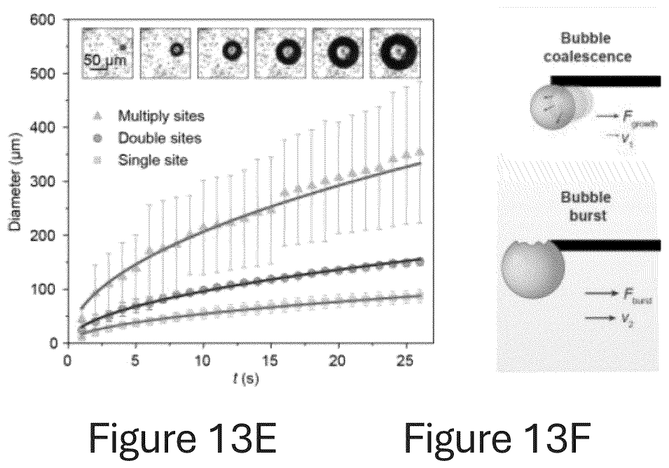

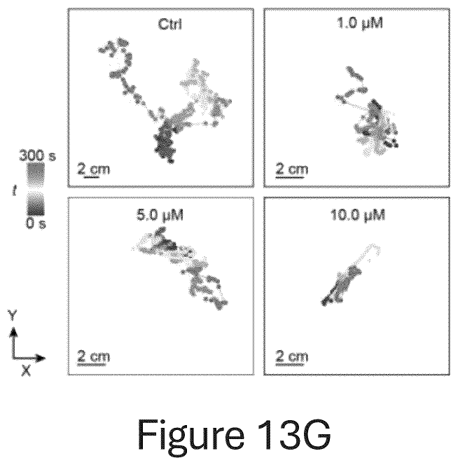

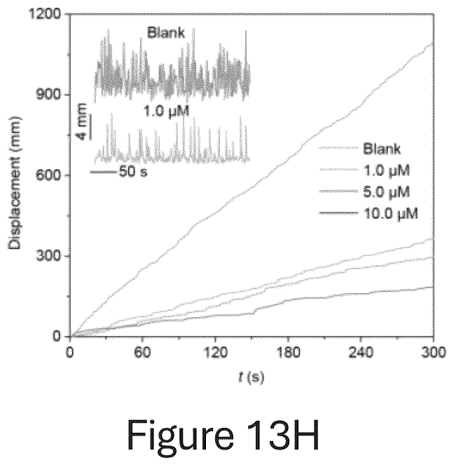

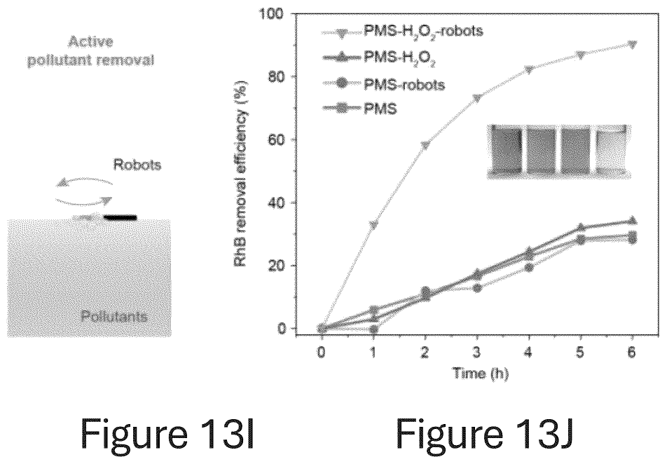

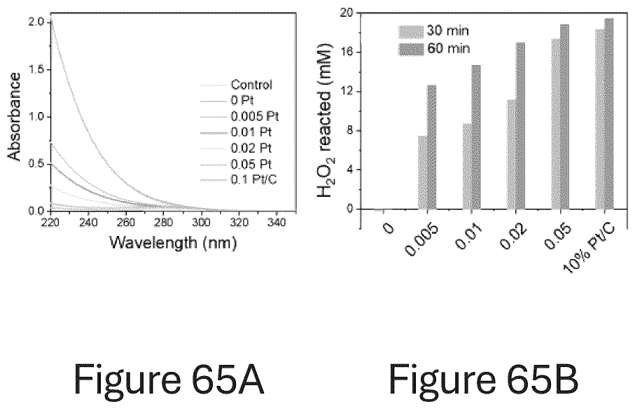

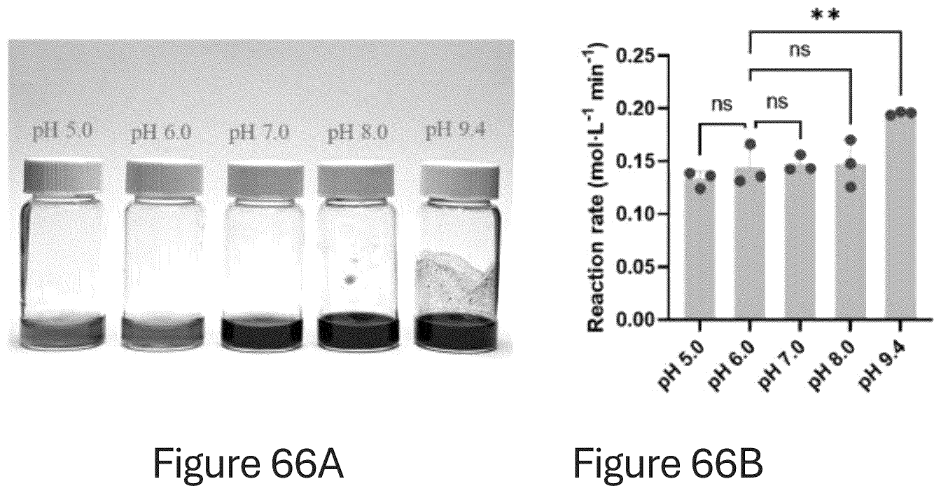

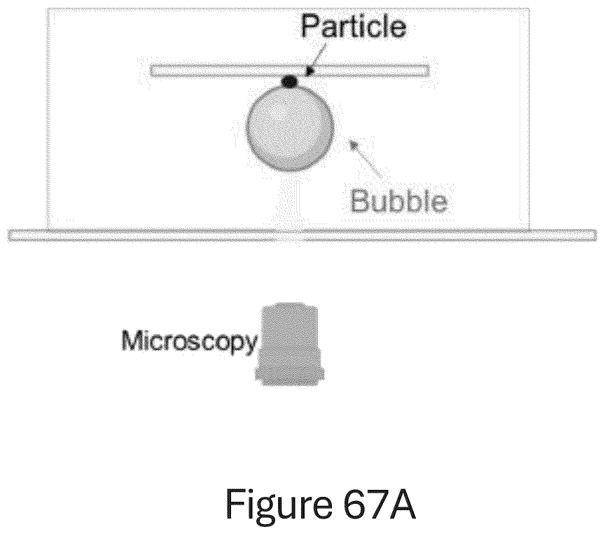

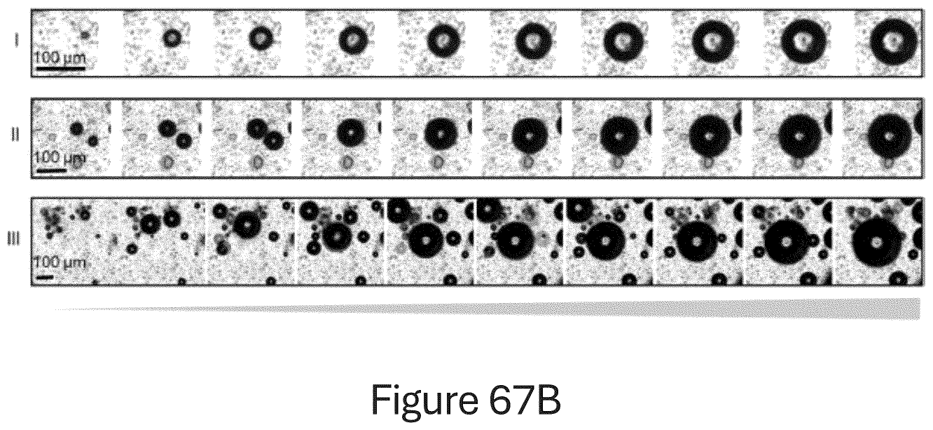

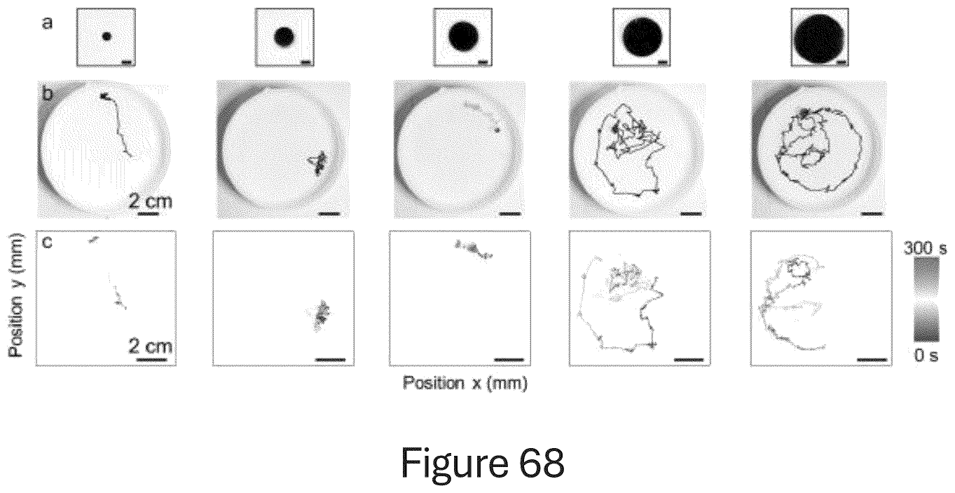

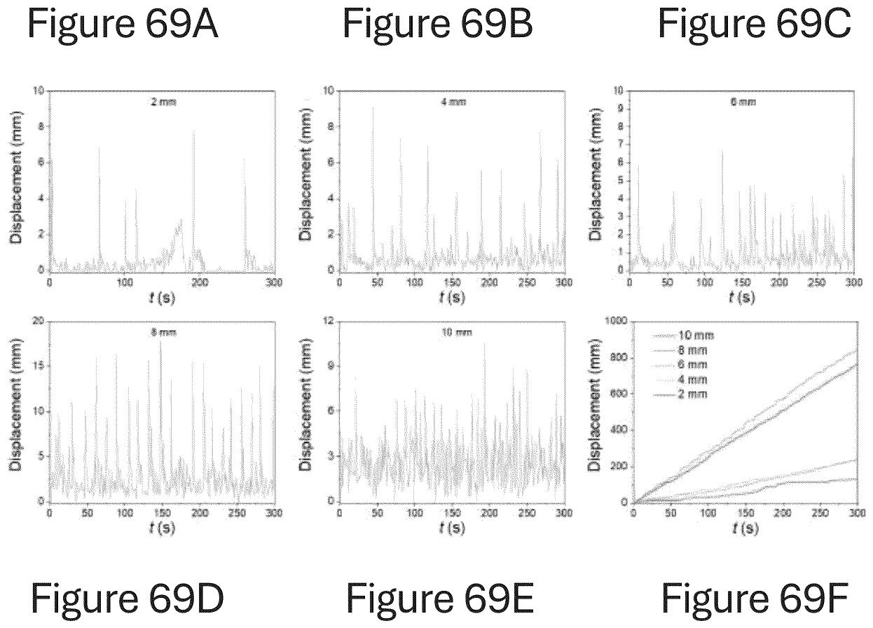

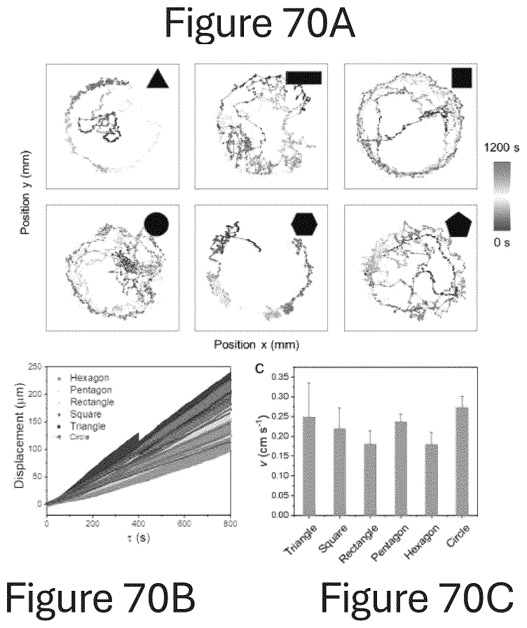

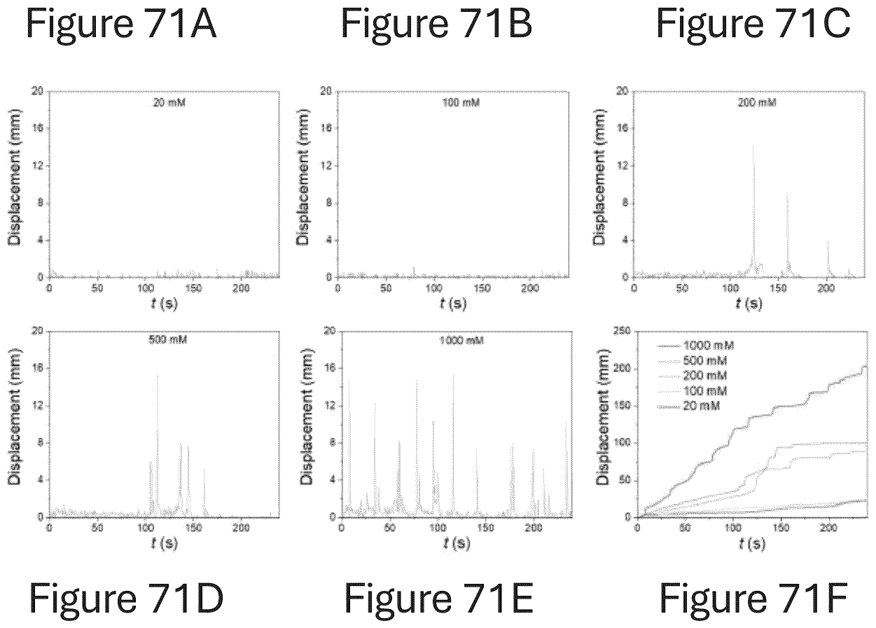

The release of heavy metals and organic pollutants into the environment due to human activities poses significant sustainability challenges, which requires the development of advanced sensing and remediation devices. To address the issues, a sustainable microfabrication method for robotic devices is introduced. Such robotic device is inspired by waterborne insects such as water striders, which demonstrate active movement and responsiveness to environmental cues like threats or food sources (FIG. 13A). A robot was engineered with a carbon pattern incorporating Pt and transferred it onto a thin, hydrophobic PET film. This robotic device propels itself by harnessing chemical energy through the Pt-catalyzed decomposition of H₂O₂ into O₂, simulating the dynamic movement of water striders (FIGS. 13B-13C). The propulsion mechanism during burst dynamics of O₂ bubbles involves phases of liquid film retraction and fragmentation (0 ms), cavity collapse (10 ms), jet formation and breakup (20 ms), and robot propulsion in the opposite direction (80 ms). Using machine learning algorithm (DeepLabCut), an automated trajectory analysis workflow was established (FIG. 13D) encompassing video capture, labelling, and network training. Catalase-like performance was optimized by altering the precursor concentration of Pt and pH during device fabrication, achieving a H₂O₂ decomposition (20 mM) rate of 5 mmol/(L min cm²) (FIGS. 65-66). Microscopic observations of bubbles on Pt-carbon particles showed a bubble growth function of R∝t½ with a minimum growth constant of 17.2 μm (FIG. 13E & FIG. 67). After nucleation, bubbles grew, and coalesced on catalytic film, promoting the continuous swimming of the robot (F_{growth}, FIG. 13F). Upon reaching maximum size, bubbles burst, releasing high-pressure O₂ gas and inducing a jumping motion (F_{burst}). The random walking and jumping behavior of the bioinspired robots was found to be size-dependent and shape-independent (FIGS. 68-70). The highest velocity (˜2.7 mm/s) was observed in robots with 8 mm diameter (FIG. 69). The catalytic robots maintained their jumping behaviors for weeks due to the protective carbon shells around the Pt nanoparticles, which indicates their potential for long-term environmental monitoring and pollutant remediation applications.

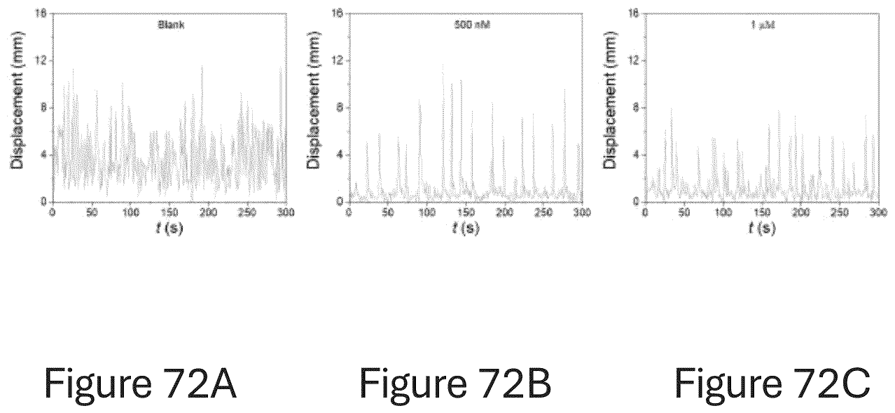

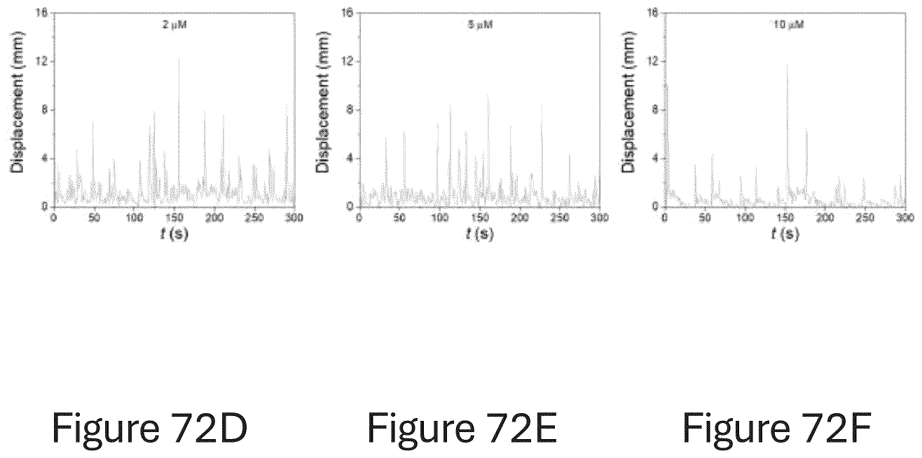

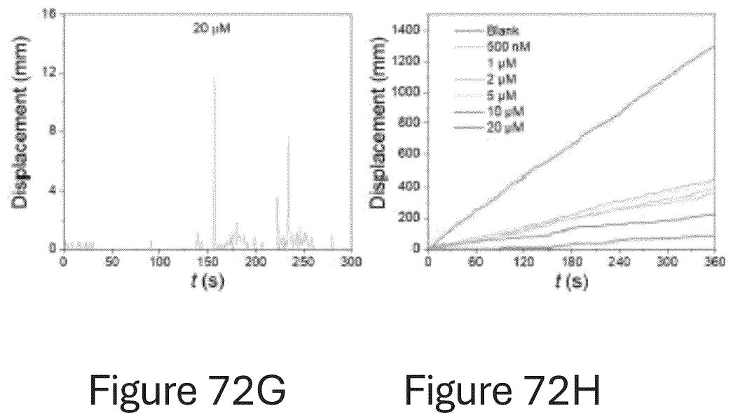

The discharge of heavy metals, notably Hg(II), into the environment from industrial processes, poses significant environmental and health risks. The potential of the bioinspired robot for Hg(II) tests was explored (FIGS. 13G-13H) by observing its movement behavior when exposed to Hg(II). In an unpolluted environment, the robot exhibited a jumping frequency of 15.2 jumps per minute and an average velocity of 3.7 mm/s in H₂O₂ solution. However, exposure to a 1 μM concentration of Hg(II) markedly reduced its mobility, leading to a decreased jumping frequency of 3.4 jumps per minute and an average velocity of 1.1 mm/s. Higher concentrations of Hg(II) further suppressed jumping frequency and velocity (FIGS. 72A-72H). This method shows the potential to detect Hg(II) at concentrations as low as ˜500 nM. Compared to conventional, sophisticated analytical instruments, this robotic sensor uses only a handheld camera for monitoring, offering a practical and versatile approach for on-site water quality monitoring in rural areas.

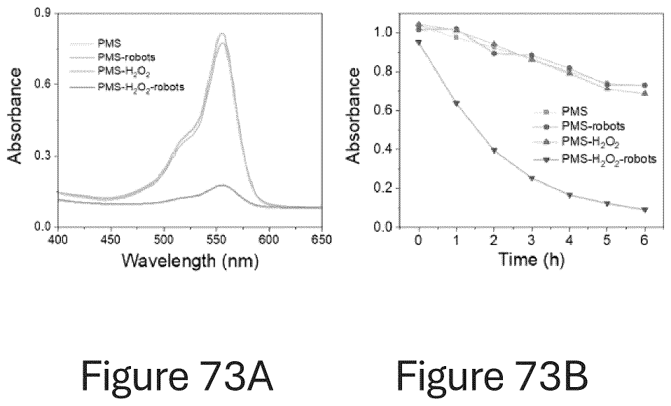

To mitigate environmental pollution caused by organic compounds, nanozyme-powered robots offer an environmentally friendly solution for active abatement of pollutants (FIGS. 13I-13J). Using rhodamine B (RhB) as a test pollutant, we measured RhB removal efficiency over time with four systems: 1) the pollutant remediator peroxymonosulfate (PMS); 2) PMS+nanozyme-powered robots; 3) PMS+H₂O₂; and 4) PMS+H₂O₂+robots. The inclusion of robots, especially when integrated with H₂O₂ as an external energy source, significantly accelerated the pollutant removal process. The active motion enables active pollutant adsorption and degradation with the synergistically catalytic effect from carbon and PMS. The robots function as autonomous cleaners, exhibiting efficient (94%) removal of organic dye within 6 hours (FIG. 13J & FIGS. 73A-73B). Compared with previous micro-sized particulate robots, this design of ‘floating’ macro-sized robots facilitates observation, recycling and reuse for environmental remediation.

### Results—Scalability and Sustainability Evaluation

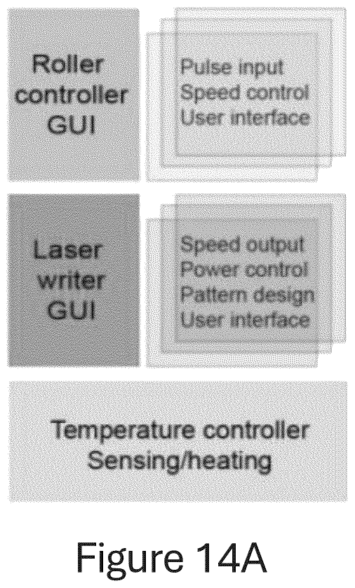

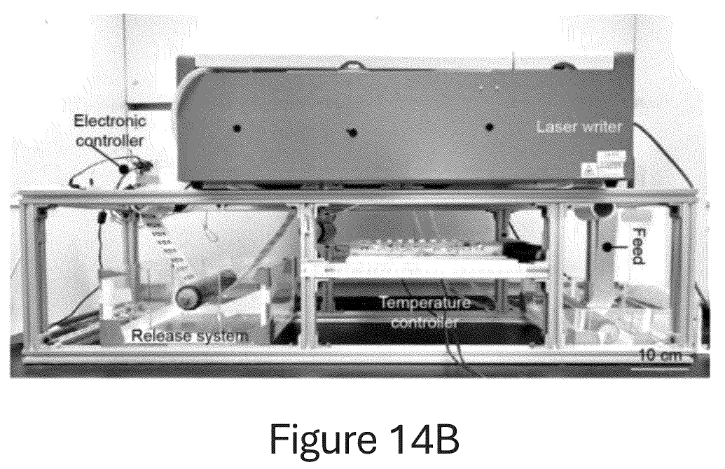

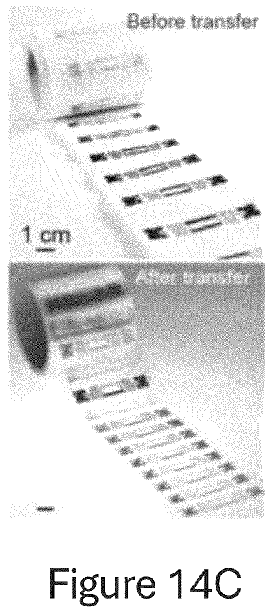

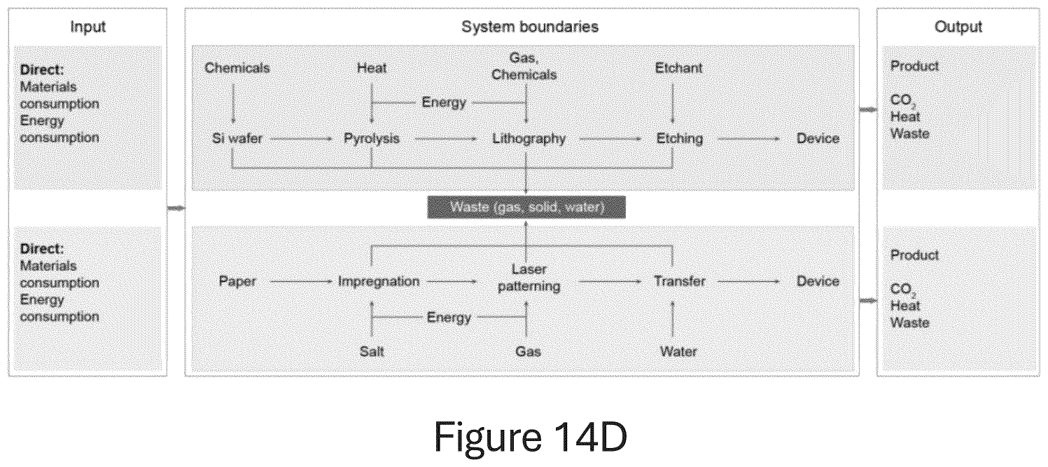

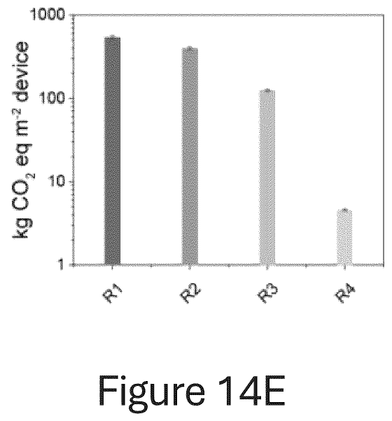

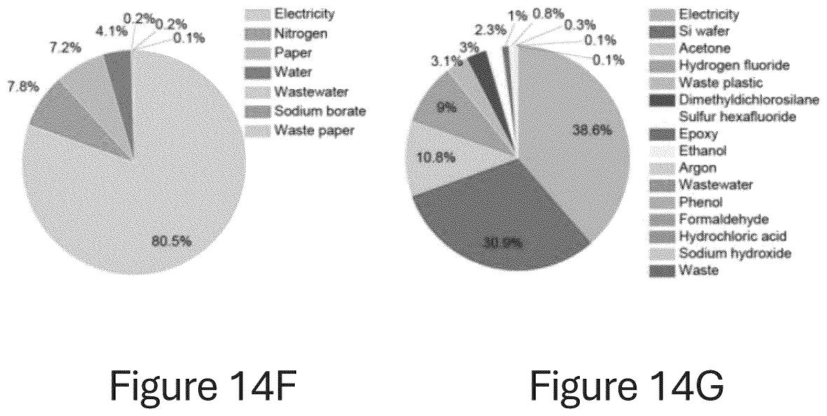

To illustrate the scalability of this approach, a R2R apparatus was built for the automated production of carbon-based devices. The R2R apparatus incorporates an integrated system including a salt impregnation unit, an electronic roller module, a laser writer, and the water-assisted transfer system (FIGS. 14A-14B & FIG. 16). Employing commercial paper roll, the R2R apparatus realized continuous fabrication for radio frequency identification (RFID) pattern (5.0 cm×0.8 cm) at a rate of 800 mm/h (FIG. 14C). The RFID tags can be swiftly transferred onto transparent PET rolls through a water-assisted process. An economic assessment of the materials and manufacturing process reveals that our technique is economically feasible, with an overall production cost estimated at approximately $1 per square meter. This cost efficiency is primarily due to the streamlined patterning and transfer processes with minimal use of chemicals and energy.

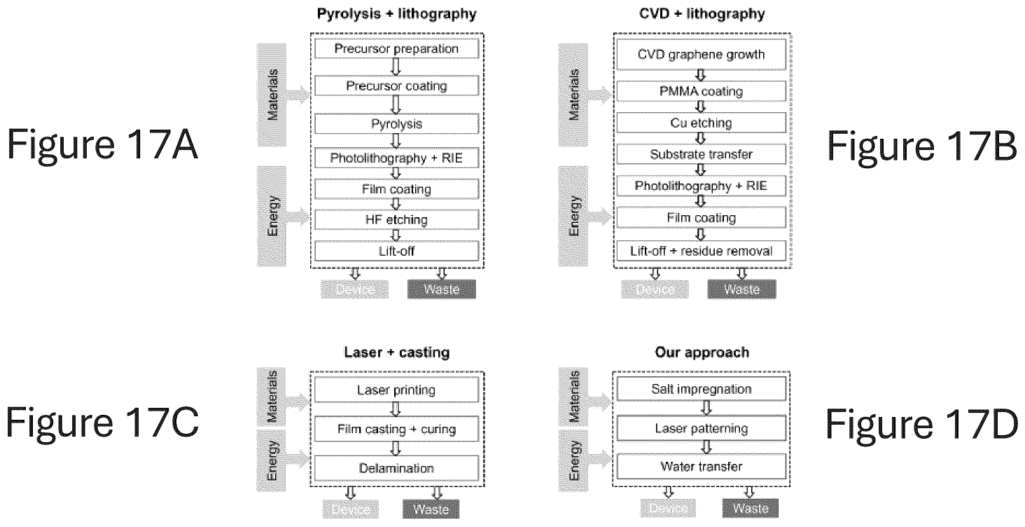

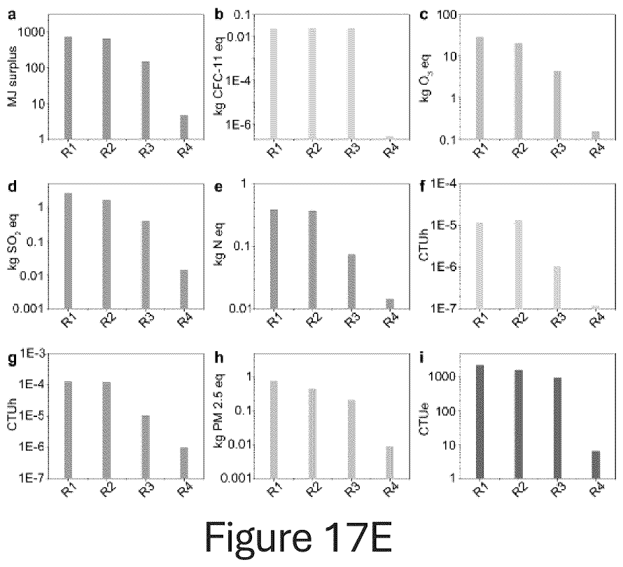

Compared to the subtractive processes typically used in conventional microfabrication, this research introduces an additive patterning approach. This approach replaces traditional processes like photolithography and etching and therefore reduces material and energy demands. To evaluate the environmental impact of our method, a preliminary life cycle analysis (LCA) was conducted during the “cradle-to-gate” stage based on the input of material and energy and the output from waste. Comparative analysis was conducted against conventional methods for fabricating carbon-based devices, including CVD+lithography methods, pyrolysis+lithography method, and lasering+casting method (FIG. 14D & FIG. 17). LCA result indicates that the GHG emissions for device fabrication per functional unit (m² device) by this proposed method are significantly lower (4.56 kg CO₂ eq) compared to pyrolysis (537.04 kg CO₂ eq), CVD (397.47 kg CO₂ eq), and lasering (124.55 kg CO₂ eq) methods, within a 95% confidence interval (FIG. 14E). In this method, the primary sources of GHG emissions are energy consumption, contributing 3.67 kg CO₂ eq m⁻² device, and gas usage, adding 0.36 kg CO₂ eq m⁻² device (FIG. 14F). By utilizing sustainable paper substrates and streamlining the fabrication and delamination processes, the carbon footprint was significantly lower. Moreover, this method shows the least environmental impact in terms of resource consumption, effects on terrestrial ecosystems, acidification, and human health (FIG. 17). In contrast, conventional methods involve intense consumption of materials and chemicals like Si wafers, epoxy, photoresist, etchants, organic solvents, and electricity consumption, which result in substantially higher environmental impacts (FIG. 14G).

### Results—Discussion

The microfabrication techniques, essential for electronics, healthcare, robotics, and other sectors, face inherent environmental challenges. This issue is addressed with a bioinspired strain engineering approach at permeable junctions, which resolves the dueling requirements of firm attachment and rapid release during microfabrication, thereby reducing energy and chemical consumption. While this approach primarily targets the production of carbon-based bioelectronic and catalytic devices, it holds the potential to serve as a model for making microfabrication techniques across various materials and device systems more sustainable. Demonstrating this, the CNF-enabled “permeable nanojunction” strategy achieves highest efficiency in fabricating bioelectronic devices with enhanced precision compared to traditional methods. This universality highlights the potential of our platform for generating devices with tailored properties for specific applications.

Manufacturing is moving towards being large-scale, intelligent, and carbon neutral. Our work demonstrates the practicality of continuous roll-to-roll processes to scale up from small laboratory experiments to large manufacturing production. The shift from traditional batch processing to automated manufacturing, and even data-driven online monitoring, represents the manufacturing nexus. Concurrently, the manufacturing sector must prioritize minimizing the carbon footprint throughout the life cycle. LCA is introduced to preliminarily quantify the environmental footprint of representative systems. In the future, by incorporating advanced analytical tools from data science field, the flows of material, energy, and greenhouse gases can be digitalized to comprehensively assess the environmental impacts of various microfabrication techniques across different stages. Identifying carbon emission hotspots will facilitate the development of effective solutions toward sustainable commercialization and application. As a starting point, this paradigm holds potential for guiding carbon-neutral development across many sectors, including energy storage device, sensors, flexible electronics, and robotics, etc.

### Methods—Substrate Fabrication

To prepare porous substrates, aqueous suspensions of sodium alginate (alginic acid sodium salt from brown algae, Sigma), CMC (average Mw ˜250,000, Sigma), agar (Fisher) were firstly prepared by autoclave under 100° C. for 15 min. Suspensions with weight concentrations between 5% and 10% (w/v) were then poured into plastic molds to achieve thicknesses ranging from 1 mm to 4 cm. Subsequently, the suspensions or gels underwent directional freezing in a dry ice and ethanol cooling bath at −72° C. After complete freezing, samples were freeze-dried for 3 days under 0.03 mbar pressure using a freeze dryer (Labconco) to form layer-structured porous scaffolds. Polymer membranes were created by pouring polymer suspension into molds and vacuum drying for 4 days at 60° C.

Common fiber-based porous substrates utilized were a selection of Whatman filter papers, including Grade 1, 602H, and 595 (Sigma). For the preparation of compressed paper substrates, Grade 1 Whatman filter papers were moistened with H₂O and placed between two stainless steel plates. The assembly was then subjected to a platen press (Dake, 44-225) at approximately 6 metric tons (˜5 MPa) of pressure and heated to 100° C. overnight.

### Methods—Substrates Preparation for Photochemical Synthesis

The fabrication of carbon membranes was accomplished using a salt-impregnation method. For fabrication on various aerogel samples, suspensions of different precursors were prepared in sodium borate solutions (0.15 M, pH 9.4) and freeze-dried. Grade 1 Whatman filter paper primarily served as the representative fiber-based porous substrate. The paper was first impregnated in aqueous solutions of sodium borate (0.15 M, pH 9.4), MgCl₂ (0.5 M), Fe(NO₃)₃ (0.5 M), Co(NO₃)₂ (0.5 M), and Zn(NO₃)₂ (0.5 M) for 1 hour and then dried at 60° C. overnight. Laser synthesis was performed using a CO₂ laser (VLS 4.60, Universal Laser Systems) with pre-designed patterns. Patterning was conducted in raster mode with optimized parameters (power, 1.8 W; speed, 1.6 cm/s; points per inch, 1000).

To fabricate metal-incorporated membranes, metal salts were either dissolved in water (0.5 M) or in sodium borate solution (0.15 M, pH 5.0). Paper substrates were impregnated in the mixed salt solution for 1 hour and then dried at 60° C. overnight. Laser fabrication and water-phase transfer were conducted.

### Methods—Swelling Analysis and Water-Assisted Transfer

The fiber network structures of cellulose-based substrates were examined using an inverted microscope (ECLIPSE Ti-2, Nikon). Structure profiles of cellulose fibers from various substrates, both before and after wetting, were analyzed with ImageJ (Fiji, v. 1.53 t). The swelling index (d′/d) and the energy release rate (G) of cellulose fibers were modulated by adjusting the intermolecular hydrogen bonds using ethanol/water mixtures. Sample sizes were N=7 for the 0%, 25%, 50%, 75%, and 100% ethanol groups, except for the 75% ethanol group which had N=5. The inhibitory effect of metal ions and the neutralization effect of EDTA were also investigated. Post-treated cellulose substrates were immersed in a 0.1 M EDTA solution, and the swelling ratio was measured. Sample sizes were as follows: N=8 for Ctrl, N=6 for Fe(III), N=6 for Co(III), N=7 for Cu(II), N=6 for Zn(II), N=7 for Fe-EDTA, N=6 for Co-EDTA, N=7 for Cu-EDTA, and N=6 for Zn-EDTA.

Water-assisted transfer was conducted through two processes: water-phase separation and capillary transfer. In the water-phase separation experiment, paper substrates were wetted with water. The swelling strain facilitated the separation of the carbon membrane from the supporting substrate in less than a second, causing it to float on the water surface. In a capillary transfer experiment, the supporting substrate was initially submerged in water and brought into contact with one end of the desired carbon membrane to form a contact line (the transfer front). For hydrophobic supporting substrates, external force could be applied to assist in forming the contact line. Then, the substrate was held by hand or a rotary knob and moved in a tilted or vertical direction at a low velocity. The high flexibility of the carbon membrane allowed it to conform to rough or 3D surfaces, enabling further fabrication on 3D devices or tissues.

### Methods—Nanofiber-Accelerated Microfabrication

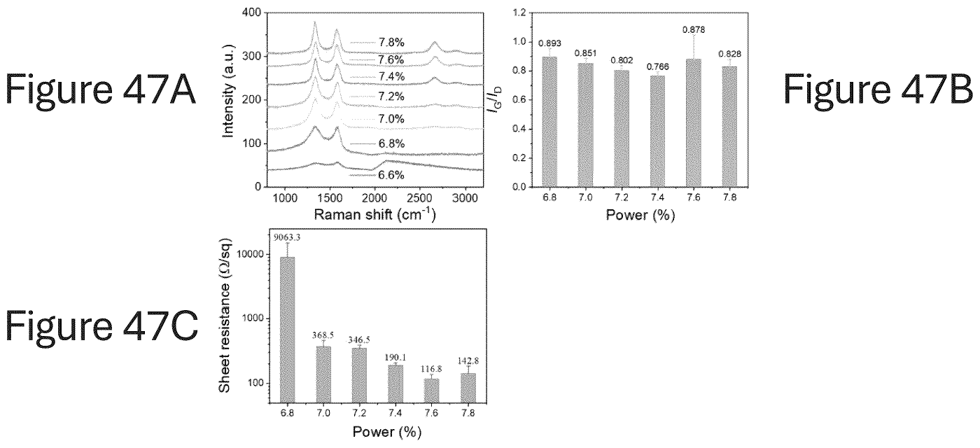

TEMPO oxidation for CNF synthesis (FIG. 47): This process initiates with the mechanical crushing of cellulose paper (Whatman, Grade 1) using a kitchen blender. The cellulose slurry then undergoes an alkaline-acid pretreatment, where it is soaked and stirred in a 15 wt % solution of NaOH for 2 hours. The fibers are then collected and subjected to thorough washing with distilled water. The microfibers are further processed through hydrolysis using a 1.0 M solution of HCl at 80° C., again for 2 hours, facilitating the solubilization of hemicelluloses. After centrifugation and washing, the fibers are bleached with a 2.0 wt % NaOH solution at 80° C. for 2 hours. After centrifugation and washing, the pulp is suspended in deionized water (˜2.0 wt %) and vigorously stirred. An aqueous solution containing sodium bromide (750 mg) and TEMPO (90 mg) is added, and the mixture is stirred continuously for 10 minutes. Next, a 4% sodium hypochlorite solution (30 mL) is added dropwise while maintaining the pH between 10 and 11 by adding sodium hydroxide. This mixture is left to react for 12 hours, following rinsing with water. Finally, the TEMPO-oxidized pulp slurry is agitated using a kitchen blender for 5 minutes to yield CNF dispersion.

CNF-enabled microfabrication and additive manufacturing (FIG. 15): Adhesion layer solutions are prepared by dissolving various polymers (CMC, dextran, and CNF) in water to achieve concentrations ranging from 2 to 5 wt % and then filtered (size cutoff. 0.22 μm). Rigid substrates such as silicon wafers (prime grade, 4-inch, Nova Electronic Materials) and glass slides are cleaned with acetone and isopropanol. These substrates are then treated with a 200 W oxygen plasma for 25 seconds and subsequently spin-coated with the prepared adhesion layer solutions at 1500 rpm, followed by a drying phase at 90° C. for 30 min. In the fabrication of flexible electronics, an SU-8 layer (SU-8 3005, Kayaku Advanced Materials) of approximately 8 m thickness is spin-coated, baked (95° C., 15 minutes), patterned using direct writer photolithography (MLA150, Heidelberg), and subjected to a post-baking process (95° C., 15 minutes). This is followed by a lift-off in SU-8 developer and a crosslinking phase. The fabrication of Au devices follows standard photolithography protocols. For additive manufacturing, CNF solution was first spin coated onto a Si wafer and a pre-designed structure was printed on the substrate with a fused deposition modeling printer (CR-6 SE, Creality). Lift-off experiments for different adhesion layers are conducted by immersing the substrates in hot water (60° C.) without any turbulence.

### Methods—Device Design and Fabrication

Serpentine structure and multichannel electrode were designed using AutoCAD software. For the fabrication of multichannel electrodes for sciatic stimulation, a carbon membrane was first produced on paper substrates (Whatman filter paper, Grade 1) using a lasering process. Subsequently, a standard water-phase transfer procedure was applied to transfer the multichannel electrodes onto PET film (12.5 μm). After drying, approximately 20 μL of Nafion 117 solution (˜5% in a mixture of lower aliphatic alcohols and water, Sigma) was applied to the carbon patterns and allowed to dry under ambient conditions for fixation. Multichannel Au electrodes (thickness: Ti, 5 nm; Au, 100 nm) were fabricated using a photomask-based procedure on PET substrate. Devices were rinsed with water and used for biological testing without further pretreatment. To prepare microcapacitor-grafted electrodes for heart modulation, a planar Au film (thickness: Ti, 5 nm; Au, 100 nm) was fabricated on a 50 μm PET substrate via e-beam coating. A serpentine carbon structure was patterned onto a paper substrate and transferred onto the Au electrode using a standard water-phase transfer method. To fabricate carbon-coated recording electrodes, 4×4 microelectrode arrays were created on a 25 μm PI film and sealed with PET using a standard photolithography procedure. Carbon was transferred onto the microelectrode array. After drying, a 10 wt % EVA solution in hexane was applied to the carbon membrane, and the assembly was pressed onto the microelectrode array using a commercial hot laminator under a processing temperature of 120° C.

### Methods—Material Characterization of Carbon Membrane

The surface structures of various substrates and carbon membrane were characterized using scanning electron microscopy (SEM) (Merlin, Carl Zeiss) at 3 kV. For transmission electron microscopy (TEM) characterization, carbon samples were separated from substrate, ultrasonicated, and dropped onto copper grids (lacey formvar/carbon, Ted Pella). Morphology and crystallinity were observed with JEM-3010 (JEOL) or Tecnai F30 (FEI) at 300 kV. Scanning transmission electron microscopy (STEM) was performed using a 200-kV aberration-corrected JEOL ARM200F system with a cold field-emission source, providing a spatial resolution of approximately 0.8 Å. Raman spectra were collected with a LabRAM HR Evolution system (Horiba) using 50× objective and 532 nm laser. Material composition was characterized using X-ray photon spectroscopy (XPS, AXIS Nova, Kratos). X-ray diffraction (XRD) spectra of paper substrate and carbon membrane were obtained on XRD spectrometer (MiniFlex, Rigaku) at a wavelength of 1.540593 Å. Surface area and pore size of carbon membrane was measured with an adsorption analyzer (3Flex, Micromeritics).

### Ethics

All animal procedures were approved by the Institutional Animal Care and Use Committee of the University of Chicago in protocol number 72378.

### Ethics—In Vivo Sciatic Stimulation

The in vivo stimulation was conducted with cuff-type electrodes interfacing with sciatic nerves. Briefly, adult rats (Sprague-Dawley strain, Charles River Laboratories) were deeply anaesthetized with isoflurane (3-4%). The fur was removed from the hindquarters using a surgical clippers and hair removal cream. A semi-circular incision across the midline was made in the skin, and the fascial plane was opened between the gluteus maximus and the anterior head of the biceps femoris, thereby exposing the sciatic nerve. Two-electrode configuration was used, where the multichannel device was wrapped around the sciatic nerve. During sciatic stimulation, biphasic waveform was used whereas one electrode acted as the working electrode while another one acted as the counter electrode/reference electrode. For EMG recording, stainless steel needle electrode in a grounded configuration were inserted into the soleus and connected to an Intantech RHD USB interface board and RHD 16-channel bipolar-input recording headstage. The USB interface board was controlled using RHX software (v. 3.0.4, Intantech). The signals were recorded at 10 kS s⁻¹ in the 0.1-200 Hz bandwidth. For the analysis of leg displacement, a protractor was placed under the leg for a distance reference. Videos of limb movement were recorded using a digital camera (α6100, Sony).

### Ethics—Electrical Heart Stimulation Ex Vivo

Electrical stimulation was conducted with an isolated heart model. Briefly, an adult rat (male, >300 g body weight) was heparinized (1000 IU per kilogram body mass) and anaesthetized with isoflurane. The heart was removed and placed in ice cold HBSS buffer, and the aorta was cannulated for use in a Langendorff set-up. Oxygenated HEPES-buffered Tyrode's solution (pH 7.3) was perfused through the cannulated aorta after a heating coil and bubble trap to maintain a temperature of 37° C. The sinoatrial node along with the atria were removed to lower the atrioventricular node pace. The perfusion pressure (PP) was monitored using a BP-100 probe (iWorx) connected to the perfusion line and was maintained at 80-100 mmHg. Left ventricular pressure (LVP) was monitored through a water-filled balloon (Radnoti) inserted into the LV. For ECG recordings, needle electrodes were positioned on the left ventricular wall and aorta, grounded on the cannula, and connected to a C-ISO-256 preamplifier (iWorx). All signals (perfusion, left ventricular pressure and ECG) were amplified using an IA-400D amplifier (iWorx) and interfaced with a computer using a Digidata 1550 digitizer with Clampex software (v. 10.7, Molecular Devices).

Stimulation electrodes (0.5 cm×0.5 cm) were connected in a two-electrode configuration, where the working electrode was placed on the left ventricular wall while the counter electrode was placed on the right ventricular wall and connected to the ground. Square current waveforms were delivered through a potentiostation (SP-200, BioLogic), and the potential between the two electrodes was recorded during stimulation.

Electrical recording was performed using a 4×4 microelectrode array (2 mm spacing between electrodes) and recorded using an Intantech RHD USB interface board and RHD 16-channel input recording headstage. The signals were recorded at 10 kS s⁻¹ in the 0.1-100 Hz bandwidth. Isochrone maps of the electrical propagation were calculated using Python. A timestamp of peak positive signal deflection for each contraction was determined, and the average was calculated for multiple signals. Gaussian interpolation was used for map rendering to improve readability.

### Ethics—Biomimetic Hg (II) Detection Using Catalytic Robotics

Water strider-like robots were fabricated using a lasering process after Pt-incorporated salt impregnation and transferred onto PET substrates (12.5 μm). Nafion 117 was employed to secure the functional carbon on the supporting substrates. Motion behaviors of robots in PTFE containers were recorded using a digital camera (α6100, Sony). Recorded videos were processed using the DeepLabCut toolbox, a markerless pose tracking algorithm based on deep neural network training. Videos were initially segmented and extracted into batches of 50 images per video using a k-means algorithm. Center point positions were manually labeled and subsequently used for training the neural network model based on the ResNet50 framework with an iteration of 5000 epochs. Predicted positions were evaluated using a validation set to determine the maximum error in axial coordinates in terms of pixels. Once trained, the neural network can be utilized to apply labels to new videos for batch processing.

### Buildup of R2R Apparatus

A roll-to-roll apparatus was designed using Autodesk Inventor, with mechanical components and raw materials sourced from McMaster-Carr. The machining and assembly took place in-house at the University of Chicago MRSEC Student Machine Shop. During the assembly process, paper was fed from the supply roll (width of 6 cm) through a set of idler rollers and pulled using a capstan roll driven by a stepper motor. A Joule heater, assembled from resistive wire and enclosed in high-temperature fiberglass sleeving, provided electrical insulation. The heater was powered by a benchtop AC-AC converter (operation voltage of 15 V) connected to the standard North American 110 VAC electrical grid. A refurbished K40 CO₂ laser was controlled by Python scripts and coordinated with a stepper motor integrated into an Arduino board. The control software was based on the K40 Whisperer source code, which was obtained from www.scorchworks.com/K40whisperer/k40whisperer.html#download and distributed under the GNU GPL. The software was modified to allow control of the roller stepper motor and execute sequential pre-programmed ablation. (FIG. 16).

### Life Cycle Analysis

In this study, a cradle-to-gate LCA was conducted to analyze the environmental impacts arising from the production of devices using both conventional methods (CVD, pyrolysis, lasering) and this approach. This evaluation aims to quantify the total environmental impacts and the contribution from each fabrication process. The system boundary includes the extraction and processing of raw materials, energy consumption, and waste generation, specifically excluding the product's usage, end-of-life disposal, and the construction of utilities. The functional unit (FU) was defined as 1 m² of monolithic device. Life cycle inventory (LCI) data for each method were organized according to standard laboratory practices within the established system boundary (FIG. 17). The LCA was performed using the Ecoinvent database (version 3.8) in SimaPro (version 9.4). TRACI 2.1 (v 1.07/US 2008) method was employed for the assessment of total GHG emissions and other environmental impacts.

### Data Processing and Statistics

Analysis of numerical data and plotting was performed with OriginLab (v. 2021), Microsoft Excel (v. 2016), Python (v. 3.8.12) scripts using NumPy (v. 1.22.1), Matplotlib (v. 3.5.1), Scipy (v. 1.7.3), pybaselines (v. 0.8.0) and Seaborn (v. 0.11.2) libraries. Machine learning-based video processing was analyzed with DeepLabCut (v. 2.3) under CONDA environment. Data were statistically analyzed with ordinary one-way analysis of variance comparisons test with Prism (v. 9, GraphPad) unless specified in the figure legends. Electron microscopy images were processed using ImageJ (Fiji, v. 1.53 t). Adobe Premiere 2021 was used for cropping and slicing video recordings. The recordings from the 16-channel device on the rat heart was analyzed by customized Python scripts.

### Materials and Methods—Substrate Fabrication

To prepare porous substrates, aqueous suspensions of sodium alginate (alginic acid sodium salt from brown algae, Sigma), sodium carboxymethyl cellulose (CMC, average Mw ˜250,000, Sigma), agar (Fisher) were firstly prepared by autoclave under 100° C. for 15 min. Suspensions with weight concentrations between 5% and 10% (w/v) were then poured into plastic molds to achieve thicknesses ranging from 1 mm to 4 cm. Subsequently, the suspensions or gels underwent directional freezing in a dry ice and ethanol cooling bath at −72° C. After complete freezing, samples were freeze-dried for 3 days under 0.03 mbar pressure using a freeze dryer (Labconco) to form layer-structured porous scaffolds. Polymer membranes were created by pouring polymer suspension into molds and vacuum drying for 4 days at 60° C.

Common fiber-based porous substrates utilized were a selection of Whatman filter papers, including Grade 1, 602H, and 595 (Sigma). For the preparation of compressed paper substrates, Grade 1 Whatman filter papers were moistened with H₂O and placed between two stainless steel plates. The assembly was then subjected to a platen press (Dake, 44-225) at approximately 6 metric tons (˜5 MPa) of pressure and heated to 100° C. overnight.

### Materials and Methods—Observation of Interfacial Separation

To examine the water penetration speed in various substrates, 16 L droplets of deionized water (18.2 MΩ) were gently deposited onto material surfaces using an injection syringe with a 1.93 mm needle diameter. The dynamic change in droplet shape and images of each droplet were captured on a contact angle analyzer (Kruss, DSA100) at a frame rate of 500 fps. The liquid drop profile exiting the syringe was recorded, and the contact area was determined using ImageJ (NIH).

To investigate water-assisted interfacial separation, a 1 mm wide and 1 cm long carbon membrane was patterned onto a paper substrate. Water droplets (16 L) were then aligned with the carbon slices and dropped onto the surface. The wicking process and water-assisted interfacial peeling were captured at a frame rate of 250 fps. Pseudo-color was added to the image sequences to differentiate between the paper substrate (green), carbon (red), and water droplet (blue).

### Materials and Methods—Molecular Analysis of the Swelling Process

FTIR-ATR measurements were carried out using an FT-IR instrument (Nicolet iS50 Flex, Thermo) equipped with a DLaTGS detector. During the measurement, cellulose fibers were pressed upon a GeSe crystal, and FTIR spectra were collected in a wavenumber range from 400 to 4000 cm⁻¹. To investigate the interaction between solvent and cellulose, solvents including H₂O, D₂O, EtOH, and EtOD were carefully applied to wet the cellulose fibers. Each group was characterized with at least five replicates. Baseline correction was performed linearly based on the absorbance at 1459 and 3724 cm⁻¹. Hydrogen bonds formed between cellulose and solvents were resolved by fitting and deconvoluting the FTIR spectra using XPSPEAK (V 4.0).

### Materials and Methods—Structural Analysis of Carbon Membrane and Substrate

To investigate morphological alterations of porous substrates in water, cellulose-based filter paper (Grade 1, Whatman, Sigma) was stained with RhB (50 mg/L) and subsequently dried at 60° C. Fiber network structures before and after water wetting were examined using a confocal microscope (SP5, Leica). Fluorescence images were captured with a 10× objective, using an excitation wavelength of 561 nm and an emission range of 600-700 nm. 3D reconstruction of substrate was processed using Arivis Vision4D software (Zeiss). Height profiles of various substrates were characterized and analyzed using a 3D laser scanning microscope (LEXT OLS5000, Olympus).

### Materials and Methods—Templated Synthesis of Functional Si Crystal on Carbon Scaffold

Templated synthesis of Si material was achieved after transferring carbon membrane onto quartz slide. Then, the growth of Si on carbon scaffold was achieved based on CVD method. The growth conditions of CVD were increasing T to 750° C. in vacuum (50° C./min); 0.35 sccm SiH₄+60 sccm H₂, at a pressure of 15 Torr for 15 min; increasing T to 1000° C. in vacuum and held for 15 min; and slowly cooling down to RT.

### Materials and Methods—Raman Characterization

Raman spectra were collected with a LabRAM HR Evolution system (Horiba) using 50× objective and 532 nm laser.

### Materials and Methods—XPS/XRD/BET Measurement

Material composition was characterized using X-ray photon spectroscopy (XPS, AXIS Nova, Kratos). X-ray diffraction (XRD) spectra of paper substrate and carbon membrane were obtained on XRD spectrometer (MiniFlex, Rigaku) at a wavelength of 1.540593 Å. Surface area and pore size of carbon membrane was measured with an adsorption analyzer (3Flex, Micromeritics).

### Materials and Methods—CT Scanning

To investigate the interface between cellulose network and carbon membrane, samples were scanned with a micro-computed tomography (Micro-CT) system (PaleoCT. General Electric). Data was acquired with a transmission 60 kV nanofocus X-ray tube at a resolution of 1.5 m. 1100 images were generated by averaging of 5 back-projections with an exposure time of 2000 ms/projection. After acquisition, reconstruction was processed, segmented, and visualized using 3D Slicer.

### Materials and Methods—Measurement of Temperature Profile during Laser Synthesis

To investigate the temperature change during laser synthesis, emission light was collected on a 1024-channel CCD spectrometer (Fergie, Teledyne Princeton Instruments) with a wavelength range of 550-1100 nm. The emission spectrum was obtained by focusing a multimode optical fiber (M133L02, Ø200 μm, 0.22 NA, High OH, Thorlabs) with a collimator on the lasering point during the process. Using a 295 g/mm grating, a spectral resolution of 0.53 nm was achieved. Spectra were read in kinetics mode with a window height of 32 rows. The instrument was calibrated with a standard Hg lamp, while the optical fiber was calibrated using its standard attenuation data. For time-resolved emission measurements, the laser head moved at a speed of 1.6 cm/s, and the time resolution of spectral collection was set at 3 ms. Following calibration, emission spectra were fitted to the blackbody radiation equation.

$${B}_{λ} ( λ , T ) = γ \frac{2 {hc}^{2}}{( \frac{hc}{{e}^{λ {k}_{B} T}} - 1 ) {λ}^{5}}$$

In the equation, k_{B} represents the Boltzmann constant, h stands for the Planck constant, c is the speed of light, λ is the wavelength, and γ is a constant introduced for fitting purposes. Although carbon materials do not exhibit constant emissivity for blackbody radiation, the minor variation in the measured wavelength range still allows for an estimation of the temperature profile during the lasering process.

### Materials and Methods—TGA Measurement

Thermogravimetric analysis (TGA) was carried out on thermogravimetric analyzer (TGA 5500, TA Instruments). Approximately 5 mg of sample was heated to 600° C. at different heating rates using nitrogen as the purge gas.

### Materials and Methods—Electrical and Electrochemical Characterization

Carbon membranes with dimensions of 25 mm×10 mm were printed on substrates. Sheet resistance (Rs) was measured using direct current four-point probe method with source meter (B2901A, Keysight).

Cyclic voltammetry (CV) characterizations were performed in 1×PBS buffer using a potentiostation (SP-200, BioLogic) controlled with EC-Lab software. A three-electrode configuration was employed, utilizing a platinum wire as the counter electrode, an Ag/AgCl electrode (1.0 M KCl) as the reference electrode, and carbon membrane as the working electrode. Areal capacitance (C) of the electrode was calculated by integrating the total cathodic/anodic area in the CV curve, C=(∫IdV)/(sΔVA), where I is the current, V is the potential (−0.4 V to 0.4 V), s is the scan rate (100 mV/s), ΔV is the potential window, and A is the planar area of the electrode. After membrane transfer, Nafion 117 solution was used to fix membrane on other substrates.

Potentiostatic electrochemical impedance spectroscopy (PEIS) was conducted in PBS buffer using a sine wave with frequencies ranging from 1 Hz to 1 MHz and a signal amplitude of 10 mV in a three-electrode configuration. In a charge injection experiment, voltage transients were measured using a potentiostat (SP-200, BioLogic). A platinum wire served as the counter electrode, and a Ag/AgCl reference electrode was employed. For the measurement, the carbon electrode was stabilized at 0 V versus Ag/AgCl for 1 ms in PBS at room temperature. Cathodic and anodic current pulses, each 700 s in duration, were delivered to the electrode with an interpulse delay of 28 s. The most negative (Emc) and positive (Ema) polarization potentials were assigned 28 s after the maximum of their respective peaks to account for access voltage and instrument delay. The charge injection limit was determined as the maximum charge injected without exceeding the −0.6 to 0.6 V potential window.

### Materials and Methods—Characterization of Catalase-Like Property

Potassium tetrachloroplatinate (0.005% to 5 wt %) was dissolved in sodium borate solution (150 mM) under varying pH conditions. The catalytic nanozyme membrane was obtained through paper impregnation, laser processing, and water-phase separation. The catalytic performance of the catalase-like membrane was evaluated based on the H₂O₂ decomposition rate. In a typical experiment, a catalytic membrane of a specific area was dispersed in H₂O₂ solution (20 mM, 10 mL) and allowed to react at room temperature without stirring. The concentration of H₂O₂ was quantified using a UV-vis spectrometer (UV-3600, Shimadzu) based on the absorption at 240 nm. Particulate matter was removed from the reactants after filtering through a PES filter with a size cutoff of 0.22 m.

### Materials and Methods—Measurement of the Dynamics of Bubble Generation and Burst

The dynamics of bubble generation were measured with an inverted microscopy (ECLIPSE Ti-2, Nikon) with 10× objective (N.A., 0.2). Catalytic particles dispersed in solutions were dropped onto PET substrate, dried under air, and fixed using Nafion 117 solution. Under transmittance white light, the projected bubble formation below PET substrates in H₂O₂ solution (1.0 M) was recorded at a frame rate of 10 min⁻¹. The nucleation, growth, coalescence, and movement of bubbles were analyzed in ImageJ (NIH). The burst dynamics of O₂ bubble were captured on a contact angle analyzer (Kruss, DSA100) at a frame rate of 100 fps.

### Materials and Methods—Active Pollutant Targeting and Removal

Catalytic robots were transferred onto PET substrates to actively eliminate pollutants. These robots were then dispersed in simulated polluted water samples, where Rhodamine B (RhB) was chosen as the pollutant of interest, with a concentration of 10 mg/L. Persulfate (PMS, 10 mg/L) was introduced to serve as the activator for reactive species, as the carbon-based material in the robots can effectively catalyze PMS decomposition, generating sulfate radicals (SO₄⁻¹). Additionally, hydrogen peroxide (H₂O₂, 1.0 M) was added to stimulate the reaction system's active motion. Three robots with a total surface area of 1.5 cm² was employed to actively target pollutants in each group, with a total reaction volume of 20 mL. RhB concentrations were then measured based on the absorbance at 554 nm.

### V. EXAMPLES

### Example 1: Theoretical Simulations of Interfacial Separation

Finite Element (FE) modeling along with the cohesive zone model were employed to compare the separation of a stiff membrane from two different types of swollen substrates: a porous one versus a nonporous one. The separation was hypothesized to be primarily due to shear stress induced by the swelling of the substrate. A 2D model was developed using the coupled temperature-displacement analysis in ABAQUS to simulate this process, where the heat equation along with thermal expansion is used to mimic the swelling of the supporting substrate that follows Fick's law:

$$\frac{δ T}{δ t} = α {∇}^{2} T$$

where T is the temperature, representing water concentration, i.e. the volume ratio of water to dry polymer; when T=0 means the dry state. α is the thermal diffusivity representing the diffusion coefficient in Fick's second law, and we will use α_{expand} for the thermal expansion coefficient representing the coefficient of hygroscopic swelling.

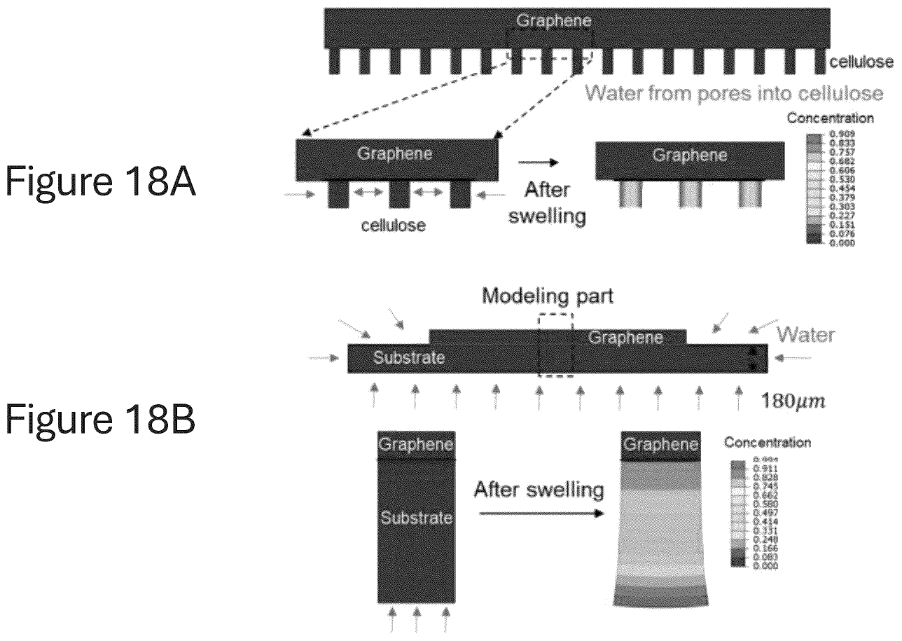

In general, the model included a stiff graphene membrane with a representative Young's modulus 1 TPa, and Poisson's ratio 0.3 at the top connecting a substrate at the bottom. The porous substrate is composed of cellulose fibers of 10 μm diameters (FIG. 18A) with diffusivity 10 μm²/s. The ethanol-concentration-dependent modulus and expansion coefficient of cellulose used in the model is listed in Table 3 below. The fibers were assumed to be uniformly distributed and the water fills in the small pores instantaneously once immersed. Therefore, the main kinetic process is water diffusion across the fibers. In contrast, for the nonporous substrate, water comes from the surroundings. As the thickness is much smaller than the width, water diffusion through the thickness of the substrate determines the time of full separation. In this way, the very middle part of the substrate was selected with a length of 100 μm and thickness of 180 μm for the model as shown in FIG. 18B. The mechanical and swelling properties of the nonporous substrate are the same as those of the cellulose fibers for better comparison. On the boundary, the flux condition was assumed to be described by

$$q = - h ( T - {T}_{en} )$$

where q is the water flux, h is a transfer coefficient assuming as 10 μm⁻²s⁻¹, and Tₑₙ represents the water concentration in the environment.

TABLE 3
Ethanol-concentration-dependent cellulose properties.

| Ethanol | | | |
|---|---|---|---|
| Concentration | Youngs' modulus (MPa) | Poisson's ratio | α_{expand} |
| 1 | 1450 | 0.3 | 0 |
| 0.5 | 500 | 0.3 | 0.1 |
| 0 | 134 | 0.3 | 0.3 |

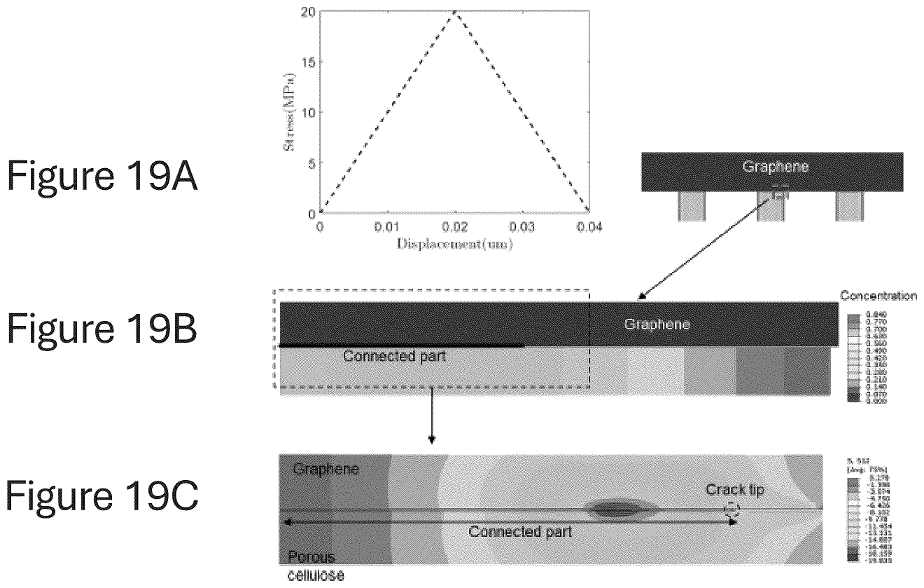

A layer of cohesive elements was embedded between the graphene membrane and the substrate with a linear traction-separation law as shown in FIG. 19A. The elements were assumed to have a thickness of 0.1 μm and Young's modulus of 100 MPa. To better match the simulation predictions of the delamination time to the experimental results for both substrates, we assume the maximum nominal stress in the traction-separation law as 20 MPa and the fracture energy is 0.4 J/m². We assume separation is caused by the shear mode. In addition, a viscous damage variable of 0.0001 s was used to mitigate the convergent issue. The cohesive elements were meshed with maximum degradation of 0.99, which means once the stiffness degradation ≥0.99 for an element, that element is considered as damaged. To prevent penetration of the graphene membrane and the substrate as compression occurs during the simulation, a surface-to-surface contact with small sliding was assigned between them. The tangential behavior was chosen to be frictionless and the normal behavior to be hard contact.

FIG. 19 displays the water concentration gradient (FIG. 19B) and shear stress (FIG. 19C) distributions when the separation reaches approximately 50% of a half single fiber in a porous cellulose substrate. The concentration distribution decreases from right to left as water comes from the right side. At this moment, the point at the crack tip deforms significantly and has already passed the critical shear stress, leading to a drop in the shear stress as deformation increases. The region ahead of the crack tip (FIG. 19C) has minimal deformation, but peaked shear stress.

### Example 2: Laser Synthesis of Graphene/Carbon Membrane

### 2.1 Physiochemical Properties of Cellulose Before and After Salt Treatment

In this study, sodium borate was introduced for the physical modification of various hydrophilic substrate, including CMC, cellulose, sodium alginate, and agar, using a simple impregnation method in aqueous solutions. By using cellulose fiber as the representative, the sodium borate modification was demonstrated to not affect the amorphous or crystalline structures of cellulose. Furthermore, these salts exhibit high affinity towards water, thereby creating a hydrophilic environment for rapid water absorption for cellulose fibers.

### 2.2 Characterization and Optimization of Laser Synthesis Condition

Celluloses are abundantly available from various biomass sources (for example, wood) and feature a one-dimensianal (1D) hierarchical structure rich in oxygen-containing polar functional groups (for example, hydroxyl) in the form of repeating anhydroglucose units (AGUs) that make up the cellulose molecular chains. These AGUs provide an abundant carbon source for directly fabricating graphene-based electronics. However, the low activation energy (Ea) of carbonization of cellulose under high temperature doesn't naturally allow for graphitization. Here, the physical modification of cellulose using sodium borate or magnesium chloride was shown to be achieved without breaking/coordinating the amorphous, crystalline or surface structure of cellulose fibers. After the modification, laser synthesis of graphene-based electronics can be achieved from AGUs on cellulose substrates (for example, paper). See Table 4 below.

TABLE 4
Specific surface area, pore volume, and pore
size of cellulose paper and carbon membrane.

| | | | Average |
|---|---|---|---|
| | BET surface area | Total pore volume | pore size |
| Sample | (m²/s) | (cm³/g) | (nm) |
| Cellulose paper | 8.592 | 0.011 | 2.898 |
| Cellulose paper- | 8.859 | 0.012 | 3.263 |
| impregnated | | | |
| Cellulos paper-after | 9.003 | 0.010 | 2.645 |
| lasering | | | |
| Cellulose paper- | 14.623 | 0.020 | 3.018 |
| impregnated/ | | | |
| lasering | | | |
| Carbon membrane | 87.458 | 0.248 | 3.103 |

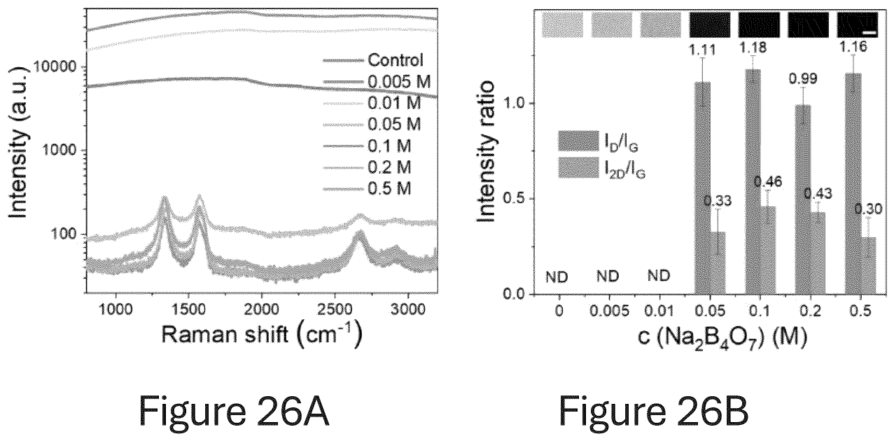

According to Raman characterization (FIG. 26), the resulting material exhibits three notable graphite peaks: the D peak at ˜1,350 cm⁻¹ (defects or bent sp²-carbon bonds), the G peak at ˜1,580 cm⁻¹, and the 2D peak at ˜2,700 cm⁻¹ (second-order zoneboundary phonons). Thin carbon flakes with ripple-like wrinkled structures were observed on the TEM grid, confirming the formation of graphitic materials through laser ablation (FIG. 25). The average lattice spacing of ˜3.5 Å corresponds to the (002) plane distance in graphitic materials, with turbostratic stacking occurring when interlayer spacing exceeds 3.42 Å. The prominent sp²-C peak (284.0 eV) in XPS spectra reveals the presence of graphite, while the control group displays sp³-C (284.8 eV) and C—O (286.0 eV), representing pristine cellulose fibers. As indicated in the Raman spectra (FIG. 26), a high fluorescence background can be observed when the borate concentration is below 0.05 M, implying that no graphitization occurs during lasering. This highlights the importance of salt in the graphitization process. However, as the borate concentration increases further (>0.05 M), the graphitization remains almost constant.

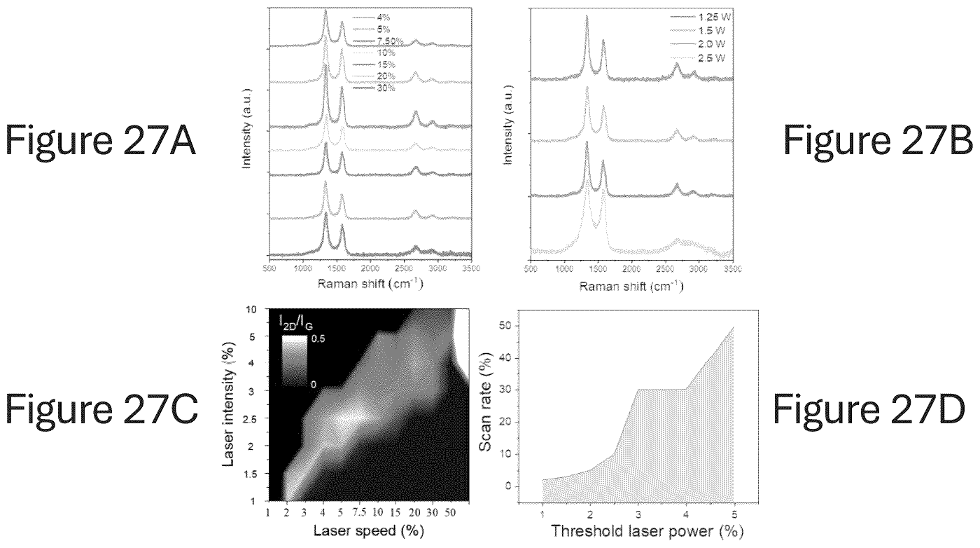

Graphene formation was optimized by adjusting laser power and scan speed (FIG. 27), revealing a critical laser energy of 11.2 mJ for successful graphitization. Optimal intensity and scan speed were 1.8 W and 1.6 cm/s, respectively, with an average laser intensity of 18 kW/cm². According to the temperature measurement, the transient localized temperature at the laser point reached up to 3700 K, with an average temperature ramping speed of approximately 6.2×10⁵ K/s under a lasering power of 1.5 W and a laser speed of 1.6 cm/s.

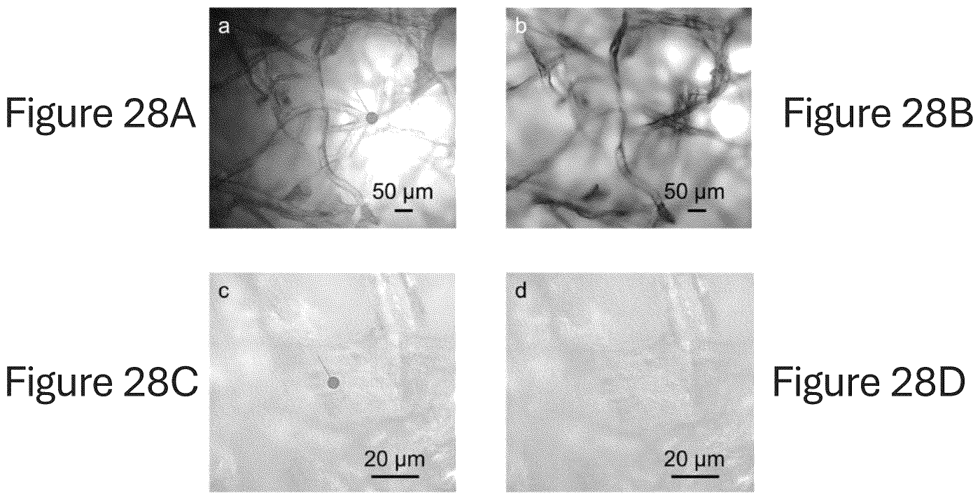

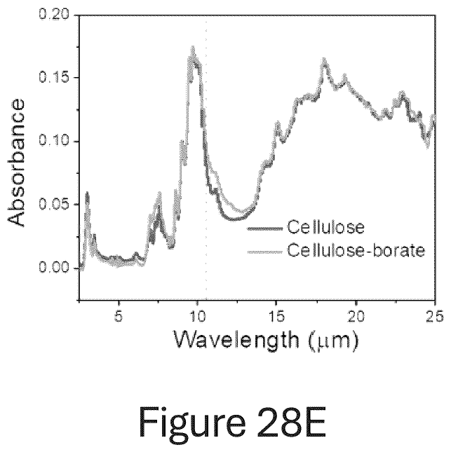

The strong absorbance of cellulose at 1025 cm⁻¹ (stretching mode of C—O, FIG. 28) coincides with the laser wavelength of 10.6 μm, promoting rapid temperature increase during laser illumination. Relatively, using other lasers, e.g., 473 nm and 532 nm, no carbon or graphene formation were found even when the irradiation dose was much higher.

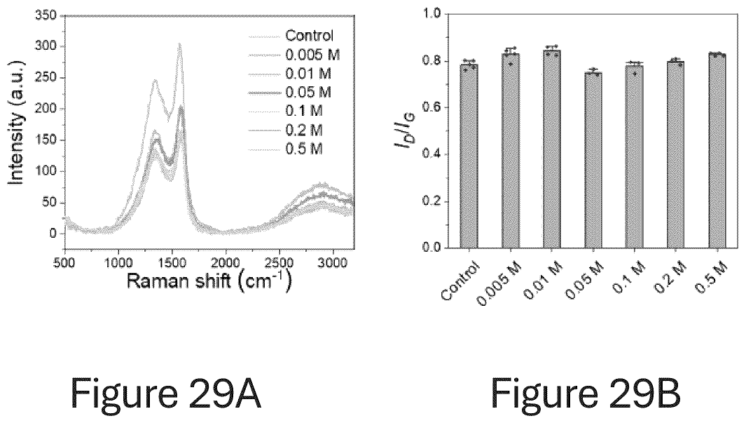

Laser irradiation on cellulose fibers produced amorphous microstructures, whereas static heating at 600° C. for 2 hours in a nitrogen atmosphere preserved the original fiber structure. The morphological differences suggest wet texturing or other processes requiring further investigation. Moreover, according to the Raman measurement on pyrolyzed cellulose samples with different borate concentration (FIG. 29), no graphene material was formed even when borate concentration was high (0.5 M). Therefore, it's speculated that ultrahigh T and T ramping speed are the critical condition for cellulose conversion to graphene material.

### 2.3 Energy Basis for the Graphitization of Natural Polymers Under Lasering

Before salt modification, paper substrates experienced localized heating, leading to noticeable morphological changes from pristine fibers to granular or segregated particles after laser illumination. However, no graphene material formation was observed post-lasering. The effect of salt was further demonstrated by adsorption experiments that adsorbed borate salt reached up to 58.4% of the weight of pristine cellulose. To differentiate between chemically and physically bound borate in graphitization, pre-impregnated cellulose paper was washed to remove physically bound sodium borate. Almost no weight increase was observed after washing, implying that sodium borate primarily interacts with cellulose physically. Further lasering on borate-removed papers did not produce carbon layers, suggesting that chemically bound borate did not contribute to graphitization. Impregnation allowed salt permeability within cellulose fibers, providing a homogeneous salt-coated environment for catalyzing the lasering process.

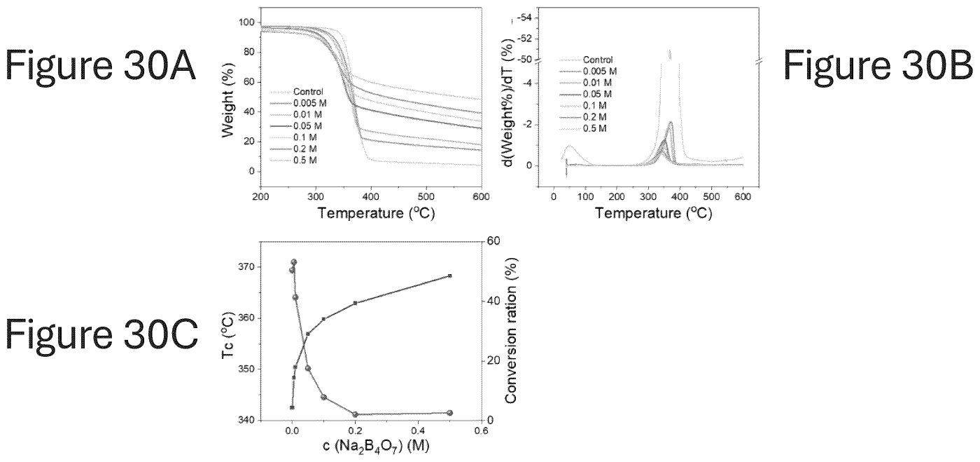

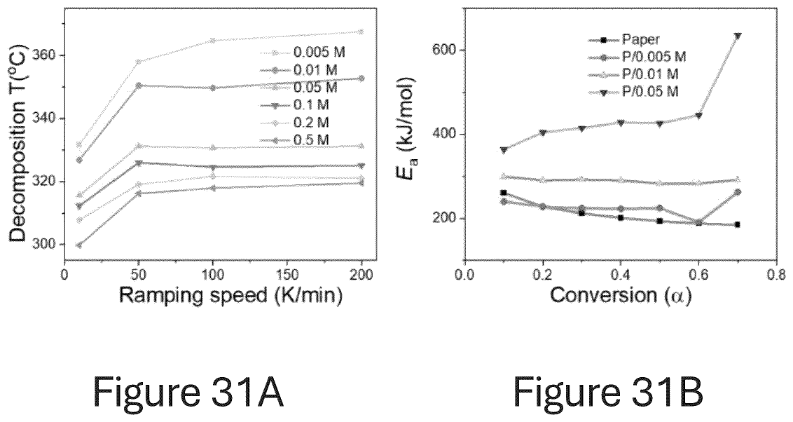

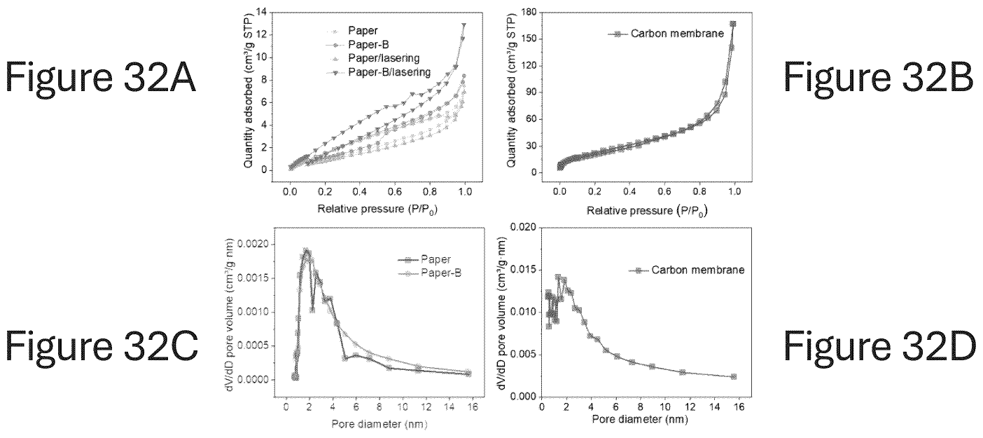

According to TGA results (FIG. 30), borate significantly reduces the decomposition temperature and enhances char yield, even at very low concentrations during impregnation (0.005/0.01 M). As reported previously, higher heating rates typically result in lower char yields and increased cellobiose during dehydration and glycosidic reactions. Comparisons Eₐ of with low borate loadings (FIG. 31) reveal that borate increases the activation energy of weight loss reaction: cellulose→char+gas↑. This corresponds to the increased char residue observed when borate is loaded (weight loss decreased). The energy barrier created by the borate layer on cellulose fibers may contribute to higher char production during rapid temperature increases, while ultrafast temperature increases may facilitate effective graphitization.

Previous studies have utilized paper as a porous substrate for low-cost, disposable, breathable, and lightweight wearable electronics. Cellulose substrates can be directly converted to graphene material by direct laser writing using commercial CO₂ laser sources after appropriate chemical treatment with fire-retardant chemicals to enhance thermal resistance. Although these chemicals aid in graphene formation, they also increase the hydrophobicity of cellulose, which prevents the swelling of cellulose fibers in water.

### 2.4 Characterization of the Materials Fabricated Using R2R Apparatus

During the roll-to-roll (R2R) fabrication (FIG. 46), various parameters were assessed to determine their impact on the quality of carbon patterns. The raster speed was maintained at 100 mm/s while the effect of laser power on the patterns was investigated. A minimum of four samples were analyzed using Raman spectroscopy and resistance measurement techniques. Raman characterization (FIG. 47) revealed that with an increase in laser power, the intensity of the D (˜1335 cm⁻¹), G (˜1580 cm⁻¹), and 2D (˜2665 cm⁻¹) peaks on the carbon surface also increased. The highest I_{G}/I_{D} value of 0.88 was achieved at a power setting of 7.6%. The presence of 2D peaks at power levels above 7.2% suggested graphene formation. The scanning speed remained constant as the power intensity was increased. According to conductivity measurements, the lowest sheet resistance of 116.8 Ω/sq was obtained at a laser power of 7.6%. For subsequent R2R fabrication, the instrumental settings of 100 mm/s speed and 7.2% power were employed.

### Example 3: Water-Enabled Transfer of Carbon Membrane

3.1 Water-Phase Separation of Carbon Membrane from Substrates

Water-phase transfer was conducted using two processes: water-phase separation and capillary transfer (FIG. 20). In the water-phase separation experiment, paper substrates were gradually submerged in water. The strain energy induced by cellulose swelling facilitated the separation of the carbon membrane from the supporting substrate in less than a second, causing it to float on the water surface. In a capillary transfer experiment, the supporting substrate was initially submerged in water and brought into contact with one end of the desired carbon membrane to form a contact line (the transfer front). For hydrophobic supporting substrates, external force could be applied to assist in forming the contact line. Then, the substrate was held by hand or a rotary knob and moved in a tilted or vertical direction at a low velocity. The high flexibility of the carbon membrane allowed it to conform to rough or 3D surfaces, enabling further fabrication into 3D devices or skin tattoos (FIG. 21). Aside from water-phase transfer, swelling-induced interfacial separation can also be applied to various water-containing substrates (e.g., polyacrylamide hydrogel) with the assistance of water. Furthermore, with the assistance of water to break the interfacial bonds between carbon and paper substrates, the carbon membrane can also be transferred onto adhesive tapes.

### 3.2 Molecular Basis of Cellulose Swelling in Water

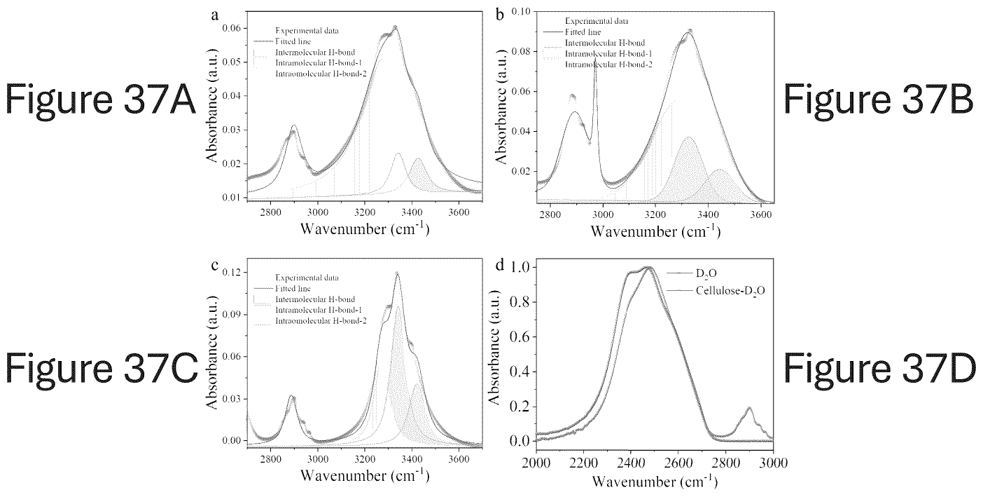

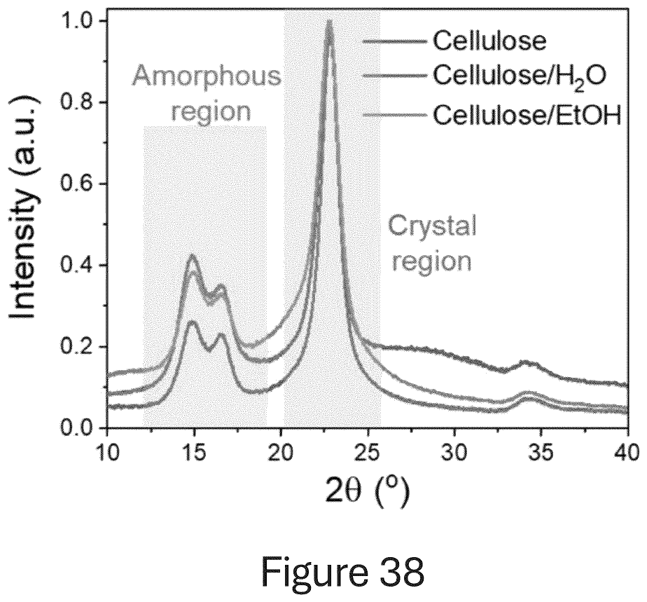

Interactions between water and cellulose fibers were investigated using FTIR (FIG. 37) and XRD spectra (FIG. 38). According to the XRD spectra, filter paper contains two forms of cellulose: crystalline cellulose I (sharp 2θ peak at 22.5°) and amorphous cellulose II (two broad 2θ peaks at 14.8° and 16.6°). The interlayer space of lattice plane (002) was determined to be 0.953 Å. The normalized XRD spectra of cellulose in the presence of water or ethanol show that ethanol induces minor changes in the cellulose XRD spectrum, while water significantly decreases the intensity of cellulose at 14.8° and 16.6° and increases the intensity at around 28°. This suggests that water interacts with the amorphous region of cellulose, while ethanol does not.

Molecular-level interactions between cellulose and solvents were further investigated using FTIR spectra. Cellulose displays a characteristic carbohydrate backbone at 1161 cm⁻¹. Hydrogen bonds formed between cellulose and solvents in the 3000-3600 cm⁻¹ range were resolved by fitting and deconvoluting the FTIR spectra (XPSPEAK 4.0). Normalized FTIR absorbance, based on the carbohydrate backbone, reveals a significant change in hydrogen bonds after wetting with water. After deconvolution of FTIR spectrum based on three different peaks of hydrogen bonds (FIG. 37), the change of hydrogen bonds was resolved during the interaction. Peak 1 corresponds to intermolecular hydrogen bonds (6-OH . . . O-3′); peak 2 is attributed to intramolecular hydrogen bonds (3-OH . . . O-5); and peak 3 is assigned to intramolecular hydrogen bonds (2-OH . . . O-6). The ratio of each peak in the hydrogen bond region indicates that intermolecular hydrogen bonds remain unchanged in the presence of EtOD but are significantly reduced when D₂O is present (Tables 5 and 6). Additionally, FTIR spectra of the O-D stretch mode of D₂O in the absence or presence of cellulose were investigated. A shift of the D-O bond to a higher frequency (FIG. 37D), indicating a weaker D-O bond in the presence of cellulose, suggests an intermolecular interaction between the D-O and hydroxyl groups of cellulose. These results demonstrate that the molecular basis for cellulose swelling in water, but not in ethanol, is due to water's ability to compete with intermolecular hydrogen bonds within the amorphous region of cellulose. Cellulose fiber swelling induces lateral strain energy, resulting in the separation of the carbon membrane and the supporting substrate.

TABLE 5
Positions and assignments of FTIR peaks of cellulose paper
before and after wetting with different solvents.

| Wavenumber | | | | | |
|---|---|---|---|---|---|
| (cm⁻¹) | Assignment | H₂O | D₂O | EtOH | EtOD |
| 3333 | γOH covalent bond, hydrogen | 3334 | 3338 | 3332 | 3335 |
| | bonding | | | | |
| 2899 | γCH | 2901 | 2901 | 2896 | 2886 |
| 1638 | absorbed water (hydrogen- | 1640 | — | 1645 | 1643 |
| | bonded) | | | | |
| 1429 | δCH₂ (symmetric) at C-6; | 1428 | 1428 | 1427 | 1428 |
| | crystalline region | | | | |
| 1369 | δCH₂ | 1370 | 1371 | 1372 | 1372 |
| 1315 | δCH₂ (wagging) at C-6 | 1315 | 1316 | 1315 | 1315 |
| 1236 | δCH₂ in plane at C-6 | 1236 | 1234 | 1235 | 1236 |
| 1161 | γCOC at β-glycosidic linkage | 1161 | 1161 | 1160 | 1161 |
| 1106 | γ ring in plane | 1110 | 1110 | 1110 | 1109 |
| 1030 | γCO at C-6 | 1031 | 1033 | 1033 | 1031 |

TABLE 6
FTIR peak change of H-bonds in cellulose under exposure to various solvents.

| | Paper | | | Paper- D2O | | | Paper-EtOD | | |
|---|---|---|---|---|---|---|---|---|---|
| | Position/ | | Percentage/ | Position/ | | Percentage/ | Position/ | | Percentage/ |
| Peak | cm⁻¹ | FWHM | % | cm⁻¹ | FWHM | % | cm⁻¹ | FWHM | % |
| 1 | 3284.2 | 293.3 | 84.1 | 3272.3 | 79.6 | 30.5 | 3296.3 | 265.6 | 68.5 |
| 2 | 3341.4 | 74.5 | 7.9 | 3341.2 | 74.9 | 46.1 | 3325.6 | 124.6 | 20.2 |
| 3 | 3425.3 | 87.7 | 8.04 | 3421.4 | 84.5 | 23.4 | 3443.9 | 134.3 | 11.3 |

Note:
Peak 1 is assigned to intermolecular H-bond (6-OH•••O-3′); peak 2 is ascribed to intramolecular H-bond (3-OH•••O-5); peak 3 is ascribed to intramolecular H-bond (2 OH•••O-6).

### Example 4: Comparison of this Transfer Method with Other Similar Methods

A comparison of this method for transferable carbon membrane materials with other methods, such as laser+casting, pyrolysis+etching, and CVD+transfer is made. The comparison spans across five dimensions: 1/production cost (inverse of production cost, implying that higher values indicate lower costs), transfer speed (inverse of the time required for transfer, implying that higher values indicate higher transfer speed), number of receiving substrates, sustainability, and functionality.

4.1 Cost (m²/$)

The cost of the lasering+casting method includes the lasering substrate (e.g., polyimide film), the lasering cost, and the casting materials (e.g., PDMS and other elastomer). The raw materials encompass PI (25 μm, $10/m², based on the listed price on www.alibaba.com) and PDMS (˜$191/kg, Sylgard 184, Fisher). With a typical use of 5 mL precursor per 25 cm² during spin coating, the cost of PDMS is $890/m². The cost from lasering primarily arises from the electricity cost of the laser cutter (60 W, VLS 4.60, Universal Laser Systems). Based on the parameters used, the production speed is ˜0.012 m²/h. Considering the electricity rate of 16.04 ¢/kWh, the average electricity cost is $0.08/m². Therefore, the total cost of the lasering+casting method is ˜$900/m².

The cost of the pyrolysis+etching method mainly comprises the deposition of precursor layers, pyrolysis, etching, and transfer. The chemicals typically used in research include phenol ($192/kg), formaldehyde ($38/L), Pluronic® F-127 ($221/kg), silicon wafer (˜$30/slice, 78.5 cm², Nova Electronic Materials), and HF ($130/L, Sigma). In a typical experiment for producing a carbon membrane on a silicon wafer, the total cost of reagents amounts to approximately $4700/m².

The cost of the CVD-based transfer method consists of the copper foil (99.9% purity, 18 μm thickness, $15/kg), CVD system, PMMA coating, and copper etching system. For a typical growth, the 5 cm×5 cm Cu foil was annealed at 1000° C. for 30 min under a hydrogen environment (10 sccm). The growth proceeded for another 30 min under methane gas at 1000° C. Afterward, the chamber cooled down to room temperature in ˜10 min. The as synthesized graphene was then transferred to the SiO₂/Si substrate via the PMMA-assisted transfer method. PMMA was spin-coated onto the graphene and dried in an oven to remove the solvent. The copper foil was etched away by ferric chloride solution in ˜30 min, and the PMMA/graphene stack was thoroughly rinsed. After being transferred to the target substrate, PMMA was finally removed by acetone. Calculating the exact cost of the graphene layer fabrication is challenging. The price of commercially available monolayer graphene from MSE Supplies was roughly adopted and the cost of etching and transfer was excluded, which is ˜$40,000/m².

In this study, the cost of membrane fabrication can be categorized into two parts: materials and manufacturing costs. For the materials aspect, our method primarily employed paper roll (based on the listed price on www.alibaba.com) and sodium borate salt (≥99.5%, Sigma), with prices of $0.5/m² and $0.38/m² (according to the physically absorbed salt on substrate), respectively. The cost of water in this work can be considered negligible. The manufacturing process is based on low-cost impregnation, drying, laser fabrication, and transfer within the R2R apparatus. According to our R2R test, the production speed of the RFID pattern is approximately 80 cm²/h with a running power of 40 W. Given the electricity rate of 16.04 ¢/kWh, the average electricity cost amounts to $0.08/m². Consequently, the total cost of fabricating freestanding carbon membranes is roughly $1/m². The total cost could be further reduced by judiciously increasing the engraving speed.

The 1/production costs for laser+casting, pyrolysis+etching, CVD+transfer, and this method were 10⁻³, 2×10⁻⁴, 2.5×10⁻⁵, and 1 m²/$.

4.2 Transfer speed (s⁻¹)

The release of graphene/carbon membranes from supporting substrates in common practice typically involves an etching procedure. As demonstrated in our work and other research, the etching time for CVD-based graphene usually takes about 10 minutes. For the complete etching of carbon membranes from Si wafers, the pyrolysis+transfer method requires approximately 8 hours. The time needed for the laser+casting method depends on the polymerization speed of the elastomer but is generally more than 2.5 hours (e.g., PDMS under 80° C.). In contrast, our method showcases a significantly faster release speed for carbon membranes on water, taking less than 1 second. Accordingly, the transfer speed, which was expressed as the inverse of the releasing time, was 10⁻⁴, 3.5×10⁻⁵, 1.7×10⁻³, and 1 s⁻¹ for laser+casting, pyrolysis+etching, CVD+transfer, and our method.

### 4.3 Number of Receiving Substrates (NRS)

The number of receiving substrates primarily depends on the transfer method, such as water-phase etching or casting. As a minimally invasive method, water-phase separation offers numerous possibilities for transferring membranes onto various 2D surfaces or 3D objects. The candidate receiving substrates encompass a wide range of material systems, including plastics, elastomers, metals, glass, hydrogels, and other 3D objects. Limited by potential polymer candidates (e.g., PDMS, SEBS), the number of receiving substrates for the casting method is relatively smaller than that for the water-phase method.

### 4.4 Sustainability

Compared to other etching methods that use toxic and corrosive chemicals like HF, HCl, or FeCl₃, this method employs environmentally friendly water as the delamination medium. Additionally, the substrates we utilized are derived from natural degradable products, which further enhances the sustainability of this method in electronics fabrication. Although the waste production of the laser+casting method is significantly less than that of other etching methods, traditional laser methods primarily use non-degradable polymers as substrates, limiting their sustainability score.

### 4.5 Functionality

The laser-based pyrolysis method enables the synthesis of various metals, metal carbides, and metal oxides within a carbon matrix. By adjusting localized reaction conditions, a wide variety of functional carbon materials can be produced. However, the spatial resolution and thickness are limited to tens of micrometers. Moreover, the material pool is limited to carbon-based materials. These properties can be optimized combining with other synthesis methods in the future. In comparison, the CVD method allows for the synthesis of other material systems, including semiconductors and insulators, and offers precise control over properties such as doping, crystallinity, and thickness. Both pyrolysis and CVD present unique advantages and limitations for material synthesis. CVD is well-suited for high-quality, large-area membranes with precise control over material properties, while pyrolysis offers versatility in creating a diverse range of carbon materials. The choice between these methods depends on the specific requirements of the material pool construction and the desired properties of the synthesized materials. In addition to material platform options, laser-based pyrolysis methods provide good precision in material patterning, facilitating the direct fabrication of electronics, supercapacitors, and other applications.

### REFERENCES

ADDIN ZOTERO_BIBL {“uncited”:[ ], “omitted”:[ ], “custom”:[ ]}CSL_BIBLIOGRAPHY ADDIN EN.REFLIST 1. Park S, et al. Self-powered ultra-flexible electronics via nano-grating patterned organic photovoltaics. Nature 561, 516-521 (2018).
2. Hwangbo S, Hu L, Hoang A T, Choi J Y, Ahn J-H. Wafer-scale monolithic integration of full-colour micro-LED display using MoS2 transistor. Nat Nanotechnol 17, 500-506 (2022).
3. Wang Q, Huang N, Chen Z, Chen X, Cai H, Wu Y. Environmental data and facts in the semiconductor manufacturing industry: An unexpected high water and energy consumption situation. Water Cycle 4, 47-54 (2023).
4. Xia. Y, Whitesides. G M. Soft lithography. Annu Rev Mater Sci 28, 153-184 (1998).
5. Chang Y, et al. Closed-loop electrochemical recycling of spent copper(II) from etchant wastewater using a carbon nanotube modified graphite felt anode. Environ Sci Technol 52, 5940-5948 (2018).
6. Insights C M. Global etching chemicals market 2023-2032. Custom Market Insights (2023).
7. Branham M S, Gutowski T G. Deconstructing energy use in microelectronics manufacturing: An experimental case study of a MEMS fabrication facility. Environ Sci Technol 44, 4295-4301 (2010).
8. Murphy C F, Kenig G A, Allen D T, Laurent J-P, Dyer D E. Development of parametric material, energy, and emission inventories for wafer fabrication in the semiconductor industry. Environ Sci Technol 37, 5373-5382 (2003).
9. Bae S, et al. Roll-to-roll production of 30-inch graphene films for transparent electrodes. Nat Nanotechnol 5, 574-578 (2010).
10. Fang Y, et al. Micelle-enabled self-assembly of porous and monolithic carbon membranes for bioelectronic interfaces. Nat Nanotechnol 16, 206-213 (2021).
11. Bubnova O. A decade of R2R graphene manufacturing. Nat Nanotechnol 16, 1050-1050 (2021).
12. Sviben S, et al. Epidermal cell surface structure and chitin-protein co-assembly determine fiber architecture in the locust cuticle. ACS Appl Mater Interface 12, 25581-25590 (2020).
13. Qu L, Dai L, Stone M, Xia Z, Wang Z L. Carbon nanotube arrays with strong shear binding-on and easy normal lifting-off. Science 322, 238-242 (2008).
14. Fraley S I, et al. A distinctive role for focal adhesion proteins in three-dimensional cell motility. Nat Cell Biol 12, 598-604 (2010).
15. Khare E, Holten-Andersen N, Buehler M J. Transition-metal coordinate bonds for bioinspired macromolecules with tunable mechanical properties. Nat Rev Mat 6, 421-436 (2021).
16. Lin J, et al. Laser-induced porous graphene films from commercial polymers. Nat Commun 5, 5714-2721 (2014).
17. Luong D X, et al. Gram-scale bottom-up flash graphene synthesis. Nature 577, 647-651 (2020).
18. Baban N S, Orozaliev A, Kirchhof S, Stubbs C J, Song Y-A. Biomimetic fracture model of lizard tail autotomy. Science 375, 770-774 (2022).
19. Nakamura T, Takashima Y, Hashidzume A, Yamaguchi H, Harada A. A metal-ion-responsive adhesive material via switching of molecular recognition properties. Nat Commun 5, 4622-4630 (2014).
20. Baxamusa S H, et al. Enhanced delamination of ultrathin free-standing polymer films via self-limiting surface modification. Langmuir 30, 5126-5132 (2014).
21. Freund L B, Suresh S. Thin film materials: Stress, defect formation and surface evolution. Cambridge University Press (2004).
22. Zhuk A V, Evans A G, Hutchinson J W, Whitesides G M. The adhesion energy between polymer thin films and self-assembled monolayers. J Mater Res 13, 3555-3564 (1998).
23. Ma J, et al. Role of thin film adhesion on capillary peeling. Nano Lett 21, 9983-9989 (2021).
24. Hu Z, et al. Rapid and scalable transfer of large-area graphene wafers. Adv Mat 35, 2300621-2300629 (2023).
25. Gao L, et al. Repeated growth and bubbling transfer of graphene with millimetre-size single-crystal grains using platinum. Nat Commun 3, 699-705 (2012).
26. Leong W S, et al. Paraffin-enabled graphene transfer. Nat Commun 10, 867-874 (2019).
27. Zhao Y, et al. Large-area transfer of two-dimensional materials free of cracks, contamination and wrinkles via controllable conformal contact. Nat Commun 13, 4409-4418 (2022).
28. Gao L, Ni G-X, Liu Y, Liu B, Castro Neto A H, Loh K P. Face-to-face transfer of wafer-scale graphene films. Nature 505, 190-194 (2014).
29. Wang M, et al. Single-crystal, large-area, fold-free monolayer graphene. Nature 596, 519-524 (2021).
30. Li J, et al. A tissue-like neurotransmitter sensor for the brain and gut. Nature 772 606, 94-101 (2022).
31. Li T, et al. Denary oxide nanoparticles as highly stable catalysts for methane combustion. Nat Catal 4, 62-70 (2021).
32. Pinheiro T, et al. Water peel-off transfer of electronically enhanced, paper based laser-induced graphene for wearable electronics. ACS Nano 16, 20633-20646 (2022).
33. Nair V, et al. Laser writing of nitrogen-doped silicon carbide for biological modulation. Sci Adv 6, eaaz2743 (2020).
34. Prominski A, et al. Porosity-based heterojunctions enable leadless optoelectronic modulation of tissues. Nat Mater 21, 647-655 (2022).
35. Merrill D R. The electrochemistry of charge injection at the electrode/tissue interface. In: Implantable neural prostheses 2: Techniques and engineering approaches (eds Zhou D, Greenbaum E). Springer (2010).
36. Zeng M, et al. Printing thermoelectric inks toward next-generation energy and thermal devices. Chem Soc Rev 51, 485-512 (2022).
37. Kay G N, Shepard R B. Stimulation and excitation of cardiac tissues. In: Clinical cardiac pacing, defibrillation, and resynchronization therapy (Fifth Edition) (eds Ellenbogen K A, Wilkoff B L, Kay G N, Lau C-P, Auricchio A). Elsevier (2017).
38. Nath T, Mathis A, Chen A C, Patel A, Bethge M, Mathis M W. Using DeepLabCut for 3D markerless pose estimation across species and behaviors. Nat Protoc 14, 2152-2176 (2019).
39. Yu Y, et al. All-printed soft human-machine interface for robotic physicochemical sensing. Sci Robotics 7, 0495-0506 (2022).
40. Huang H, et al. Large-scale self-assembly of MOFs colloidosomes for bubble-propelled micromotors and stirring-free environmental remediation. Angew Chem, Int Ed 61, 11163-11173 (2022).
41. Li W, et al. Self-driven magnetorobots for recyclable and scalable micro/nanoplastic removal from nonmarine waters. Sci Adv 8, 1731-1742 (2022).
42. Urso M, Ussia M, Pumera M. Smart micro- and nanorobots for water purification. Nat Rev Bioeng 1, 236-251 (2023).
43. Ullah S, et al. Graphene transfer methods: A review. Nano Res 14, 3756-3772 (2021).
44. Li S-C, et al. Wood-derived ultrathin carbon nanofiber aerogels. Angew Chem Int Ed Engl 57, 7085-7090 (2018).
45. Kim D-H, et al. Dissolvable films of silk fibroin for ultrathin conformal bio-integrated electronics. Nat Mater 9, 511-517 (2010).
46. Frischknecht R, et al. Implementation of life cycle impact assessment methods. (2007).
47. Finkbeiner M, Inaba A, Tan R, Christiansen K, Klüppel H-J. The new international standards for life cycle assessment: ISO 14040 and ISO 14044. Int J Life Cycle Assess 11, 80-85 (2006).
48. Wernet G, Bauer C, Steubing B, Reinhard J, Moreno-Ruiz E, Weidema B. The ecoinvent database version 3 (part I): overview and methodology. Int J Life Cycle Assess 21, 1218-1230 (2016).
49. Bare J. TRACI 2.0: the tool for the reduction and assessment of chemical and other environmental impacts 2.0. Clean Techn Environ Policy 13, 687-696 (2011).
50. Bare J C. TRACI: The tool for the reduction and assessment of chemical and other environmental impacts. J Ind Ecol 6, 49-78 (2002).
51. Zhang, Y. et al. Capillary transfer of soft films. Proc. Natl. Acad. Sci. U.S.A 117, 5210-5216, (2020).
52. Cai, C. & Chen, J. Direct electron transfer and bioelectrocatalysis of hemoglobin at a carbon nanotube electrode. Anal. Biochem. 325, 285-292, (2004).
53. Fang, Y. et al. Micelle-enabled self-assembly of porous and monolithic carbon membranes for bioelectronic interfaces. Nat. Nanotechnol. 16, 206-213, (2021).
54. Kim, D.-H. et al. Dissolvable films of silk fibroin for ultrathin conformal biointegrated electronics. Nat. Mater. 9, 511-517, (2010).
55. Prominski, A. et al. Porosity-based heterojunctions enable leadless optoelectronic modulation of tissues. Nat. Mater. 21, 647-655, (2022).
56. Nath, T. et al. Using DeepLabCut for 3D markerless pose estimation across species and behaviors. Nat. Protoc. 14, 2152-2176, (2019).
57. Lin, J. et al. Laser-induced porous graphene films from commercial polymers. Nat. Commun. 5, 5714-2721, (2014).
58. Ferrari, A. C. et al. Raman Spectrum of Graphene and Graphene Layers. Physical Review Letters 97, 187401, (2006).
59. Wan, S. et al. High-strength scalable MXene films through bridging-induced densification. Science 374, 96-99, (2021).
60. Pan, J., Jiang, H., Qing, T., Zhang, J. & Tian, K. Transformation and kinetics of chlorine-containing products during pyrolysis of plastic wastes. Chemosphere 284, 131348, (2021).
61. Coats, A. W. & Redfern, J. P. Kinetic Parameters from Thermogravimetric Data. Nature 201, 68-69, (1964).
62. Luong, D. X. et al. Gram-scale bottom-up flash graphene synthesis. Nature 577, 647-651, (2020).
63. Zhang, Y., Zhang, T., Huang, Z. & Yang, J. A new class of electronic devices based on flexible porous substrates. Adv. Sci. 9, 2105084, (2022).
64. Park, H., Kim, M., Kim, B. G. & Kim, Y. H. Electronic functionality encoded laserinduced graphene for paper electronics. ACS Appl. Nano Mater. 3, 6899-6904, (2020).
65. Chyan, Y. et al. Laser-induced graphene by multiple lasing: toward electronics on cloth, paper, and food. ACS Nano 12, 2176-2183, (2018).
66. Pinheiro, T. et al. Water peel-off transfer of electronically enhanced, paper-based laserinduced graphene for wearable electronics. ACS Nano 16, 20633-20646, (2022).
67. Oh, S. Y. et al. Crystalline structure analysis of cellulose treated with sodium hydroxide and carbon dioxide by means of X-ray diffraction and FTIR spectroscopy. Carbohydr. Res. 340, 2376-2391, (2005).
68. Cichosz, S. & Masek, A. IR study on cellulose with the varied moisture contents: Insight into the supramolecular structure. Materials 13, 4573, (2020).
69. Solhi, L. et al. Understanding nanocellulose-water interactions: Turning a detriment into an asset. Chem. Rev. 123, 1925-2015, (2023).
70. Olsson, A.-M. & Salmén, L. The association of water to cellulose and hemicellulose in paper examined by FTIR spectroscopy. Carbohydr. Res. 339, 813-818, (2004).
71. De Marco, L. et al. Differences in the vibrational dynamics of H2O and D2O: Observation of symmetric and antisymmetric stretching vibrations in heavy water. J. Phys. Chem. Lett. 7, 1769-1774, (2016).
72. Li, J. et al. A tissue-like neurotransmitter sensor for the brain and gut. Nature 606, 94-101, (2022).
73. Meng, Y. et al. Ordered mesoporous polymers and homologous carbon frameworks: amphiphilic surfactant templating and direct transformation. Angew Chem Int Ed Engl 44, 7053-7059, (2005).
74. Deng, B. et al. Roll-to-roll encapsulation of metal nanowires between graphene and plastic substrate for high-performance flexible transparent electrodes. Nano Lett 15, 4206-4213, (2015).

1. A roll-to-roll (R2R) apparatus for continuous production of carbon/graphene-based electronic devices, comprising:
a substrate handling module;
an infiltration module;
a patterning module;
a control system; and
a post-processing module.

2. The R2R apparatus of claim 1, wherein the substrate handling module comprises:
a freely moving unwind unit;
a tension control system; and
a motor-driven rewind unit.

3. The R2R apparatus of claim 2, wherein the freely moving unwind unit is configured to be continuously fed a flexible substrate from an unprocessed roll.

4. The R2R apparatus of claim 3, wherein the tension control system further comprises an alignment system, and wherein the tension control system and the alignment system are configured to maintain tension of the flexible substrate as it moves from the freely moving unwind unit to the motor-driven rewind unit.

5. The R2R apparatus of claim 4, wherein the motor-driven rewind unit is configured to collect the flexible substrate fed through the freely moving unwind unit onto a roll.

6. The R2R apparatus of claim 1, wherein the infiltration module comprises:
an infiltration bath; and
a heater assembly.

7. The R2R apparatus of claim 6, wherein the infiltration bath is configured to process the flexible substrate in a predesigned sink using a deposition technique.

8. The R2R apparatus of claim 7, wherein the infiltration bath comprises at least one of a functional salt, a conductive ink, a semiconducting polymer, a dielectric material, and an encapsulation layer.

9. The R2R apparatus of claim 7, wherein the deposition technique comprises a salt-impregnation process, and wherein the salt-impregnation process comprises applying a concentrated sodium borate solution to the flexible substrate, or wherein the deposition technique comprises at least one of a slot-die coating and a spray coating.

10. The R2R apparatus of claim 6, wherein the heater assembly comprises a Joule heater assembled from resistive wire enclosed in high-temperature fiberglass sleeving.

11. The R2R apparatus of claim 6, wherein the heater assembly is configured to dry the flexible substrate after the flexible substrate is bathed in the infiltration bath.

12. The R2R apparatus of claim 1, wherein the patterning module comprises:
an ablation machine; and
control software integrated with a stepper motor integrated into an Arduino board.

13. The R2R apparatus of claim 12, wherein the ablation machine comprises a K40 CO₂ laser configured to create conductive carbon/graphene patterns on the flexible substrate, and wherein the K40 CO₂ laser is configured to transform cellulose-based material into conductive carbon/graphene patterns on the flexible substrate.

14. The R2R apparatus of claim 12, wherein the ablation machine comprises at least one of a photolithography machine, a screen printing machine, and a blade coating machine to create patterns for electrodes, transistors, and other electronic components on the flexible substrate.

15. The R2R apparatus of claim 12, wherein the ablation machine further comprises an alignment system, and wherein the control software allows for coordination of rolling, patterning, and pausing the flexible substrate with the ablation machine integrated with the alignment system.

16. The R2R apparatus of claim 1, wherein the control system comprises:
a central controller;
an ablation controller;
a raster; and
a user interface for managing rolling and patterning processes of the R2R apparatus.

17. The R2R apparatus of claim 16, wherein the control system coordinates operation of the substrate handling module, the impregnation module, the patterning module, and the post-processing module.

18. The R2R apparatus of claim 17, wherein the control system is configured to precisely regulate substrate feeding speed at the substrate handling module, impregnation time at the impregnation module, patterning design at the patterning module, and post-processing conditions at the post-processing module to achieve uniform and high-quality flexible electronic devices.

19. The R2R apparatus of claim 1, wherein the post-processing module comprises:
a performance testing device; and
a water-phase transfer device.

20. The R2R apparatus of claim 19, wherein the performance testing device is configured to test parameters of fabricated electronic devices created out of the flexible substrate through processing at the substrate handling module, the impregnation module, and the patterning module, wherein the post-processing module is configured to separate fabricated electronic devices from the remainder of the flexible substrate after processing at the substrate handling module, the impregnation module, and the patterning module, or wherein the water-phase transfer device is configured to transfer the fabricated electronic devices from the remainder of the flexible substrate after processing at the substrate handling module, the impregnation module, and the patterning module.
